(19) United States
(12) Patent Application Publication
(10) Pub. No.: US 2022/0155500 A1
(43) Pub. Date: May 19, 2022

(54) NOVEL ACTIVE MICRO-OPTICS SYSTEM

(71) Applicant: MANTAPOOLE TECHNOLOGIES LLC, Reston, VA (US)

(72) Inventor: Jesse H. CLAYPOOLE, Knoxville, TN (US)

(21) Appl. No.: 17/431,879

(22) PCT Filed: Feb. 18, 2020
(86) PCT No.: PCT/US2020/018660

§ 371 Date: Aug. 18, 2021

Related U.S. Application Data
(60) Provisional application No. 62/806,908, filed on Feb. 18, 2019.

(51) Int. Cl. G02B 5/04; G02B 27/30; G02B 5/22

(52) U.S. Cl. CPC G02B 5/045; G02B 5/22; G02B 27/30

(57) ABSTRACT

An assembly for use with an optical component, the assembly including a first plurality of optical devices positioned along a light axis and aligned with one or more pixels of an optoelectronic component, wherein the first plurality of optical devices are configured to receive light at a light receiving angle along the light axis at a first end of the plurality of optical devices and controllably alter the angle of light exiting the plurality of optical devices at an angle divergent to the light receiving angle at a second end of the plurality of optical devices.

### CROSS-REFERENCE TO RELATED APPLICATIONS

This application is a national stage application filed under 35 U.S.C. § 371 of International Patent Application No. PCT/US2020/018660, filed on Feb. 18, 2020, which is incorporated by reference herein in its entirety for all purposes.

### FIELD OF THE INVENTION

Aspects of present invention relate to a Micro-Optical System, Directional Light Capture, 3D Cameras, Plenoptic Cameras, Multispectral Cameras, Light Field Displays, and 3D Displays.

### SUMMARY

In some aspects, the present disclosure provides an assembly for use with an optical component. In certain embodiments, the assembly comprises a first plurality of optical devices positioned along a light axis and aligned with one or more pixels of an optoelectronic component. In certain embodiments, the first plurality of optical devices are configured to receive light at a light receiving angle along the light axis at a first end of the plurality of optical devices and controllably alter the angle of light exiting the plurality of optical devices at an angle divergent to the light receiving angle at a second end of the plurality of optical devices. In certain embodiments, the one or more pixels includes a first pixel sub-component configured to emit and/or receive first pixel sub-component light having a first wavelength range and a second pixel sub-component configured to emit and/or receive second pixel sub-component light having a second wavelength range. In certain embodiments, the first wavelength range is separate and distinct from the second wavelength range. In certain embodiments, the first plurality of optical devices are aligned with the first pixel sub-component and the second pixel sub-component. In certain embodiments, the assembly further comprises a second plurality of optical devices positioned along a light axis and aligned with the second pixel sub-component, the second plurality of optical devices including at least one dispersion compensator configured to alter an angle of the second pixel sub-component light to exit the second plurality of optical devices at a substantially similar angle to the first pixel sub-component light by generating an electric field across the dispersion compensator. In certain embodiments, the one or more pixels includes a third pixel sub-component configured to emit and/or receive third pixel sub-component light having a third wavelength range. In certain embodiments, the assembly further comprises a third plurality of optical devices positioned along a light axis and aligned with the third pixel sub-component. In certain embodiments, the third plurality of optical devices including at least one dispersion compensator configured to alter an angle of the third pixel sub-component light to exit the third plurality of optical devices at a substantially similar angle to the first pixel sub-component light by generating an electric field across the dispersion compensator. In certain embodiments, the one or more pixels includes a fourth pixel sub-component configured to emit and/or receive fourth pixel sub-component light having a fourth wavelength range. In certain embodiments, the assembly further comprises a fourth plurality of optical devices positioned along a light axis and aligned with the fourth pixel sub-component. In certain embodiments, the fourth plurality of optical devices including at least one dispersion compensator configured to alter the angle of the fourth pixel sub-component light to exit fourth plurality of optical devices at a substantially similar angle to the first pixel sub-component light by generating an electric field across the dispersion compensator. In certain embodiments, the first plurality of optical devices includes at least one dispersion compensator configured to alter an angle of the first pixel sub-component light to exit the first plurality of optical devices. In certain embodiments, the pixel sub-component corresponds to a respective color component of the one or more pixels. In certain embodiments, each of the plurality of optical devices includes a second dispersion compensator. In certain embodiments, a periphery of the first plurality of optical devices is aligned with a periphery of the one or more pixels. In certain embodiments, each of the plurality of optical devices includes a light collimator configured to only permit light substantially along the light receiving axis to travel through the light collimator. In certain embodiments, the light collimator includes an optically transparent material that extends along the light axis. In certain embodiments, the light collimator includes an optically absorptive material that surrounds the optically transparent material along the light axis. In certain embodiments, the optically absorptive material has a U-shape that extends along the light axis. In certain embodiments, a region defined by the U-shape includes an optically absorptive material. In certain embodiments, each of the plurality of optical devices includes a dispersion compensator configured to alter a respective angle of a respective wavelength range of light by a respective angular amount by generating an electric field across the respective dispersion compensator. In certain embodiments, the dispersion compensator includes an electro-optical deflector including: two or more electrodes configured to generate an electric field that varies as a function of a received voltage signal from a controller. In certain embodiments, each of the plurality of optical devices includes a first main beam deflector configured to alter the angle of a respective wavelength range of light relative to the light axis by an angular amount based on the magnitude of the gradient in refractive index across the first main beam deflector that varies as a function of a characteristic of a received electrical signal from a controller, and a height of the first main beam deflector. In certain embodiments, each of the plurality of optical devices includes a second main beam deflector configured to alter the angle of a respective wavelength range of light relative to the light axis by an angular amount based on a magnitude gradient in refractive index across the second main beam deflector that varies as a function of a characteristic of a received electrical signal from a controller, and a height of the second main beam deflector. In certain embodiments, each of the plurality of optical devices includes a first prism array configured to alter the angle of a respective wavelength range of light relative to the light axis by an angular amount based on an angle of the first prism array. In certain embodiments, each of the plurality of optical devices includes a second prism array configured to alter the angle of a respective wavelength range of light relative to the light axis by an angular amount based on an angle of the second prism array. In certain embodiments, each of the plurality of optical devices includes a first planarization layer configured to planarize the first prism array so that a side of the first planarization layer where a respective wavelength range of light exits is normal to the light axis. In certain embodiments, each of the plurality of optical devices includes a second planarization layer configured to planarize the second prism array so that a side of the second planarization layer where a respective wavelength range of light exits is normal to the light axis. In certain embodiments, the assembly is a plurality of the assemblies according to any of the preceding claims, each of the assemblies arranged in a one or two dimensional array extending along a plane orthogonal to the light axis, each respective assembly independently altering an angle of a respective wavelength of light entering the respective assembly. In certain embodiments, the assembly further comprises a controller configured to cause each respective assembly to independently alter an angle of a respective wavelength of light entering the respective assembly. In certain embodiments, the assembly further comprises a controller configured to set an angle of the wavelength range of light for a respective assembly at a first angle during a first time period and set an angle of the wavelength range of light for the respective assembly at a second angle during a subsequent time periods. In certain embodiments, the second angle is substantially similar to the first angle. In certain embodiments, the second angle is different from the first angle. In certain embodiments, In certain embodiments, the controller is configured to set a respective angle of a respective wavelength range of light by applying a one or more voltages to one or more electrodes of the one or more dispersion compensators and/or the one or more main beam deflectors to alter the electric field applied to the one or more electrodes. In certain embodiments, the controller is configured to set the angle of a first wavelength range of light along different angular positions along an angular range of greater than 3 degrees during a scanning time period of less than 10 seconds by adjusting a respective voltage applied to the one or more electrodes during the scanning time period. In certain embodiments, the assembly further comprises a sensor configured to detect light exiting the optical electronic component and generate a sensor signal representative of the light field of its environment. In certain embodiments, the assembly further comprises a sensor configured to detect light exiting the optical assembly and generate a sensor signal representative of the light field of its environment. In certain embodiments, the assembly further comprises a sensor configured to detect light exiting the assembly and generate a sensor signal representative of the light field of its environment. In certain embodiments, the assembly further comprises a sensor configured to detect light exiting the optical device and generate a sensor signal representative of the light field of its environment. In certain embodiments, the assembly further comprises a controller configured to receive the sensor signal and alter the angle of the first wavelength range of light exiting the plurality of optical devices based on at least one of: sensor signal characteristics, operating characteristics, and optical device characteristics. In certain embodiments, the optoelectronic component is a light emitter or light receiver. In certain embodiments, each of the first plurality of optical devices positioned along the light axis are disposed about the light axis. In certain embodiments, the light axis is a central axis of each of the optical devices of the plurality of optical devices. In certain embodiments, each of the respective plurality of optical devices are aligned with a corresponding one or more pixels and are configured to transfer light there between. In certain embodiments, an optical device of the plurality of optical devices varies the divergent angle as a function of characteristics of a control signal received from a controller. In certain embodiments, the second plurality of optical devices including at least two dispersion compensators each configured to alter an angle of the second pixel sub-component light to exit the second plurality of optical devices at a substantially similar angle to the first pixel sub-component light by generating an independent electric field across each of the dispersion compensators.

In some aspects, the present disclosure provides a method for using an assembly for use with an optical component. In certain embodiments, the method comprises positioning a first plurality of optical devices along a light axis and aligned with one or more pixels of an optoelectronic component. In certain embodiments, the first plurality of optical devices are configured to receive light at a light receiving angle along the light axis at a first end of the plurality of optical devices. In certain embodiments, the method further comprises controllably altering the angle of light exiting the plurality of optical devices at an angle divergent to the light receiving angle at a second end of the plurality of optical devices. In certain embodiments, the method comprises emitting and/or receiving first pixel sub-component light having a first wavelength range. In certain embodiments, the method comprises emitting and/or receiving second pixel sub-component light having a second wavelength range. In certain embodiments, the first wavelength range is separate and distinct from the second wavelength range. In certain embodiments, the method comprises aligning the first plurality of optical devices with the first pixel sub-component and the second pixel sub-component. In certain embodiments, the method comprises positioning a second plurality of optical devices along a light axis and aligned with the second pixel subcomponent, the second plurality of optical devices including at least one dispersion compensator. In certain embodiments, the method comprises altering, using the at least one dispersion compensator of the second plurality of optical devices, an angle of the second pixel sub-component light to exit the second plurality of optical devices at a substantially similar angle to the first pixel sub-component light by generating an electric field across the dispersion compensator. In certain embodiments, the one or more pixels includes a third pixel sub-component configured to emit and/or receive third pixel sub-component light having a third wavelength range. In certain embodiments, the method comprises positioning a third plurality of optical devices along a light axis and aligned with the third pixel subcomponent. In certain embodiments, the third plurality of optical devices including at least one dispersion compensator configured to alter an angle of the third pixel sub-component light to exit the third plurality of optical devices at a substantially similar angle to the first pixel sub-component light by generating an electric field across the dispersion compensator. In certain embodiments, the one or more pixels includes a fourth pixel sub-component configured to emit and/or receive fourth pixel sub-component light having a fourth wavelength range. In certain embodiments, the method comprises positioning a fourth plurality of optical devices along a light axis and aligned with the fourth pixel subcomponent. In certain embodiments, the fourth plurality of optical devices including at least one dispersion compensator configured to alter the angle of the fourth pixel sub-component light to exit fourth plurality of optical devices at a substantially similar angle to the first pixel sub-component light by generating an electric field across the dispersion compensator. In certain embodiments, the first plurality of optical devices includes at least one dispersion compensator. In certain embodiments, the method comprises altering an angle of the first pixel sub-component light to exit the first plurality of optical devices. In certain embodiments, the pixel sub-component corresponds to a respective color component of the one or more pixels. In certain embodiments, each of the plurality of optical devices includes a second dispersion compensator. In certain embodiments, aligning a periphery of the first plurality of optical devices with a periphery of the one or more pixels. In certain embodiments, each of the plurality of optical devices includes a light collimator. In certain embodiments, the method comprises only permitting light substantially along the light receiving axis to travel through the light collimator. In certain embodiments, the light collimator includes an optically transparent material that extends along the light axis. In certain embodiments, the light collimator includes an optically absorptive material that surrounds the optically transparent material along the light axis. In certain embodiments, the optically absorptive material has a U-shape that extends along the light axis. In certain embodiments, a region defined by the U-shape includes an optically absorptive material. In certain embodiments, each of the plurality of optical devices includes a dispersion compensator. In certain embodiments, the method further comprising: altering a respective angle of a respective wavelength range of light by a respective angular amount by generating an electric field across the respective dispersion compensator. In certain embodiments, the dispersion compensator includes an electro-optical deflector including two or more electrodes configured to generate an electric field that varies as a function of a received voltage signal from a controller. In certain embodiments, each of the plurality of optical devices includes a first main beam deflector. In certain embodiments, the method comprises altering the angle of a respective wavelength range of light relative to the light axis by an angular amount based on the magnitude of the gradient in refractive index across the first main beam deflector that varies as a function of a characteristic of a received electrical signal from a controller, and a height of the first main beam deflector. In certain embodiments, each of the plurality of optical devices includes a second main beam deflector. In certain embodiments, the method comprises altering the angle of a respective wavelength range of light relative to the light axis by an angular amount based on a magnitude gradient in refractive index across the second main beam deflector that varies as a function of a characteristic of a received electrical signal from a controller, and a height of the second main beam deflector. In certain embodiments, each of the plurality of optical devices includes a first prism array. In certain embodiments, the method comprises altering, using the first prism array, the angle of a respective wavelength range of light relative to the light axis by an angular amount based on an angle of the first prism array. In certain embodiments, each of the plurality of optical devices includes a second prism array. In certain embodiments, the method comprises altering the angle of a respective wavelength range of light relative to the light axis by an angular amount based on an angle of the second prism array. In certain embodiments, each of the plurality of optical devices includes a first planarization layer configured to planarize the first prism array so that a side of the first planarization layer where a respective wavelength range of light exits is normal to the light axis. In certain embodiments, each of the plurality of optical devices includes a second planarization layer configured to planarize the second prism array so that a side of the second planarization layer where a respective wavelength range of light exits is normal to the light axis. In certain embodiments, the assembly is a plurality of the assemblies according to any of the preceding claims, each of the assemblies arranged in a one or two dimensional array extending along a plane orthogonal to the light axis, each respective assembly independently altering an angle of a respective wavelength of light entering the respective assembly. In certain embodiments, the assembly further includes a controller configured to cause each respective assembly to independently alter an angle of a respective wavelength of light entering the respective assembly. In certain embodiments, the assembly further includes a controller configured to set an angle of the wavelength range of light for a respective assembly at a first angle during a first time period and set an angle of the wavelength range of light for the respective assembly at a second angle during a subsequent time periods. In certain embodiments, the second angle is substantially similar to the first angle. In certain embodiments, the second angle is different from the first angle. In certain embodiments, the method comprises setting, using a controller, a respective angle of a respective wavelength range of light by applying a one or more voltages to one or more electrodes of the one or more dispersion compensators and/or the one or more main beam deflectors to alter the electric field applied to the one or more electrodes. In certain embodiments, the method comprises setting, using a controller, the angle of the first wavelength range of light along different angular positions along an angular range of greater than 3 degrees during a scanning time period of less than 10 seconds by adjusting a respective voltage applied to the one or more electrodes during the scanning time period. In certain embodiments, the method comprises detecting, using a sensor, light exiting the optical assembly and generate a sensor signal representative of the light field of its environment. In certain embodiments, the method comprises receiving using a controller the sensor signal and alter the angle of the first wavelength range of light exiting the plurality of optical devices based on at least one of: sensor signal characteristics, operating characteristics, and optical device characteristics. In certain embodiments, the optoelectronic component is a light emitter or light receiver. In certain embodiments, each of the first plurality of optical devices positioned along the light axis are disposed about the light axis. In certain embodiments, the light axis is a central axis of each of the optical devices of the plurality of optical devices. In certain embodiments, each of the respective plurality of optical devices are aligned with a corresponding one or more pixels and are configured to transfer light there between. In certain embodiments, the method comprises varying the divergent angle as a function of characteristics of a control signal received from a controller. In certain embodiments, the second plurality of optical devices including at least two dispersion compensators each configured to alter an angle of the second pixel sub-component light to exit the second plurality of optical devices at a substantially similar angle to the first pixel sub-component light by generating an independent electric field across each of the dispersion compensators.

### BRIEF DESCRIPTION OF THE DRAWINGS

FIG. 1 shows the general arrangement of a superpixel in a one dimensional array of superpixels that make up the active micro-optical array in accordance with at least one embodiment of the invention.

FIG. 2 shows the general arrangement of a superpixel in a two dimensional array of superpixels that make up the active micro-optical array in accordance with at least one embodiment of the invention.

FIG. 3 shows the general reference orientation and directions for a superpixel in accordance with at least one embodiment of the invention.

FIG. 4 shows a two pixel sub-component superpixel with light entering the bottom of the superpixel through each pixel sub-component and leaving the top of the superpixel at the same or different angle in accordance with at least one embodiment of the invention.

FIG. 5 shows a three pixel sub-component superpixel with light entering the bottom of the superpixel through each pixel sub-component and leaving the top of the superpixel at the same or different angle in accordance with at least one embodiment of the invention.

FIG. 6 shows a four pixel sub-component superpixel with light entering the bottom of the superpixel through each pixel sub-component and leaving the top of the superpixel at the same or different angle in accordance with at least one embodiment of the invention.

FIG. 7 shows a two pixel sub-component superpixel with light entering the top of the superpixel and leaving the bottom of the superpixel at the same or different angle through each pixel sub-component in accordance with at least one embodiment of the invention.

FIG. 8 shows a three pixel sub-component superpixel with light entering the top of the superpixel and leaving the bottom of the superpixel at the same or different angle through each pixel sub-component in accordance with at least one embodiment of the invention.

FIG. 9 shows a four pixel sub-component superpixel with light entering the top of the superpixel and leaving the bottom of the superpixel at the same or different angle through each pixel sub-component in accordance with at least one embodiment of the invention.

FIG. 10 shows a four electrode configuration over a pixel sub-component of a dispersion compensator or all of the pixel subcomponents in a main beam deflector in accordance with at least one embodiment of the invention.

FIG. 11 shows one embodiment of the three electrode configuration over a pixel subcomponent of a dispersion compensator or all of the pixel sub-components in a main beam deflector in accordance with at least one embodiment of the invention.

FIG. 12 shows one embodiment of the three electrode configuration over a pixel subcomponent of a dispersion compensator or all of the pixel sub-components in a main beam deflector in accordance with at least one embodiment of the invention.

FIG. 13 shows an embodiment of a two electrode configuration over a pixel subcomponent of a dispersion compensator or all of the pixel sub-components in a main beam deflector in accordance with at least one embodiment of the invention.

FIG. 14 shows an embodiment of a two pixel sub-component dispersion compensator in accordance with at least one embodiment of the invention.

FIG. 15 shows a three pixel sub-component dispersion compensator in accordance with at least one embodiment of the invention.

FIG. 16 shows a four pixel sub-component dispersion compensator in accordance with at least one embodiment of the invention.

FIG. 17 shows a two pixel sub-component main beam deflector in accordance with at least one embodiment of the invention.

FIG. 18 shows a three pixel sub-component main beam deflector in accordance with at least one embodiment of the invention.

FIG. 19 shows a four pixel sub-component main beam deflector in accordance with at least one embodiment of the invention.

FIG. 20 (20A-20C) shows a two pixel sub-component light collimator in accordance with at least one embodiment of the invention.

FIG. 21 (21A-21C) shows a three pixel sub-component light collimator in accordance with at least one embodiment of the invention.

FIG. 22 (22A-22C) shows a four pixel sub-component light collimator in accordance with at least one embodiment of the invention.

FIG. 23 shows a two pixel sub-component prism array and planarization layer in accordance with at least one embodiment of the invention.

FIG. 24 shows a three pixel sub-component prism array and planarization layer in accordance with at least one embodiment of the invention.

FIG. 25 shows a four pixel sub-component prism array and planarization layer in accordance with at least one embodiment of the invention.

FIG. 26 shows a two pixel sub-component 90 degree rotation layer in accordance with at least one embodiment of the invention.

FIG. 27 shows a three pixel sub-component 90 degree rotation layer in accordance with at least one embodiment of the invention.

FIG. 28 shows a four pixel sub-component 90 degree rotation layer in accordance with at least one embodiment of the invention.

FIG. 29 shows layers of a two pixel sub-component one directional superpixel in accordance with at least one embodiment of the invention.

FIG. 30 shows layers of a three pixel sub-component one directional superpixel in accordance with at least one embodiment of the invention.

FIG. 31 shows layers of a four pixel sub-component one directional superpixel in accordance with at least one embodiment of the invention.

FIG. 32 shows layers of a four pixel sub-component two directional superpixel in accordance with at least one embodiment of the invention.

FIG. 33 (33A-33E) shows the one subregion light collimator with solid and U shaped cross section in accordance with at least one embodiment of the invention.

FIG. 34 shows layers of a one subregion one directional superpixel with a light collimator and a main beam deflector in accordance with at least one embodiment of the invention.

FIG. 35 shows layers of a one subregion superpixel with a light collimator, a main beam deflector, prism array and planarization layer in accordance with at least one embodiment of the invention.

FIG. 36 shows layers of a one subregion superpixel with a light collimator, first main beam deflector, 90 degree rotation layer, and second main beam deflector in accordance with at least one embodiment of the invention.

FIG. 37 shows layers of a one subregion superpixel with a light collimator, first main beam deflector, first prism array, first planarization layer, 90 degree rotation layer, second main beam deflector, second prism array, and second planarization layer in accordance with at least one embodiment of the invention.

FIG. 38 (38A-38D) shows an exemplary assembly, according to at least one embodiment of the invention.

FIG. 39 (39A-39C) shows a controller and assembly configuration, according to at least one embodiment of the invention.

### DETAILED DESCRIPTION

Three of the types of light information that can be captured by an imaging system or emitted by a light source include intensity, spectral and directional information. The intensity information is a measure of the number of photons reaching the imaging sensor or being emitted by the light source. Essentially, how bright the light is. The spectral information is a measure of the wavelength, small group of wavelengths, or color of the light that reaches the pixels on a detector like an imaging sensor or is emitted from a light source like the pixels on a display. The directional information is the angle with respect to the normal of a plane for example the plane of the imaging sensor or the plane of a light source like a display.

Most conventional imaging systems do not record the directional information of light as the directional information is lost during the moment of capture. In order to capture the directional information, specialized imaging systems have been developed which can capture the directional information of light using approaches like a camera array, moving a camera to multiple known positions and orientations and taking a picture at each position, or using a plenoptic camera. The camera array uses at least 2 imaging sensors which can be conventional cameras at different positions with known positions and orientations to capture images from different perspectives which contain the depth information. The problem with using the two or more imaging sensors approach is that two or more imaging sensors are needed to capture the depth information. Moving a camera usually with a conventional camera to multiple different positions and taking images at each of the different positions is another common way to capture the depth information. The disadvantage of doing the moving the camera approach is that an apparatus to move the camera to precise positions and orientations is needed which makes the combined imaging system larger, heavier, and more complicated. The plenoptic camera consists of a mains lens assembly, a micro-optical array, and an imaging sensor. The main lens assembly controls the depth of field of the light and then each element of the micro-optical array directs the light from a particular angle or small range of angles and position on the micro-optical element to a particular pixel on the imaging sensor. While the plenoptic approach does capture some angular information, the problem with this plenoptic approach is that each pixel on the imaging sensor can only measure one angle or direction of light and that angle cannot be changed. The plenoptic approach of one non-changeable angle per pixel causes there to be a tradeoff between the image quality and the number of directions measured by the imaging sensor which is not desirable in a plenoptic imaging systems.

Convention displays emit light from there pixels at a particular color over a wide field of view and in a large range of directions which results in the creation of a 2 dimensional image. In order to create a 3D image or 3D display, the direction of the light being emitted by the display is important. Each eye needs be able to see the appropriate image at a certain view point, plane, or multiple planes.

The subject of the invention includes an Active Micro-Optical System (AMOS) that can control the angle of light in one or two directions at one or more wavelengths or small groups of wavelengths that enters the top of the AMOS and exits through the bottom of the AMOS or that enters the bottom of the AMOS and exits through the top of the AMOS.

The subject of the invention includes an active micro-optical system (AMOS) that can control the angle of light in one or two directions at one or more wavelengths or small groups of wavelengths that enters the top of the AMOS and exits through the bottom of the AMOS or that enters the bottom of the AMOS and exits through the top of the AMOS. A technique can then be used called space time modulation with the AMOS in conjunction with detector like an imaging sensor or light source like a display. With respect to a detector like an imaging sensor, an image can be captured and then the angles of the AMOS can be changed one or multiple times so that the angle of light that reaches the imaging sensor's pixels are different the next time an image is captured. With respect to a light source like a display, light may be emitted from each pixel on a display, the light from the pixels may be then bent by the AMOS to the desired directions, and the angles of the light that will exit the AMOS may be then changed. The technique of capturing or emitting light and then changing the angles may be continuously repeated until the desired number of cycles is achieved.

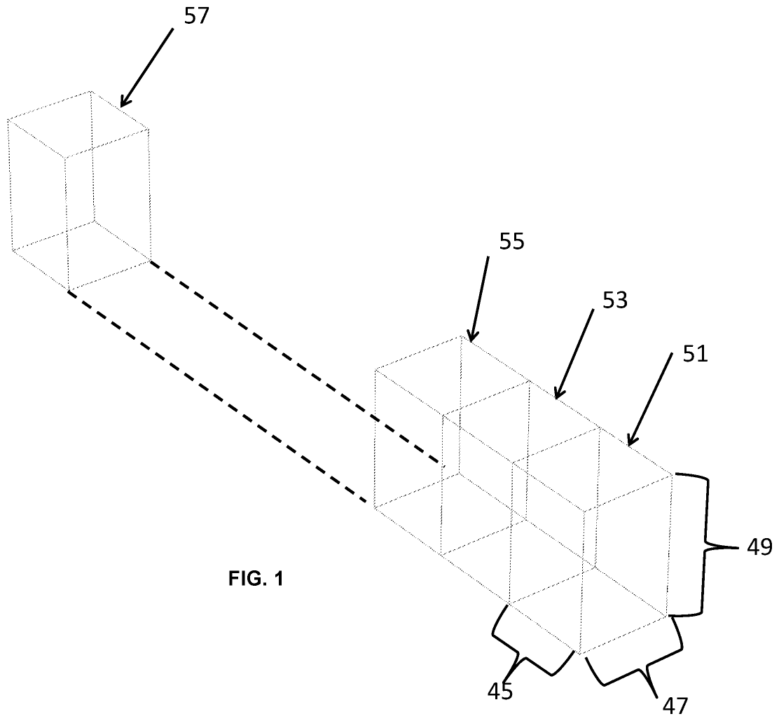

The Active Micro-optical system called AMOS in one embodiment includes a one or two dimensional array of a functional unit called a “superpixel.” The size of the AMOS array in a one dimensional array can be made up of one to Nth number of superpixels with Nth being the last superpixel in the first dimension and a number from one to infinity. A one dimensional embodiment of a AMOS is seen in FIG. 1, with superpixel 51 being the first superpixel, superpixel 53 being second superpixel, superpixel 55 being the third superpixel, and superpixel 57 being the Nth superpixel. If the one dimensional AMOS only has one superpixel, only superpixel 51 will be part of the AMOS. If more superpixels are needed in the one dimensional array then the superpixels can be added using the scheme seen in FIG. 1 starting with the second 53, then third 55, and so on. The general shape of a superpixel in one embodiment of the one dimensional array will have a square or rectangular shape with a length 45, width 47, and height 49. If the AMOS includes more than one superpixel in the one dimensional array, the length 45, width 47, and height 49 of each superpixel do not have to be the same but it is preferred if length 45, width 47, and height 49 are. The preferred size of a superpixel embodiment has a length 45 of 10 to 25 microns, a width 47 of 10 to 25 microns, and a height 49 of 100 to 400 microns.

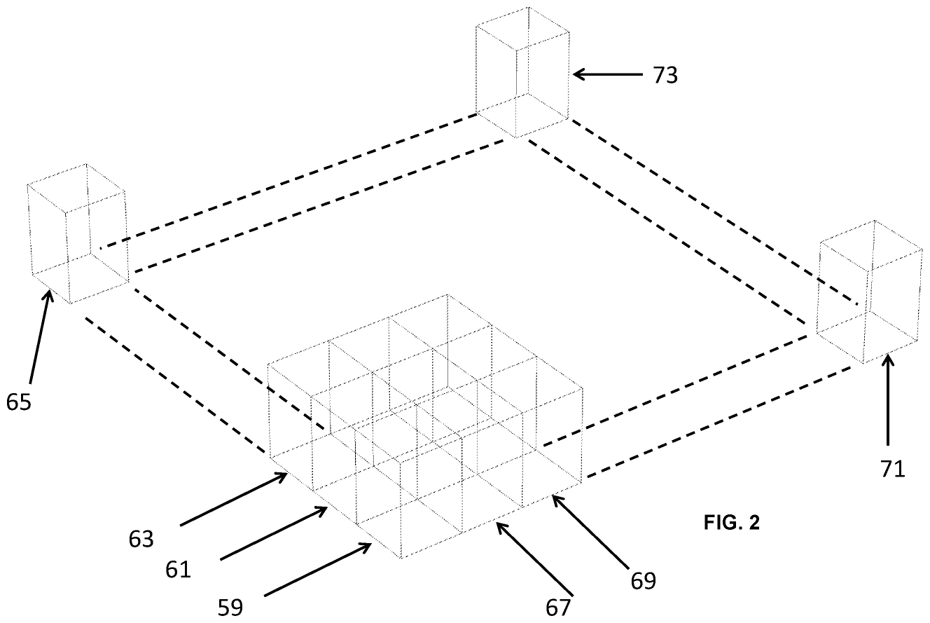

The size of an embodiment of an AMOS in a two dimensional array can be made up of one to Nth number superpixels in the first dimension with Nth being the last superpixel in the first dimension and a number from one to infinity and the size of the AMOS array. In a second dimension, the AMOS can be made up of one to Kth number superpixels with the Kth being the last superpixel in the second dimension and a number from one to infinity. The two dimensional embodiment of an AMOS can be seen in FIG. 2, with superpixel 59 being the (0, 0) superpixel, superpixel 61 being the (1, 0) superpixel, superpixel 63 being the (2, 0) superpixel, superpixel 65 being the (Nth, 0) superpixel, superpixel 67 being the (0, 1) superpixel, superpixel 69 being the (0, 2) superpixel, superpixel 71 being the (0, Kth) superpixel, and superpixel 73 being the (Nth, Kth) superpixel. The general outline of a superpixel in one embodiment of the two dimensional array will have a square or rectangular shape the same as the one dimensional array with a length 45, width 47, and height 49. If there is more than one superpixel in the two dimensional array, the length 45, width 47, and height 49 of each superpixel do not have to be the same but it is preferred if the length 45, width 47, and height 49 are. The preferred size of a superpixel embodiment has a length 45 of 10 to 25 microns, a width 47 of 10 to 25 microns, and a height 49 of 100 to 400 microns. If the two dimensional AMOS only has one superpixel, only superpixel 59 will be part of the AMOS. If more superpixels are needed in the two dimensional array then the superpixel can be added using the scheme seen in FIG. 2 starting with the second, then third, and so on in that dimension until the desired size is reached.

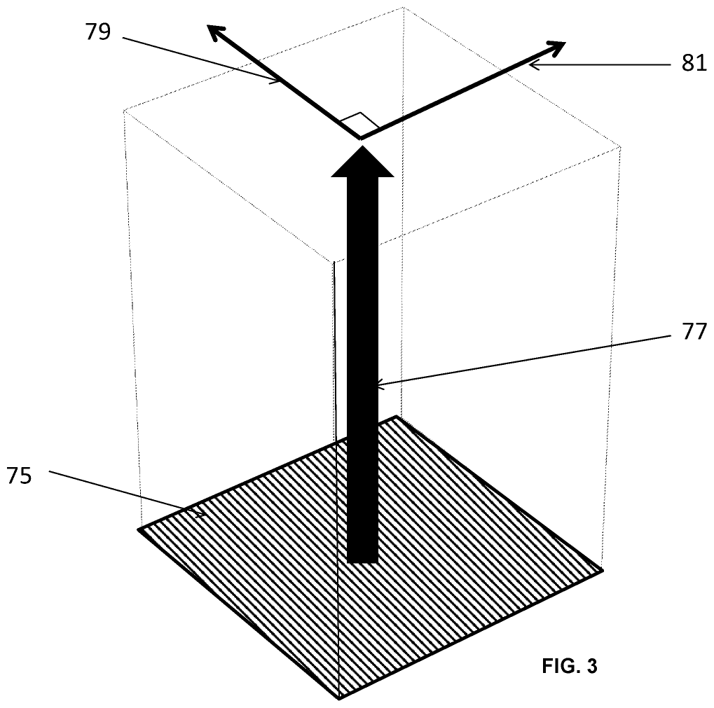

In one embodiment of a superpixel, a superpixel includes multiple layers of optical elements and devices that may be aligned and stacked on top of each other. As light travels through each layer of the superpixel, each layer of the superpixel accomplishes a specific task in bending light of two to four wavelengths or small range of wavelengths of light per superpixel in substantially one (x axis 79 or y axis 81) or 2 directions (both x axis 79 and y axis 81) that may be substantially perpendicular to the normal 77 (the light axis) of the plane of the superpixel 75 to the desired direction. See FIG. 3. Different superpixels of the AMOS can be responsible for bending two to four wavelengths or small range of wavelengths of light of the same or different wavelengths or small bands of light as other superpixels on the AMOS to the desired direction. A superpixel may be further be divided into a unit called a pixel sub-component and can be made up of 1 to 4 or more pixel sub-components. Each pixel sub-component may be a section of space at the bottom of a superpixel where one or multiple beamlets of light enters or exits the superpixel at a particular wavelength or small band of wavelengths and angle. From here on, we will use the word beamlet to describe one or multiple beamlets of light that may be in close proximity to each other in space and each beamlets may have the same or different wavelength between 10 nanometers and 3000 nanometers. The purpose of a superpixel may be based on two different cases seen below each of which has three or more subcases based on the whether the superpixel has two, three, or four pixel sub-components.

In one embodiment of a superpixel referred to as case 1, light of interest of two to four wavelengths or small range of wavelengths enters the two, three, or four pixel sub-components of the superpixel from the bottom of the superpixel. The light can for example be from pixels on a display, laser sources, or another light source. In the embodiment where the light emitting device may be a display, each pixel sub-component in one embodiment of the superpixel may be aligned over a sub-pixel or group of sub-pixels of the same or substantially similar wavelength on the display. The purpose of the superpixel then is to make sure that the two to four wavelengths that enter the 2, 3, or 4 pixel sub-components of the superpixel from the bottom pixel sub-components of the superpixel exit the top of the superpixel or a nearby superpixel (if there is one in the AMOS) all at the same or substantially similar angle and direction. There are several different subcases describing the overview of the various variations described in case 1.

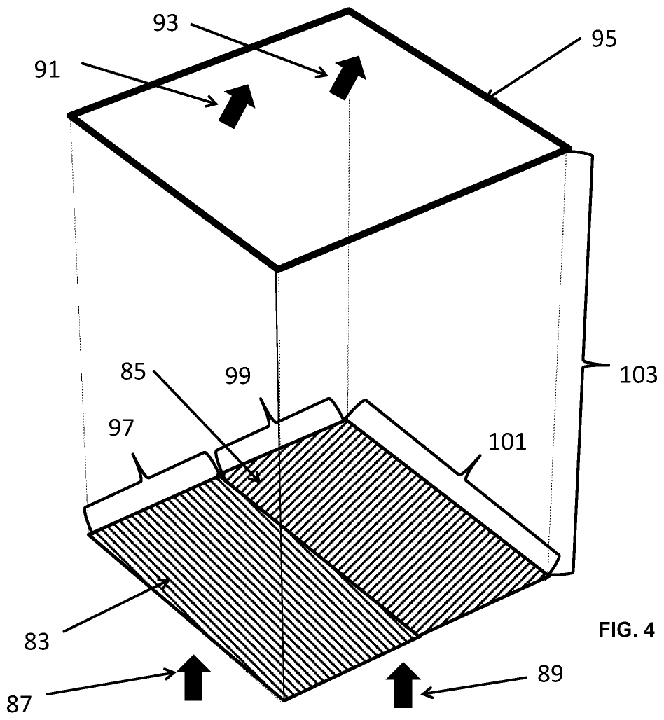

In one embodiment of a superpixel which includes two pixel sub-components and is referred to as subcase 1.1, two beamlets of light of interest enter the bottom of a two pixel subcomponents superpixel seen in FIG. 4. The first beamlet 87 of a wavelength or small range of wavelengths enters the first pixel sub-component 83 at a given angle in one (79 or 81) or two (79 and 81) directions. The first beamlet then travels through the different layers of the superpixel and exits the top of the superpixel 95 at the same or different angle in one direction 91. The second beamlet 89 of a different wavelength or small range of wavelengths enters the second pixel subcomponent 85 at a given angle in one (79 or 81) or two (79 and 81) directions and exits the top of the superpixel 95 at a substantially similar angle as the first beamlet 93. Each of the pixel subcomponent in the 2 pixel sub-component in one embodiment of the superpixel has a width with the first pixel sub-component's width 97 and the second pixel sub-component's width 99 not having to be the same but it is preferred practice if width are. The length 101 and the height 103 of the pixel sub-component in one embodiment of the two pixel sub-component superpixel may be the same.

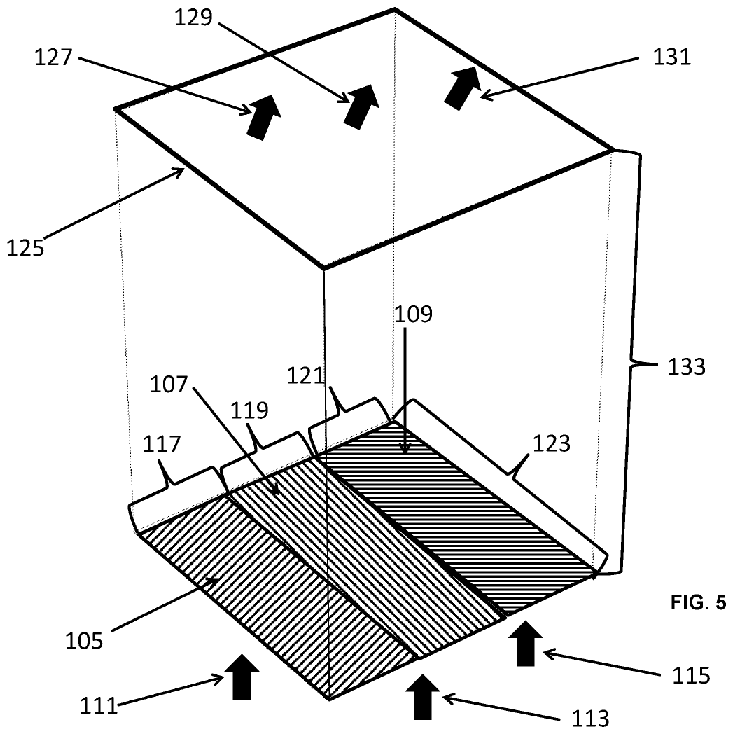

In one embodiment of a superpixel referred to as subcase 1.2 includes three pixel subcomponents with three beamlets of light of interest entering the bottom of a three pixel subcomponent superpixel and is seen in FIG. 5. The first beamlet 111 of a wavelength or small range of wavelengths enters the first pixel sub-component 105 at a given angle in one (79 or 81) or two (79 and 81) directions. The first beamlet then travels through the different layers of the superpixel and exits the top of the superpixel 125 at the same or different angle in one direction 127. The second beamlet 113 of a wavelength or small range of wavelengths enters the second pixel sub-component 107 at a given angle in one (79 or 81) or two (79 and 81) directions. The second beamlet then travels through the different layers of the superpixel and exits the top of the superpixel 125 at a substantially similar angle 129 as 127. The third beamlet 115 of a wavelength or small range of wavelengths enters the third pixel sub-component 109 at a given angle in one (79 or 81) or two (79 and 81) directions. The third beamlet then travels through the different layers of the superpixel and exits the top of the superpixel 125 at a substantially similar angle 131 as 127 and 129. If only two wavelengths or small range of wavelengths pass through the superpixel then two of the three beamlets will have the same or substantially similar wavelength or small range of wavelengths. The third beamlet will have a different wavelength or small range of wavelengths. If three wavelengths or small range of wavelengths pass through the superpixel then each beamlets will have a different wavelength or small range of wavelengths. In one embodiment of the superpixel, the width of pixel sub-component one 117, the width of pixel sub-component two 119, and the width of pixel sub-component three 121 can have the same or different widths. The height 133 and length 123 of the three pixel sub-component may be all the same or substantially similar. The three pixel sub-component superpixel includes two sub-cases based on whether the three beamlets have two or three different wavelengths or small range of wavelengths.

In one embodiment of a superpixel referred to as sub-case 1.21 includes three pixel subcomponents with three beamlets of interest at two wavelengths or small range of wavelengths passing through the superpixel embodiment. If the three beamlets only have two different wavelengths or small range of wavelengths passing through the three pixel sub-component superpixel, there are two unique options for which each beamlet of a wavelength or small range of wavelengths passes through each pixel sub-component. In the first option, two beamlets of a substantially similar wavelength pass through pixel sub-component 105 and 107 and the beamlet with a different wavelength or small range of wavelengths from the first two beamlets passes through pixel sub-component 109. In the second option, two beamlets of the same or substantially similar wavelength pass through pixel sub-component 105 and 109 and the beamlet with a different wavelength or small range of wavelengths from the first two beamlets pass through pixel sub-component 107.

In one embodiment of a superpixel referred to as sub-case 1.22 includes three pixel subcomponents with three beamlets of interest at three different wavelengths or small range of wavelengths passing through the superpixel embodiment. If the three beamlets have three different wavelengths or small range of wavelengths passing through the three pixel sub-component superpixel, there may be one unique option for which each beamlet of a different wavelength or small range of wavelengths passes through each pixel sub-component. In the first option, three beamlets of different wavelength pass through pixel sub-component 105, 107, and 109.

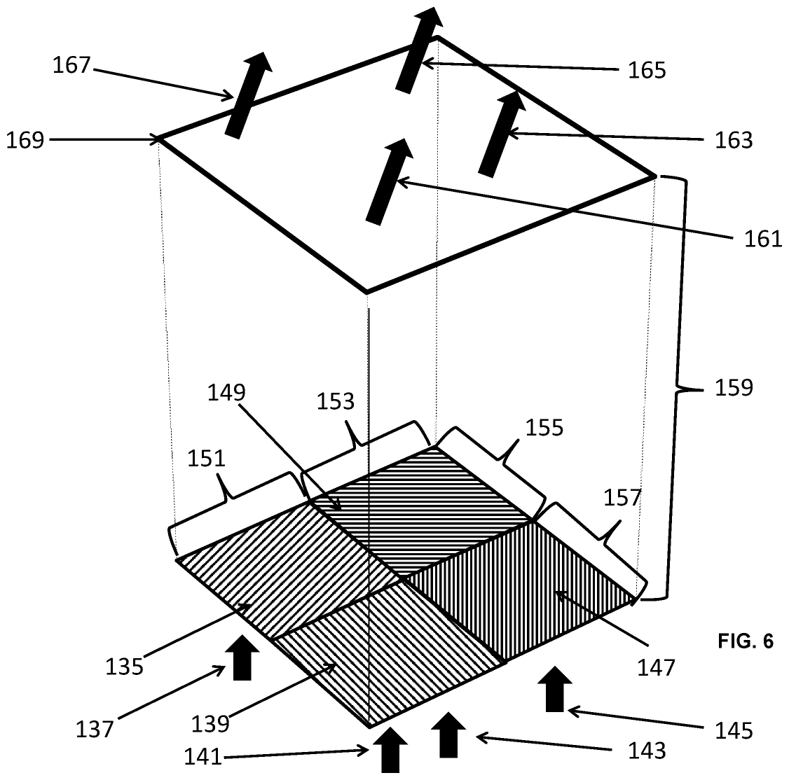

In one embodiment of a superpixel referred to as sub-case 1.30 includes four pixel subcomponents with four beamlets of interest passing through the superpixel embodiment and may be seen in FIG. 6. Four beamlets of light enter the bottom of a four pixel sub-component superpixel. The first beamlet 137 of a wavelength or small range of wavelengths enters the first pixel subcomponent 135 at a given angle in one (79 or 81) or two (79 and 81) directions. The first beamlet then travels through the different layers of the superpixel and exits the top of the superpixel 169 at the same or different angle in one (79 or 81) or two (79 and 81) directions 167. The second beamlet 141 of a wavelength or small range of wavelengths enters the second pixel sub-component 139 at a given angle in one (79 or 81) or two (79 and 81) directions. The second beamlet then travels through the different layers of the superpixel and exits the top of the superpixel 169 at the same or substantially similar angle in one (79 or 81) or two (79 and 81) directions 161 as 167. The third beamlet 145 of a wavelength or small range of wavelengths enters the third pixel subcomponent 147 at a given angle in one (79 or 81) or two (79 and 81) directions. The third beamlet then travels through the different layers of the superpixel and exits the top of the superpixel 169 at substantially the same angle in one (79 or 81) or two (79 and 81) directions 163 as 167 and 161. The fourth beamlet 143 of a wavelength or small range of wavelengths enters the fourth pixel subcomponent 149 at a given angle in one (79 or 81) or two (79 and 81) directions. The fourth beamlet then travels through the different layers of the superpixel and exits the top of the superpixel 169 at the same or substantially similar angle in one (79 or 81) or two (79 and 81) directions 165 as 167, 161, and 163. The width of pixel sub-component 135 and 139 is width 151. The width of pixel sub-component 147 and 149 is the width 153. The length of pixel subcomponent 135 and 149 is length 155. The length of pixel sub-component 139 and 147 is length 157. The preferred practice is to make 151, 153, 155, and 157 the same though it is not required. The height of superpixel 159 may be the same or substantially similar over all of the pixel subcomponents. The four pixel sub-component superpixel includes three additional sub-cases based on whether the four beamlets have two, three, or four different wavelengths or small range of wavelengths.

In one embodiment of a superpixel referred to as sub-case 1.31 includes four pixel subcomponents with four beamlets of interest at two wavelengths or small range of wavelengths passing through the superpixel embodiment. If the four beamlets only have two different wavelengths or small range of wavelengths passing through the four pixel sub-component superpixel, there are two unique options for which each beamlet of a wavelength or small range of wavelengths passes through each pixel sub-components. In the first option, two beamlets of the same or substantially similar wavelength pass through pixel sub-components 135 and 139 and the third and fourth beamlets of the same or substantially similar wavelength or small range of wavelengths that may be different wavelengths or small range of wavelengths from the first two beamlets pass through pixel sub-components 147 and 149. Option one is similar to the two pixel sub-component superpixel in FIG. 4 with an additional two beamlets. In the second option, two beamlets of the same or substantially similar wavelength pass through pixel sub-components 135 and 147 and the third and fourth beamlets of the same wavelength that may be different from the first two beamlets pass through pixel sub-components 139 and 149. In the third option, the first 135, second 139, and third 147 pixel sub-components have the same or substantially similar wavelength or small range of wavelengths and the fourth 149 pixel sub-component has a different wavelength or small range of wavelengths that the first, second, or third beamlet. Option one and three may be better for changing the angle of light in substantially one direction (79 or 81) while option two may be better for changing the angle or light in substantially two directions (79 and 81).

In one embodiment of a superpixel referred to as sub-case 1.32 includes four pixel subcomponents with four beamlets of interest at three wavelengths or small range of wavelengths passing through the superpixel embodiment. If the four beamlets only have three different wavelengths or small range of wavelengths passing through the four pixel sub-component superpixel, there are two unique options for which each beamlet of a wavelength or small range of wavelengths passes through each pixel sub-components. In the first option, two beamlets of the same or substantially similar wavelength pass through pixel sub-components 135 and 139 and the third and fourth beamlets of different wavelengths or small range of wavelengths that may be different from the first two beamlets pass through pixel sub-components 147 and 149. In the second option, two beamlets of the same or substantially similar wavelength pass through pixel sub-components 135 and 147 and the third and fourth beamlets of different wavelengths or small range of wavelengths that may be different from the first two beamlets pass through pixel subcomponents 139 and 149. The first option may be only useful for bending the light in substantially one direction (79 or 81) while the second option may be by far the most useful as three wavelengths of light can be bent in two directions (79 and 81).

In one embodiment of a superpixel referred to as sub-case 1.33 includes four pixel subcomponents with four beamlets of interest at four wavelengths or small range of wavelengths passing through the superpixel embodiment. If the four beamlets have different wavelengths or small range of wavelengths passing through each of the four pixel sub-component superpixel, there may be one unique option for which each beamlet of a wavelength or small range of wavelengths passes through each pixel sub-components. In the first option, each beamlet of a different wavelength or small range of wavelengths passes through a different pixel sub-component of the superpixel. Option 1 works well when the beamlets all have very similar wavelengths or small group of wavelengths or the beamlets wavelengths may be all in the infrared spectrum as the dispersion of refractive index is generally smaller in infrared region than in the visible or ultraviolet spectrum. The reason the superpixel is not effective with four wavelengths or small range of wavelengths in the visible or ultra violet spectrum is the larger dispersion of refractive index and the fact that the superpixel embodiment can only correct the angle of up to three wavelengths or small group of wavelengths of light in one (79 or 81) or two (79 and 81) directions.

In one embodiment of a superpixel referred to as case 2, light of interest of two to four wavelengths or small range of wavelengths enters the superpixel or a nearby superpixel (if there is one in the AMOS) from the top of the superpixel. The light can for example be from an external light source. The purpose of the superpixel then may be to make sure that only light from a particular angle or small angle range with respect to the normal 77 of the plane of the superpixel 75 of two to four wavelengths reaches the two, three, or four pixel sub-components at the bottom of the superpixel and exits the superpixel. Light that does not reach the pixel sub-components will be absorbed by the superpixel's optical elements or devices. There are several different subcases describing the overview of the various variations described in case 2.

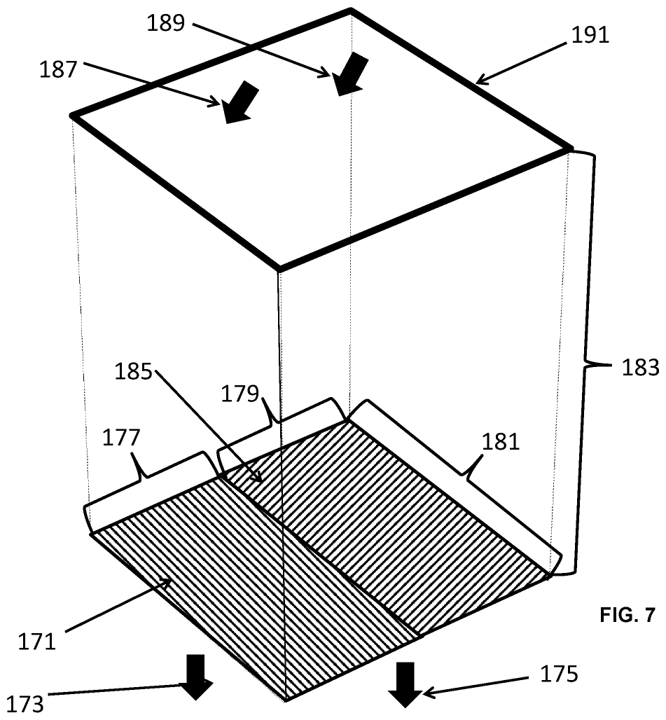

In one embodiment of a superpixel referred to as sub-case 2.1 includes two pixel subcomponents with two beamlets of interest at two different wavelengths or small range of wavelengths passing through the superpixel embodiment and is seen in FIG. 7. The two beamlets of light enter the top 191 of a two pixel sub-components superpixel or adjacent superpixel. The first beamlet 187 of a wavelength or small range of wavelengths enters the top 191 of the superpixel or top of the adjacent superpixel at a given angle in one (79 or 81) or two (79 and 81) directions. The first beamlet then travels through the different layers of the superpixel and exits the bottom of the first pixel sub-component 171 in a direction that may be near parallel to the normal 77 of the plane of the superpixel 75. The second beamlet of a wavelength or small range of wavelengths 189 that may be different than the first beamlet enters the top 191 of the superpixel or top of the adjacent superpixel at a given angle in one (79 or 81) or two (79 and 81) directions. The second beamlet 189 then travels through the different layers of the superpixel and exits 175 the bottom of pixel sub-component two 185 in a direction that may be near parallel to the normal 77 of the plane of the superpixel 75. The width 177 of first pixel sub-component 171 and the width 179 of the second pixel sub-component 185 do not have to be the same or substantially similar but it is preferred if the widths are. The length 181 and height 183 of the first 171 and second 185 pixel sub-component may be the same.

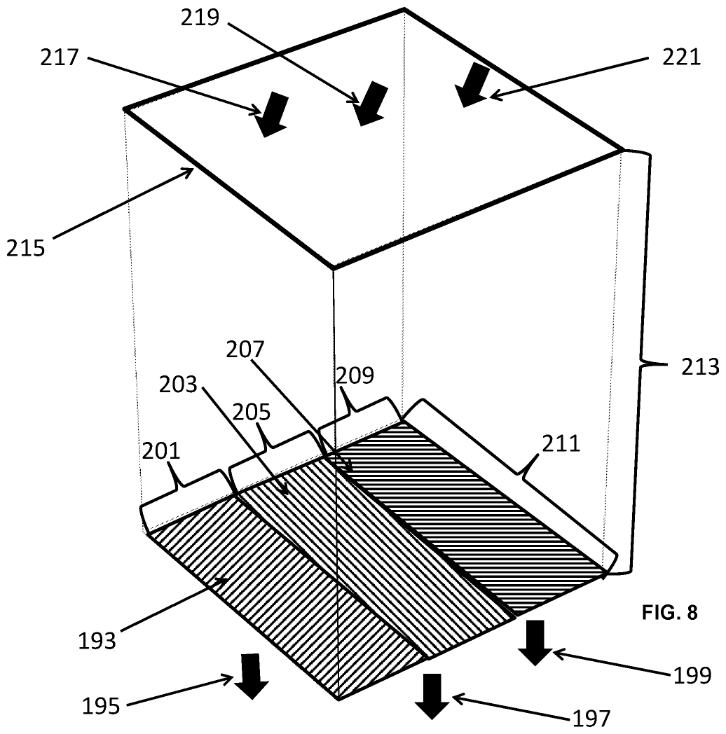

In one embodiment of a superpixel referred to as sub-case 2.2 includes three pixel subcomponents with three beamlets of interest at two different wavelengths or small range of wavelengths passing through the superpixel embodiment and is seen in FIG. 8. The three beamlets of light at a wavelength or small range of wavelengths enter the top 215 of a three pixel sub-component superpixel or adjacent superpixel seen in FIG. 8. The first beamlet 217 of a wavelength or small range of wavelengths enters the top of the superpixel 215 or top of the adjacent superpixel at a given angle in one (79 or 81) or two (79 and 81) directions. The first beamlet then travels through the different layers of the superpixel and exits 195 the bottom of the first pixel sub-component 193 in a direction that may be near parallel to the normal 77 of the plane of the superpixel 75. The second beamlet 219 of a wavelength or small range of wavelengths enters the top of the superpixel 215 or top of the adjacent superpixel at a given angle in one or two directions. The second beamlet 219 then travels through the different layers of the superpixel and exits 197 the bottom of the second pixel sub-component 203 in a direction that may be near parallel to the normal 77 of the plane of the superpixel 75. The third beamlet 221 of a wavelength or small range of wavelengths enters the top of the superpixel 215 or top of the adjacent superpixel at a given angle in substantially one (79 or 81) or two (79 and 81) directions. The third beamlet then travels through the different layers of the superpixel and exits 199 the bottom of the third pixel sub-component 207 in a direction that may be near parallel to the normal of the plane of the superpixel 75. With the three pixel sub-components superpixel embodiment at two different wavelengths or small range of wavelengths there are two unique options depending on which wavelengths or small range of wavelengths exits which of the three pixel sub-components. In option one, the first 217 and second 219 beamlet that exit the first 193 and second 203 pixel subcomponent may be the same or substantially similar wavelength or small range of wavelengths and the third 221 beamlet that exits the third 207 pixel sub-component may be a different wavelength or small range of wavelengths. In option two, the first 217 and third 221 beamlets that exit the first 193 and third 207 pixel sub-component may be the same or substantially similar wavelength or small range of wavelengths and the second beamlet 219 may be a different wavelength or small range of wavelengths. Either option one or two will work well for bending the light in substantially one direction (79 or 81). The width 201 of the first pixel sub-component 193, the width 205 of the second 203, and the width 209 of the third pixel sub-component 207 do not have to be the same or substantially similar but the device works best if the widths all are the same or substantially similar width. The height 213 and length 211 of all the pixel sub-components are the same or substantially similar.

In one embodiment of a superpixel referred to as sub-case 2.22 includes three pixel subcomponents with three beamlets of interest at three different wavelengths or small range of wavelengths passing through the superpixel embodiment. The three beamlets of light at a wavelength or small range of wavelengths enter the top 215 of a three pixel sub-component superpixel or adjacent superpixel seen in FIG. 8. The first beamlet 217 of a wavelength or small range of wavelengths enters the top 215 of the superpixel or top of the adjacent superpixel at a given angle in one (79 or 81) or two (79 and 81) directions. The first beamlet 217 then travels through the different layers of the superpixel and exits 195 the bottom of the first pixel subcomponent 193 in a direction that may be near parallel to the normal 77 of the plane of the superpixel 75. The second beamlet 219 of a wavelength or small range of wavelengths enters the top 215 of the superpixel or top of the adjacent superpixel at a given angle in one (79 or 81) or two (79 and 81) directions. The second beamlet 219 then travels through the different layers of the superpixel and exits 197 the bottom of the second pixel sub-component 203 in a direction that may be near parallel to the normal 77 of the plane of the superpixel 75. The third beamlet 221 of a wavelength or small range of wavelengths enters the top of the superpixel 215 or top of the adjacent superpixel at a given angle in one (79 or 81) or two (79 and 81) directions. The third beamlet 221 then travels through the different layers of the superpixel and exits 199 the bottom of the third pixel sub-component 207 in a direction that may be near parallel to the normal 77 of the plane of the superpixel 75. With the three pixel sub-components superpixel embodiment at three different wavelengths or small range of wavelengths, there is one unique option. Each beamlet 217, 219, and 221 that enters the top of the superpixel 215 and exits the first 193, second 203, and third 207 pixel sub-components each have a different wavelength or small range of wavelengths.

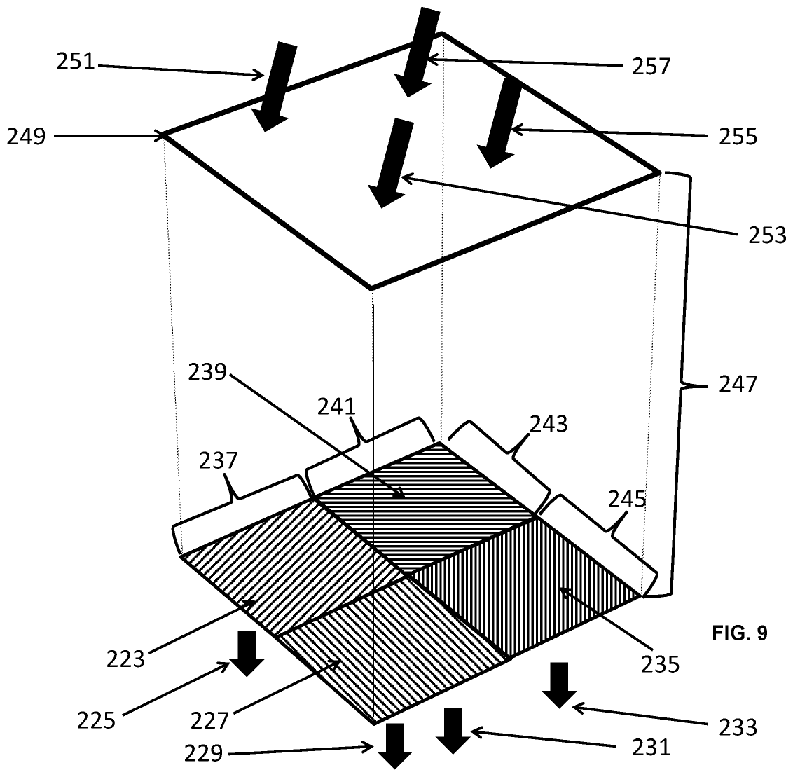

In one embodiment of a superpixel referred to as sub-case 2.30 includes four pixel subcomponents with four beamlets of interest passing through the superpixel embodiment. The four beamlets of light at a wavelength or small range of wavelengths enter the top 249 of a four pixel sub-component superpixel or adjacent superpixel seen in FIG. 9. The first beamlet 251 of a wavelength or small range of wavelengths enters the top 249 of the superpixel or top of the adjacent superpixel at a given angle in one (79 or 81) or two (79 and 81) directions. The first beamlet then travels through the different layers of the superpixel and exits 225 the bottom of the first pixel sub-component 223 may be near parallel to the normal 77 of the plane of the superpixel 75. The second beamlet 253 of a wavelength or small range of wavelengths enters the top 249 of the superpixel or top of the adjacent superpixel at a given angle in one (79 or 81) or two (79 and 81) directions. The second beamlet 253 then travels through the different layers of the superpixel and exits 229 the bottom of the second pixel sub-component 227 in a direction that may be near parallel to the normal 77 of the plane of the superpixel 75. The third beamlet 255 of a wavelength or small range of wavelengths enters the top 249 of the superpixel or top of the adjacent superpixel at a given angle in one (79 or 81) or two (79 and 81) directions. The third beamlet then travels through the different layers of the superpixel and exits 233 the bottom of the third pixel subcomponent 235 in a direction that may be near parallel to the normal 77 of the plane of the superpixel 75. The fourth beamlet 257 of a wavelength or small range of wavelengths enters the top 249 of the superpixel or top of the adjacent superpixel at a given angle in one (79 or 81) or two (79 and 81) directions. The fourth beamlet 257 then travels through the different layers of the superpixel and exits 231 the bottom of the fourth pixel sub-component 239 in a direction that may be near parallel to the normal 77 of the plane of the superpixel 75. The width 237 of pixel subcomponent one 223 and two 227 may be the same or substantially similar and the width 241 of pixel sub-component three 235 and four 239 may be also the same or substantially similar. The length 243 of pixel sub-component one 223 and four 239 may be the same or substantially similar and the length 245 of pixel sub-component 227 and 235 may be also the same or substantially similar. The preferred practice is for the lengths (243, 245) and widths (237, 241) to all be the same or substantially similar. The height 247 of all the pixel sub-components may be all the same or substantially similar. There are three sub cases of the case 2 four pixel sub-component super pixel based on the desired number of wavelengths for the four beamlets of either two, three, or four different wavelengths or small range of wavelengths. The sub cases are seen below.

In one embodiment of a superpixel referred to as sub-case 2.31 includes four pixel subcomponents with four beamlets of interest at two different wavelengths or small range of wavelengths passing through the superpixel embodiment. If only two wavelengths or small range of wavelengths exit the bottom of the four pixel sub-components in FIG. 9, then there are three unique options to the design of the superpixel. In option one, the first 223 and second 227 pixel sub-component have the same or substantially similar wavelength or small wavelength range of light passing through t first 223 and second 227 pixel sub-component and the third 235 and fourth 239 pixel sub-component also have the same or substantially similar wavelength or small range of wavelengths of light passing through third 235 and fourth 239 pixel sub-component that may be different from the first and second pixel sub-component. In option two, the first 223 and third 235 pixel sub-component have the same or substantially similar wavelength or small wavelength range and the second 227 and fourth 239 pixel sub-component also have the same or substantially similar wavelength or small range of wavelengths that may be different from the first 223 and third 235 pixel sub-components. In option three, the first 223, second 227, and third 235 pixel subcomponents have the same or substantially similar wavelength or small range of wavelengths and the fourth 239 pixel sub-component has a different wavelength or small range of wavelengths. Of the options, option one and three may be good for bending the light in substantially one direction (79 or 81) and option two may be better for bending the light in substantially two directions (79 and 81).

In one embodiment of a superpixel referred to as sub-case 2.32 includes four pixel subcomponents with four beamlets of interest at three different wavelengths or small range of wavelengths passing through the superpixel embodiment. If three wavelengths or small range of wavelengths exit the bottom of the four pixel sub-components in FIG. 9, then there are two unique options. In option one, the first 223 and second 227 pixel sub-components have the same or substantially similar wavelength or small wavelength range of wavelengths of light passing through the first 223 and second 227 pixel sub-components and the third 235 and fourth 239 pixel sub-components have different wavelength or small range of wavelengths of light passing through the third 235 and fourth 239 pixel sub-components that may be different from the first 223 and second 227 pixel sub-components. In option two, the first 223 and third 235 pixel sub-components have the same or substantially similar wavelength or small wavelength range of light passing through the first 223 and third 235 pixel sub-components and the second 227 and fourth 239 pixel sub-components have different wavelength or small range of wavelengths of light passing through the second 227 and fourth 239 pixel sub-components that may be different from the first 223 and second 227 pixel sub-components. Of the options, option one is good for bending the light in substantially one direction (79 or 81) and option two is better for bending the light in substantially two directions (79 and 81).

In one embodiment of a superpixel referred to as sub-case 2.33 includes four pixel subcomponents with four beamlets of interest at four different wavelengths or small range of wavelengths passing through the superpixel embodiment. If four different wavelengths or small range of wavelengths exit the bottom of the four pixel sub-components in FIG. 9, then there is one unique option. In option one, the first 223, second 227, third 235, and fourth 239 pixel subcomponent have different wavelengths or small wavelength ranges of light passing through The first 223, second 227, third 235, and fourth 239 pixel sub-component. Option one is good for bending the light in one (79 or 81) or two (79 and 81) directions if the light is in the near or short wave infrared region where the dispersion of refractive index is lower or the beamlets may be close in wavelengths.

From herein, case 1 and case 2 and the corresponding sub-cases and options for case 1 and 2 will be referred to as case 1 and 2.

The optical elements and devices that can be used to make up a layer of different embodiments of a superpixel are seen below numbered 1 to 9. In a superpixel embodiment, each layer accomplishes a specific task in bending light of interest to the desired direction and may be used in a given superpixel embodiment to accomplish case 1 and 2
1) Spectral filters
2) Polarizer
3) Light Collimator
4) Dispersion Compensator
5) 90 degree optical rotation layer
6) Main Beam Deflector
7) Micro-optics array
8) Planarization Layer
9) Top glass layer
   Some or all of the layers can be used one or multiple times in the order listed (from bottom to top) or in a different order to give different embodiments of a super pixel different capabilities to bend the light of interest to the desired direction.

An embodiment of a superpixel that can actively change the angle of light beamlets in substantially one (79 or 81) direction that travel through the superpixel as in case 1 or 2 may be called a one directional scanning superpixel and may include some or all the layers list below with layers 3 to 8 making up the most commonly used layers of preferred one directional scanning superpixel embodiments
1) Polarizer (If Case 1, the polarizer can be positioned here)
2) Spectral Filters

3) Light Collimator
4) Dispersion Compensator
5) Main Beam Deflector 1
6) Prism Array 1
7) Planarization Layer
8) Top glass Layer
9) Polarizer (If Case 2, the polarizer can be positioned here)

An embodiment of a superpixel that can actively change the angle of light beamlets in two (79 and 81) directions that travel through the superpixel as in case 1 or 2 may be called a 2 directional scanning superpixel and may include some or all the layers list below with layers 3 through 14 making up the most commonly used layers of preferred two directional scanning superpixel embodiments.
1) Polarizer (If Case 1, the polarizer can be positioned here)
2) Spectral Filters
3) Light Collimator
4) Dispersion Compensator 1
5) 90 degree Light Rotation layer 1
6) Dispersion Compensator 2 (may be oriented at 90 degrees to the first Dispersion Compensator)
7) Main Beam Deflector 1
8) Prism array 1
9) Planarization Layer 1
10) 90 degree Light Rotation layer 2
11) Main Beam Deflector 2
12) Prism array
13) Planarization Layer
14) Top glass Layer
15) Polarizer (If Case 2, the polarizer can be positioned here

A brief description of the purpose of each layer is seen below.

Embodiments of a superpixel may contain a polarizer which may be used to polarize the light to so the light's polarization may be substantially perpendicular to the length of the electrodes of the nearest dispersion compensator or main beam deflector.

Embodiments of a superpixel may contain a spectral filters. The spectral filters may function to allow light of only certain wavelength or wavelength range to pass through the spectral filters. The spectral range of the spectral filters can be between 10 nanometers and 3000 nanometers.

Embodiments of a superpixel may contain a light collimator. The light collimator may be designed to only allow light to travel through the light collimator if the angle and path of the light at a particular wavelength may be substantially close to the normal to the plane of the super pixel. The light collimator may be fabricated on a substrate of an optically transparent material that is as thin as possible like ultrathin glass or plastic. An optically opaque grid may be then fabricated on top of the optically transparent substrate which could be made out of optically opaque photoresist. The fill between the grid where the light travels through may be made of an optically transparent material like transparent photoresist. Light that does not have a direction and angle substantially close to the normal of the plane of the super pixel, collides with the optically opaque side grid and may be substantially absorbed. The taller the height of the optically opaque grid the smaller the angle range of light that may be substantially normal 77 to the plane of the superpixel 75 that can pass through the light collimator.

Embodiments of a superpixel may contain one or more dispersion compensators. The dispersion compensator may be designed to change the angle and trajectory of light beamlets in substantially one direction that enters and exits the superpixel using electro-optical deflectors and NCMs so that light of two or more wavelengths that enter and exit the superpixel exits the superpixel in the same or substantially similar angle in substantially one direction (79 or 81) or two directions (79 and 81).

Embodiments of a superpixel may contain a main beam deflector. The main beam deflector may be designed to change the angle and trajectory of light substantially in one direction (79 or 81) that enters or exits the superpixel. The amount of change in angle and trajectory of the light may be based on the magnitude gradient in refractive index across the main beam deflector and height of the main beam deflector. The magnitude in the gradient in refractive can be cause by applying a voltage on electrodes in proximity to an electro-optical material like a liquid crystal. The magnitude of the gradient in refractive index can be changed by changing the voltages on the electrodes and hence the electric field across the electro-optical material. Another important feature is that the lights polarization as the light passes through the main beam deflector may be substantially parallel to the gradient in refractive index across the main beam deflector. If 2 main beam deflectors are used in a design, the main beam deflectors may be positioned so that the main beam deflector's electrodes may be perpendicular to each other and hence the main beam deflector's gradient in refractive indexes may be perpendicular to each other.

Embodiments of a superpixel may contain a prism array. The prism array includes a triangular or round prism with an angle which determines the angular range in substantially one direction (79 or 81) that will be able to exit and enter the superpixel as in case 1 and 2. The prism array may have a higher refractive index than the planarization layer and the magnitude of the difference in refractive index of the prism array and the planarization layer substantially affect the angular range.

Embodiments of a superpixel may contain a planarization layer. The planarization layer's purpose includes planarizing or flattening the prism array layer so additional layers can be built on the planarization layer.

Embodiments of a superpixel may contain a 90 degree rotation layer: The 90 degree rotation layer's purpose includes rotating the polarization of the light by 90 degrees or substantially close to 90 degrees. The 90 degree rotation layer may be used to make sure that the polarization of the light that enters a main beam deflector underneath the 90 degree rotation layer is parallel or near parallel to the main beam deflector or dispersion compensators potential gradient in refractive index. The 90 degree rotation layer may be used when two main beam deflectors or dispersion compensators are used in a superpixel. The 90 degree rotation layer can utilize a liquid crystal layer which is the preferred practice or birefringent material to rotate the light 90 degrees or substantially close to 90 degrees.

Embodiments of a superpixel may contain a top glass layer. The top glass layer's purpose includes to be highly transparent and allow light to pass through the superpixel embodiment to or from the lower layers of the superpixel. The top glass layer also can act as a protective layer and mechanical support for the other layers of the super pixel to be built on.

Embodiments of a superpixel and layers that make up an embodiment of a superpixel may contain various possible electrode configurations. The various electrode configurations can be used to create an electric field across the materials in the dispersion compensator and main beam deflector layers. A two, three, four or more electrode configuration may be used. In addition, each pixel sub-component for the dispersion compensator layer and all of the pixel sub-components for the main beam deflector may have the same or different electrode configuration. In the dispersion compensator, different pixel sub-components electrodes of adjacent pixel sub-components in the same super pixel can be electrically connected together length and/or width wise depending on the electrode configuration which is the preferred practice. The electrodes of pixel sub-components on adjacent superpixels can also be electrically connected together which is the preferred practice to reduce the number of electrical connections. The best electrode practice for the superpixels on the AMOS is to use a four electrode configuration in each pixel sub-component of the dispersion compensators and all of the pixel sub-components for the main beam deflectors and electrically connect then together length wise along that entire layer of the AMOS in order to reduce the number of external electrical connections required. Later drawings of the dispersion compensator and main beam deflector show the four electrode configuration due to the four electrode configuration being the preferred practice but the other electrode configurations can also be used.

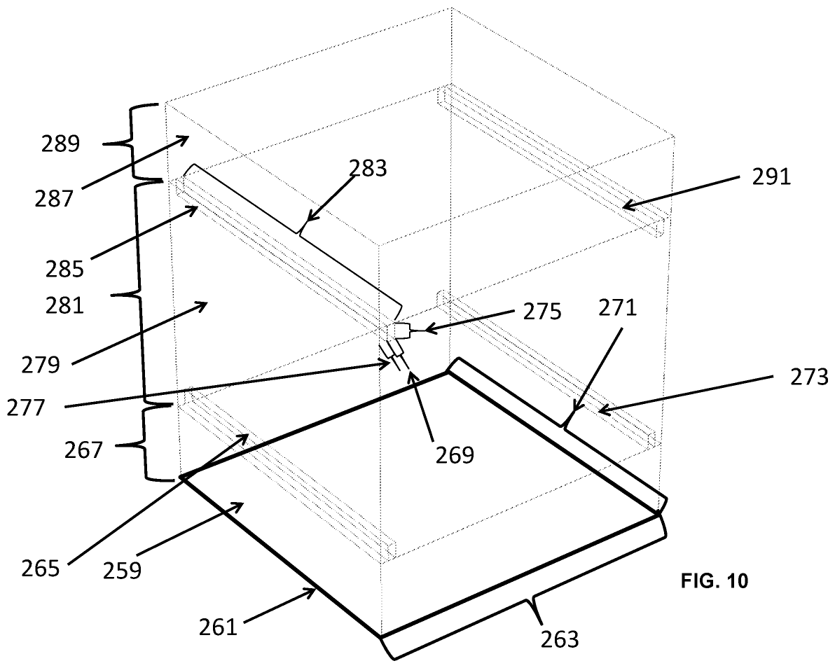

FIG. 10 shows an embodiment of a four electrode configuration for a pixel sub-component in a dispersion compensator 261 or over all of the pixel sub-components for a main beam deflector 261. The electrodes one 265 and two 273 may be built on a bottom piece of transparent material 259 of a thickness 267, width 263, and length 271. The electrodes three 285 and four 291 may be built on a top piece of transparent material 287 like glass of a thickness 289, width 263, and length 271. The four electrodes can have a small distance 277 from the edge of the superpixel. The small distance 277 does not have to be the same or substantially similar for each of the four electrodes but it is preferred if small distances are all the same or substantially similar. If the small distance for a given electrode is made to be substantially close to zero then an electrode in that pixel sub-component 261 or superpixel layer 261 and the small distance for another adjacent electrode on an adjacent pixel sub-component or superpixel is made to be substantially close to zero then an electrode in that pixel sub-component 261 or superpixel layer 261 can be electrically connected or shared with an adjacent pixel sub-component 261 or superpixel layer 261. One or all of the four electrodes can also be embedded into the transparent material 259 or 287 if desired. Each electrode has a width 269, length 283, and height 275. The width 269 and height 275 of the electrodes do not need to be the same or substantially similar but it is preferred if the widths and heights all are. The length 283 of the four electrodes all may be the same or substantially similar. The material 279 between the top 287 and bottom 259 transparent material and around the four electrodes 265, 273, 285, and 291 in the dispersion compensator can be either an electro-optical material like a liquid crystal or electro-optical crystal or a material whose refractive index negligibly changes (NCM) when an electric field is applied across material 279. In the main beam deflector, the material 279 is all an electro-optical material. During operation, static or dynamic changing voltages may be applied to each of the four electrodes in order to create an electric field across the material 279.

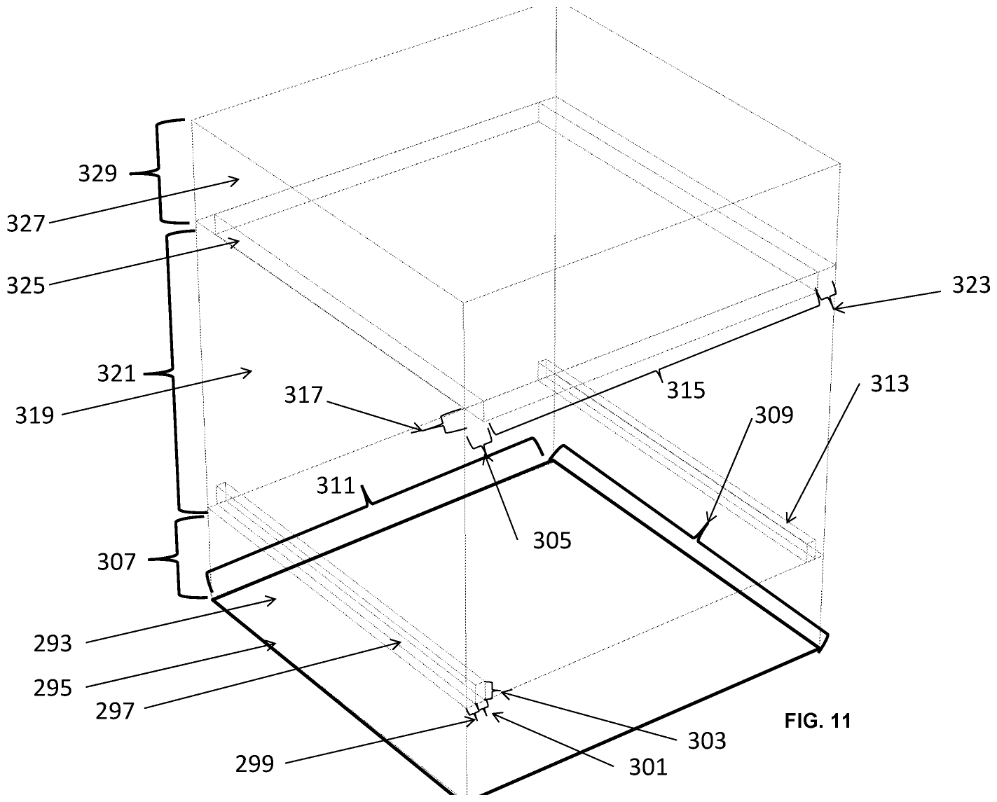

FIG. 11 shows an embodiment of a three electrode configuration for a pixel subcomponent in the dispersion compensator 295 or over all of the pixel sub-components for a main beam deflector 295. The electrodes one 297 and two 313 may be built on a bottom piece of a transparent material 293 of a thickness 307, width 311, and length 309. The third electrode 325 may be built on a top piece of transparent material 327 like glass of a thickness 329, width 311, and length 309. The first 297 and second 313 electrodes can have a small distance 299 from the edge of the superpixel. The small distance 299 does not have to be the same or substantially similar for the first 297 or second 313 electrodes but it is preferred if the small distances are all the same or substantially similar. If the small distance from the first or second electrode is made to be substantially close to zero then an electrode in that pixel sub-component 295 for a dispersion compensator or over all the pixel sub-components for the main beam deflector 295 and the small distance 299 for another adjacent electrode is made to be substantially close to zero then an electrode in that pixel sub-component 295 or superpixel layer 295 can be electrically connected (which increases the width of the first or second electrode) or shared with the adjacent pixel subcomponent 295 or superpixel layer 295. The third electrode 325 with a width 315, length 309, and height 317 has a small distance 305 and 323 away from the edge of the superpixel. If the small distance 305 or 323 is made to be substantially close to zero then an electrode in that pixel subcomponent 295 for a dispersion compensator or over all the pixel sub-components for the main beam deflector 295 and the small distance 299, 305, or 323 for another adjacent electrode on an adjacent superpixel is made to be zero then an electrode in that pixel sub-component 295 or superpixel layer 295 can be electrically connected (which increases the width of the electrode) with the electrode in the adjacent pixel sub-component 295 or superpixel layer 295.

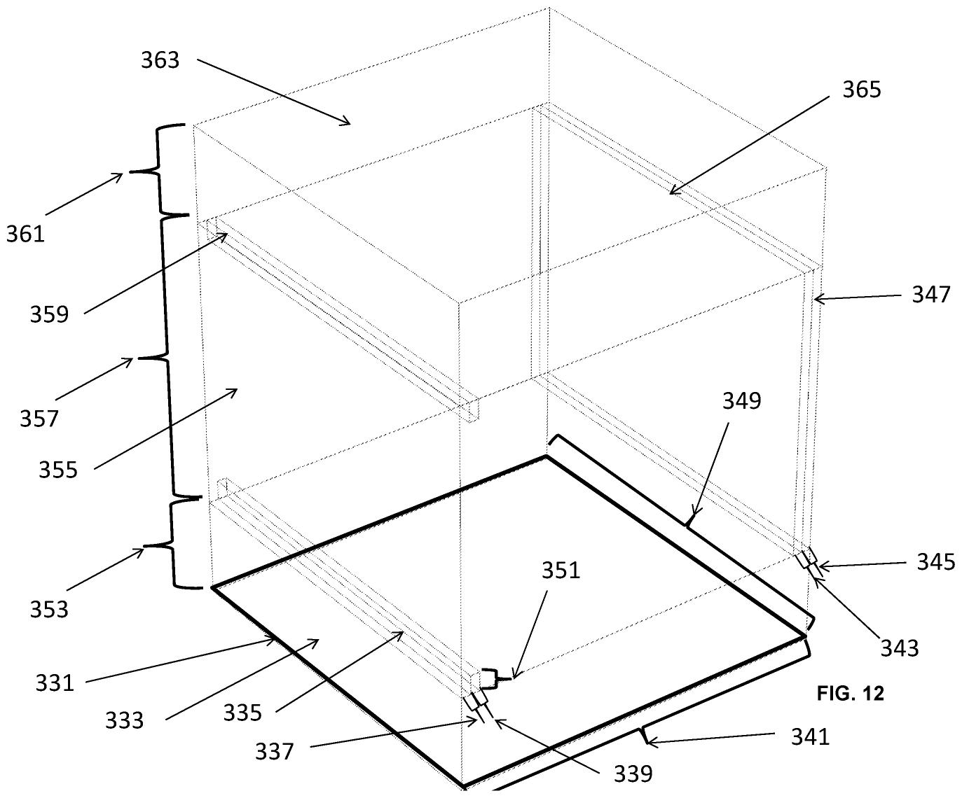

FIG. 12 shows another embodiment of a three electrode configuration for a pixel subcomponent in the dispersion compensator 331 or over all of the pixel sub-components for a main beam deflector 331. The first electrode 335 may be built on a bottom piece of a transparent material 333 with a width 339, length 349, and height 351. The first electrode can be a small distance 337 away from the edge of the superpixel. If the small distance 337 is made to be substantially close to zero and small distance 337 of an electrode on an adjacent subregion or superpixel is also made to be substantially close to zero then the first electrode can be shared and electrically connected to the electrode on the adjacent subregion or superpixel. Connecting electrodes widthwise in adjacent pixel sub-components or superpixels can be beneficial to reduce the number of electrical connections. The second electrode 359 may be built on a top piece of a transparent material 363 with a width 339, length 349, and height 351. The width 339 and height 351 of the second electrode 359 do not have to be the same or substantially similar as the first electrode 335 but the length 349 of the electrodes may be both the same or substantially similar. The second electrode can also be a small distance 337 away from the edge of the subregion or superpixel. If the small distance 337 is made to be substantially close to zero and small distance 337 of an electrode on an adjacent subregion or superpixel is also made to be substantially close to zero then the first electrode 335 can be shared and electrically connected to the electrode on the adjacent superpixel. Connecting electrodes widthwise in adjacent pixel sub-components or superpixels can be beneficial to reduce the number of electrical connections. The third electrode 365 has a length 349, width 343, and height 357. The third electrode 365 is sandwiched between the top 363 and bottom 333 transparent material and can be a small distance 345 away from the edge of the superpixel. If the small distance 345 is made to be substantially close to zero and small distance 337 of an electrode on an adjacent subregion or superpixel is also made to be substantially close to zero then the third electrode 365 can be shared and electrically connected to the electrode on the adjacent subregion or superpixel. If the small distance 345 is not zero then the material 347 with a width 345, length 349, and height 357 can either be an electro-optical material or an electrically insulating material. The material 355 is either an electro-optical material like a liquid crystal or electro-optical crystal or a material that has a negligible change in refractive index (NCM) when an electric field is applied across material 355 in a pixel sub-component in the dispersion compensator. The material 355 may be only an electro-optical material across all of the pixel sub-components in the main beam deflector.

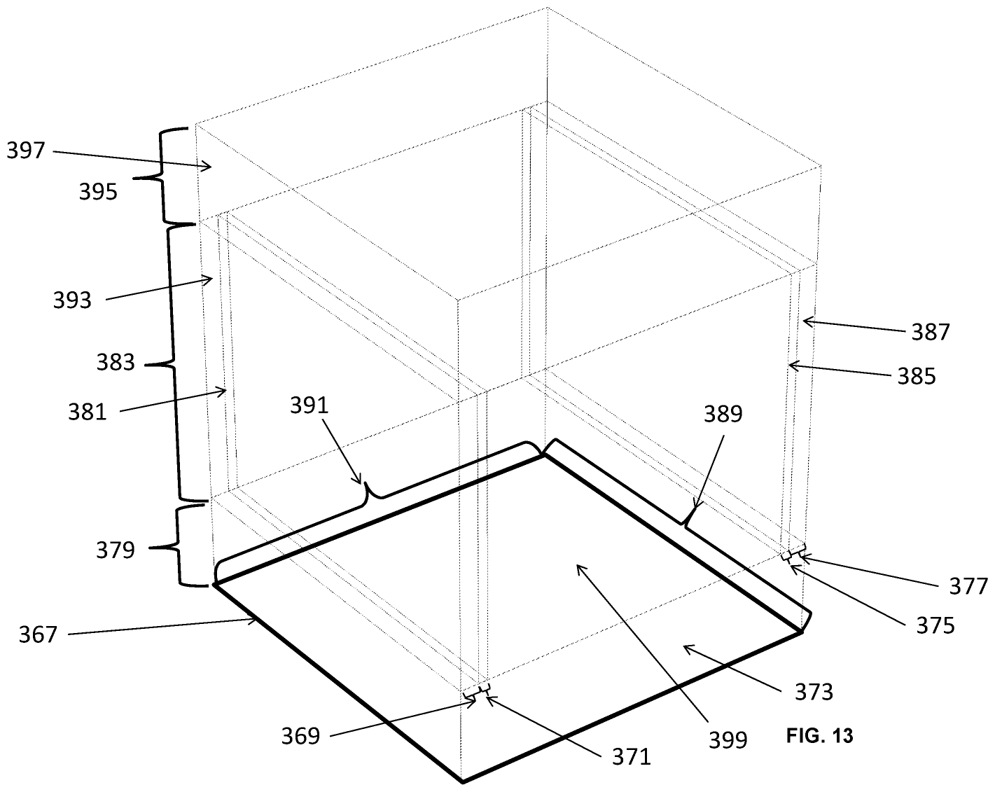

FIG. 13 shows an embodiment of a two electrode configuration for a pixel sub-component 367 in the dispersion compensator or over all of the pixel sub-components 367 for a main beam deflector. The first electrode 381 may be built between a top 397 and bottom 373 piece of a transparent material with a width 371, length 389, and height 383. The bottom piece 373 of transparent material has a width 391, length 389, and height 379 and the top piece 397 of transparent material has a width 391, length 389, and height 395. The first electrode 381 can be a small distance 369 away from the edge of the subregion or superpixel. If the small distance 369 is made to be substantially close to zero and small distance 369 of an electrode on an adjacent pixel sub-component or superpixel is also made to be substantially close to zero then the first electrode can be shared and electrically connected to the electrode on the adjacent subregion or superpixel. If the small distance 369 is not zero then the material 393 with a width 369, length 389, and height 383 can either be an electro-optical material or an electrically insulating material. The second electrode 385 may be also built between a top 397 and bottom 373 piece of a transparent material with a width 375, length 389, and height 383. The second electrode 385 can also be a small distance 377 away from the edge of the subregion or superpixel. If the small distance 377 is made to be substantially close to zero and small distance 377 of an electrode on an adjacent pixel subcomponent or superpixel is also made to be substantially close to zero then that electrode can be shared and electrically connected to the electrode on the adjacent subregion or superpixel. If the small distance 377 is not zero then the material 387 with a width 377, length 389, and height 383 can either be an electro-optical material or an electrically insulating material. The material 399 may be either an electro-optical material like a liquid crystal or electro-optical crystal or a material that has a negligible change in refractive index when an electric field is applied across material 399 in a pixel sub-component in the dispersion compensator. The material 399 may be only an electro-optical material across all of the pixel sub-components in the main beam deflector.

In one embodiment of the invention that can make up one or two layers of a superpixel includes dispersion compensator 921 as described herein. In one embodiment, dispersion compensator 921 may be needed in the superpixel designs because the refractive index of nearly all materials is dependent on the wavelength of light. Different wavelengths or small bands of light may get their angle with respect to the normal 77 of the plane of the superpixel 75 modified differently as the light of two to four wavelengths or small bands of light pass through different layers of the superpixel. The dispersion compensator provides a corrective angle adjustment to one or two of the two to four wavelengths or narrow bands of light in substantially one direction (79 or 81) that may be substantially perpendicular to the normal 77 of the plane of the superpixel 75. The corrective angle adjustment may be done so that the final angle of the two to four wavelengths that exits the top or bottom of the superpixel as in case 1 or case 2 (described herein) may be the same or substantially similar. In one embodiment, dispersion compensator 921 may be configured to provide one or more corrective angle adjustments. The corrective angle adjustments may be accomplished by using one to three electro-optical deflectors that may be over one to four of the two to four pixel sub-components of the dispersion compensator. The two to three electro-optical deflectors may all use a two, three, or four electrode scheme or a combination of different electrode schemes depending on the design of the dispersion compensator. The same or different voltage waveforms may be applied to the electrodes to create an electric field across the electro-optic material like a liquid crystal or electro-optic crystal in the electro-optic deflector that can cause a gradient in refractive index across the electro-optic material when an electric field may be applied across the electro-optic material. The gradient of the refractive index of the electro-optic deflectors may be perpendicular or substantially perpendicular to the normal of the plane of the superpixel 75. The two, three, and four pixel sub-component dispersion compensator are described herein.

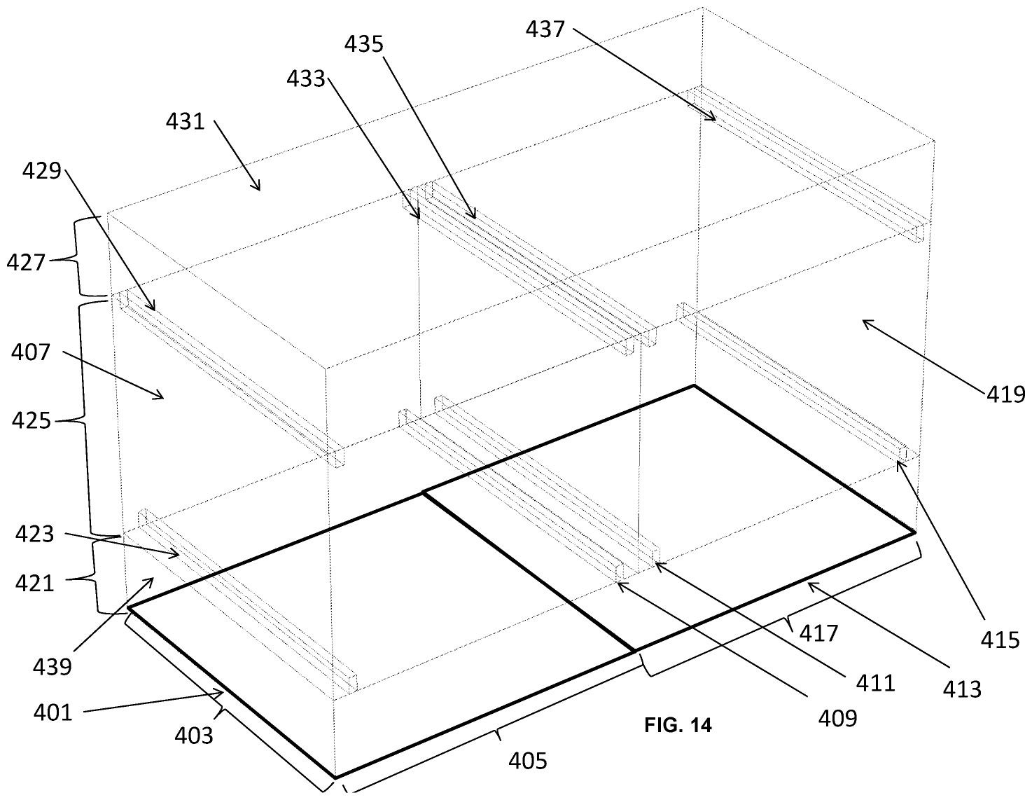

One embodiment of a dispersion compensator uses a two pixel sub-component design. FIG. 14 shows the two pixel sub-component dispersion compensator. The two pixel subcomponent dispersion compensator may be made on a top 431 and bottom 439 piece of transparent material like glass with a length 403 and width (405 plus 417). The thickness 427 of the top transparent material 431 and the thickness 421 of the bottom transparent material 439 do not have to be the same or substantially similar but it is preferred if the transparent materials are as thin as possible. The first pixel sub-component 401 has a width 405 and length 403 and the second pixel sub-component 413 has a width 417 and length 403. The two pixel sub-components, called the first 401 and second 413 pixel sub-component, may be aligned over the first and second pixel sub-components located on layers of the superpixel that may be above or below the dispersion compensator. The length and width of a pixel sub-component in the dispersion compensator and length and width of the same pixel sub-component on a different layer of the superpixel in the same superpixel may be the same or substantially similar length and width dimensions. Each pixel sub-component on the two pixel sub-component dispersion compensator shown in FIG. 14 has a four electrode configuration. The four electrode configuration over each pixel sub-component is only one of the electrode configuration possibilities and the two and three electrode configurations over each pixel sub-component described herein could also be used. Over the first pixel sub-component 401, the same or different voltage wave forms may be applied to electrodes one 423, two 409, three 429, and four 433 in order to create an electric field across the material 407. The material 407 can either be an electro-optical material like a liquid crystal or electro-optical crystal or a material that will have a negligible change in its refractive index when an electric field is applied across it called a negligible change material (NCM). Over the second pixel sub-component 413, electrode five 411, six 415, seven 435, and eight 437 may be used in order to create an electric field across the material 419. The material 419 can also either be an electro-optical material like a liquid crystal or electro-optical crystal or a NCM. The height 425 of material 407 and 419 is important as if material 407 or 419 is an electro-optical material as the height 425 will be directly related to the optical path length of light of a given wavelength or small range of wavelengths. The optical path length may be important because when an electric field is applied across the electro-optical material, the electric field can create a gradient in the electro-optical material's refractive index across the electro-optical material substantially perpendicular to the length of the electrodes. The longer the optical path length, the larger the change in angle in substantially one direction (79 or 81) will be. The magnitude of the gradient of refractive index and the optical path length of the light will change the angle of light in substantially one direction (79 or 81). The magnitude of the gradient in refractive index may be controlled by the magnitude of the electric field applied across the electro-optical material. The combination of the electrodes and electro-optical material is called an electro-optical deflector. The NCM material may have electrodes around the NCM material but the electrodes are not required to be around a NCM in the two pixel sub-component dispersion compensator even if the electrodes are seen in FIG. 14 though it is preferred if the electrodes are included around a NCM in the two pixel sub-component dispersion compensator. The two pixel sub-component dispersion compensator may be used to make sure that the beamlets of two wavelengths or small range of wavelengths that exit the top or bottom of the superpixel as in case 1 and 2 both have the same or substantially similar angle. To make sure that the beamlets exit the top or bottom of the superpixel as in case 1 and 2 both have the same or substantially similar angle, the materials that make up material 407 and 419 can be changed from either an electro-optical material or an NCM based on the two unique cases below for the two pixel sub-component dispersion compensator as described herein as case 3.1 and 3.2.

In an embodiment of the two pixel sub-component dispersion compensator called case 3.1, material 407 and 419 may be both an electro-optical material. The case 3.1 configuration is preferred when each of the two beamlets of light of two different wavelengths or small range of wavelengths of light entering or exiting the superpixel and the dispersion compensator each have different angles in substantially one direction (79 or 81) and the angle of each beamlet in substantially one direction needs to be independently corrected. The gradient in refractive index across material 407 and material 419 may be changed so that the gradient in refractive index across material 407 and 419 modify the angle of light of each beamlet so that each beamlet exit the top or bottom of the superpixel at the same or substantially similar angle as in case 1 and 2.

In an embodiment of the two pixel sub-component dispersion compensator called case 3.2, material 407 may be an electro-optical material and material 419 may be a NCM. The case 3.2 configuration is preferred when each of the two beamlets of light of two different wavelengths or small range of wavelengths of light entering or exiting the superpixel and the dispersion compensator each have different angles in one direction (79 or 81) and the angle of only one beamlet in the superpixel in substantially one direction needs to be independently corrected. The beamlet traveling through the material 419, the NCM, and second pixel sub-component 413 will not have beamlet's angle modified. The appropriate voltages can then be placed on electrodes one to four of the first pixel sub-components electro-optical deflector in order to correct the angle of the first beamlet so the first beamlet exits the top or bottom of the superpixel at the same or substantially similar angle as the second beamlet that traveled through the NCM as in case 1 and 2.

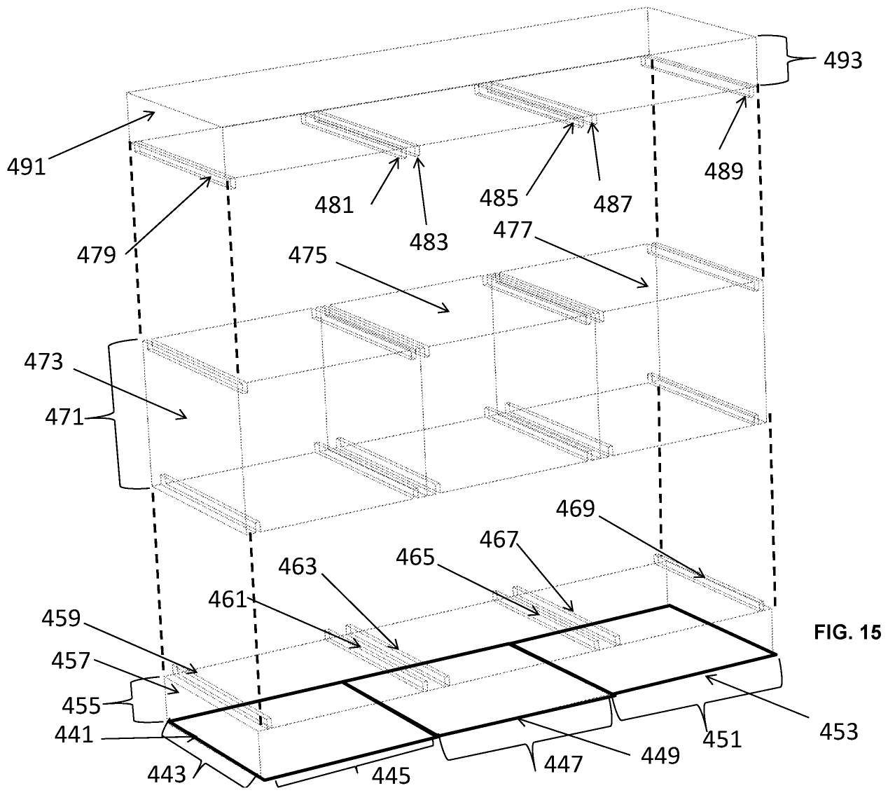

One embodiment of a dispersion compensator uses a three pixel sub-component design. FIG. 15 shows an embodiment of a three pixel sub-component dispersion compensator. The dispersion compensator embodiment may be made on a top 491 and bottom 457 piece of transparent material like glass with a length 443 and width (445 plus 447 plus 451). The thickness 493 of the top transparent material 491 and the thickness 455 of the bottom transparent material 457 do not have to be the same or substantially similar but it is preferred if the transparent materials are as thin as possible. The first pixel sub-component 441 has a width 445 and length 443, the second pixel sub-component 449 has a width 447 and length 443, and the third pixel subcomponent 453 has a length 443 and width 451. The widths of the three pixel sub-components can be different but the length of the pixel sub-components must all be the same or substantially similar for a given three pixel sub-component dispersion compensator in a given superpixel. The three pixel sub-components, called the first 441, second 449, and third 453 pixel sub-component, may be aligned over the first, second, and third pixel sub-components located on layers of the superpixel that may be above or below the dispersion compensator. The length and width of a pixel sub-component in the dispersion compensator and length and width of the same or substantially similar pixel sub-component on a different layer of the superpixel in the same superpixel may be the same or substantially similar length and width dimensions. Each pixel subcomponent on the three pixel sub-component dispersion compensator shown in FIG. 15 has a four electrode configuration. The four electrode configuration over each pixel sub-component is only one of the electrode configuration possibilities and the two and three electrode configurations over each pixel sub-component described herein could also be used. Over the first pixel subcomponent 441, the same or different voltage wave forms may be applied to electrodes one 459, two 461, three 479, and four 481 in order to create an electric field across the material 473. The material 473 can either be an electro-optical material like a liquid crystal or electro-optical crystal or an NCM. Over the second pixel sub-component 449, electrode five 463, six 465, seven 483, and eight 485 may be used in order to create an electric field across the material 475. The material 475 can also either be an electro-optical material like a liquid crystal or electro-optical crystal or a NCM. Over the third pixel sub-component 453, electrode nine 467, ten 469, eleven 487, and twelve 489 may be used in order to create an electric field across the material 477. The material 477 can either be an electro-optical material like a liquid crystal or electro-optical crystal or a NCM. The height 471 of material 473, 475, and 477 is important as if material 473, 475 or 475 is an electro-optical material, as the height 471 of material 473, 475, and 477 will be directly related to the optical path length of light of a given wavelength or small range of wavelengths. The optical path length may be important because when an electric field is applied across the electro-optical material, the electric field may create a gradient in electro-optical material's refractive index across the electro-optical material substantially perpendicular to the length of the electrodes. The longer the optical path length, the larger the change in angle in substantially one direction (79 or 81) will be. The magnitude of the gradient of refractive index and the optical path length of the light will change the angle of light in substantially one direction (79 or 81). The magnitude of the gradient in refractive index may be controlled by the magnitude of the electric field applied across the electro-optical material. The NCM material(s) may have electrodes around the NCM material but the electrodes are not required to be around the NCM(s) in the three pixel sub-component dispersion compensator even if the electrodes are seen in FIG. 15 though it is preferred if the electrodes are around the NCM(s) in the three pixel sub-component dispersion compensator. The three pixel sub-component dispersion compensator may be used to make sure that the three beamlets of two or three wavelengths or small range of wavelengths that exit the top or bottom of the superpixel as in case 1 and 2 both have the same or substantially similar angle. To accomplish the beamlets exiting the top or bottom of the superpixel as in case 1 and 2 both having the same or substantially similar angle, the materials that make up material 473, 475, and 477 can be changed from either an electro-optical material or an NCM based on the unique cases described herein called case 4.1, case 4.2, case 4.3, case 4.4, case 4.5, and case 4.6.

In one embodiment of a three pixel sub-component dispersion compensator called case 4.1, material 473, 475, and 477 may be all an electro-optical material. The case 4.1 configuration is preferred when each of the three beamlets of light have either one of two different wavelengths or small range of wavelengths of light entering or exiting the superpixel and the dispersion compensator each have different angles in substantially one direction (79 or 81) and the angle of each beamlet in substantially one direction needs to be independently corrected. The gradient in refractive index across material 473, 475, and material 477 may be changed so that the gradient in refractive index across material 473, 475, and material 477 may be modifies the angle of light of each beamlet so that the beamlets exit the top or bottom of the superpixel at the same or substantially similar angle as in case 1 and 2.

In one embodiment of a three pixel sub-component dispersion compensator called case 4.2, material 473 and 475 may be an NCM and material 477 may be an electro-optical material. The case 4.2 configuration is preferred when the two beamlets with the same or substantially similar wavelength or small range of wavelengths pass through pixel sub-component one 441 and two 449 at the same or substantially similar angle in substantially one direction (79 or 81). The third beamlet at a wavelength or small range of wavelengths that may be different from the first and second beamlets travels through material 477 and the third beamlet's angle may be adjust in substantially one direction by changing the voltages on electrodes nine 467, ten 469, eleven 487, and twelve 489 to create the appropriate gradient of refractive index across material 477. Adjusting the third beamlet in substantially one direction (79 or 81) may be done so that the third beamlet exits the top or bottom of the superpixel at the same or substantially similar angle as beamlet one and two in substantially one direction (79 or 81) as in case 1 or 2.

In one embodiment of a three pixel sub-component dispersion compensator called case 4.3, material 473 and 477 may be an NCM and material 475 may be an electro-optical material. The case 4.3 configuration is preferred when the two beamlets with the same or substantially similar wavelength or small range of wavelengths pass through pixel sub-component one 441 and three 453 at the same or substantially similar angle in substantially one direction. The second beamlet at a wavelength or small range of wavelengths that may be different from the first and the third beamlets travels through material 475 and the second beamlet's angle may be adjust in one (79 or 81) direction by changing the voltages on electrodes five 463, six 465, seven 483, and eight 485 to create the appropriate gradient of refractive index across material 475. Adjusting the second beamlet in substantially one direction (79 or 81) may be done so that the second beamlet exits the top or bottom of the superpixel at the same or substantially similar angle as beamlet one and three in substantially one direction as in case 1 or 2.

In one embodiment of a three pixel sub-component dispersion compensator called case 4.4, material 473, 475, and 477 may be all an electro-optical material. The case 4.4 configuration is preferred when each of the three beamlets of light of three different wavelengths or small range of wavelengths of light entering or exiting the superpixel and the dispersion compensator each have different angles in substantially one direction (79 or 81) that may be perpendicular to the length of the electrodes and the angle of each beamlet in one direction (79 or 81) needs to be independently corrected. The gradient in refractive index across material 473, 475, and material 477 may be changed so that gradient in refractive index across material 473, 475, and material 477 modify the angle of light of each beamlet so that each beamlet exit the top or bottom of the superpixel at the same or substantially similar angle as in case 1 and 2.

In one embodiment of a three pixel sub-component dispersion compensator called case 4.5, material 473 and 475 may be an electro-optical material and material 477 may be a NCM. The case 4.5 configuration is preferred when the two beamlets with different wavelength or small range of wavelengths pass through pixel sub-component one 441 and two 449 at the same or different angles in substantially one direction (79 or 81) that is perpendicular to the length of the electrodes. The first and second beamlet's angle may be adjust in substantially one (79 or 81) direction by changing the voltages on electrodes one 459, two 461, three 479, and four 481 and electrodes five 463, six 465, seven 483, and eight 485 to create the appropriate gradient of refractive index across material 473 and 475. Adjusting the first and second beamlet in substantially one direction (79 or 81) may be done so that the beamlets exit the top or bottom of the superpixel at the same or substantially similar angle as beamlet three in substantially one direction that may be perpendicular to the length of the electrodes as in case 1 or 2. The third beamlet at a wavelength or small range of wavelengths that may be different from the first and second beamlets travels through material 477 unaffected by the voltages on electrodes nine 467, ten 469, eleven 487, and twelve 489. The third beamlet's angle in substantially one direction (79 or 81) that may be perpendicular to the length of the electrodes may be unaffected by voltages on the electrodes in the dispersion compensator.

In one embodiment of a three pixel sub-component dispersion compensator called case 4.6, material 473 and 477 may be an electro-optical material and 475 may be a NCM. The case 4.6 configuration is preferred when the two beamlets with different wavelength or small range of wavelengths pass through pixel sub-component one 441 and three 453 at the same or different angles in substantially one direction (79 or 81) that may be perpendicular to the length of the electrodes. The first and third beamlet's angle may be adjust in substantially one direction (79 or 81) by changing the voltages on electrodes one 459, two 461, three 479, and four 481 and electrodes nine 467, ten 469, eleven 487, and twelve 489 to create the appropriate gradient of refractive index across material 473 and 477. Adjusting the first and third beamlet in substantially one direction (79 or 81) may be done so that the beamlets exit the top or bottom of the superpixel at the same or substantially similar angle as beamlet two in substantially one direction (79 or 81) that may be perpendicular to the length of the electrodes as in case 1 or 2. The second beamlet at a wavelength or small range of wavelengths that may be different from the first and third beamlets travels through material 475 substantially unaffected by the voltages on electrodes five 463, six 465, seven 483, and eight 485. The second beamlet's angle in substantially one direction (79 or 81) that may be perpendicular to the length of the electrodes is substantially unaffected by voltages on the electrodes in the dispersion compensator.

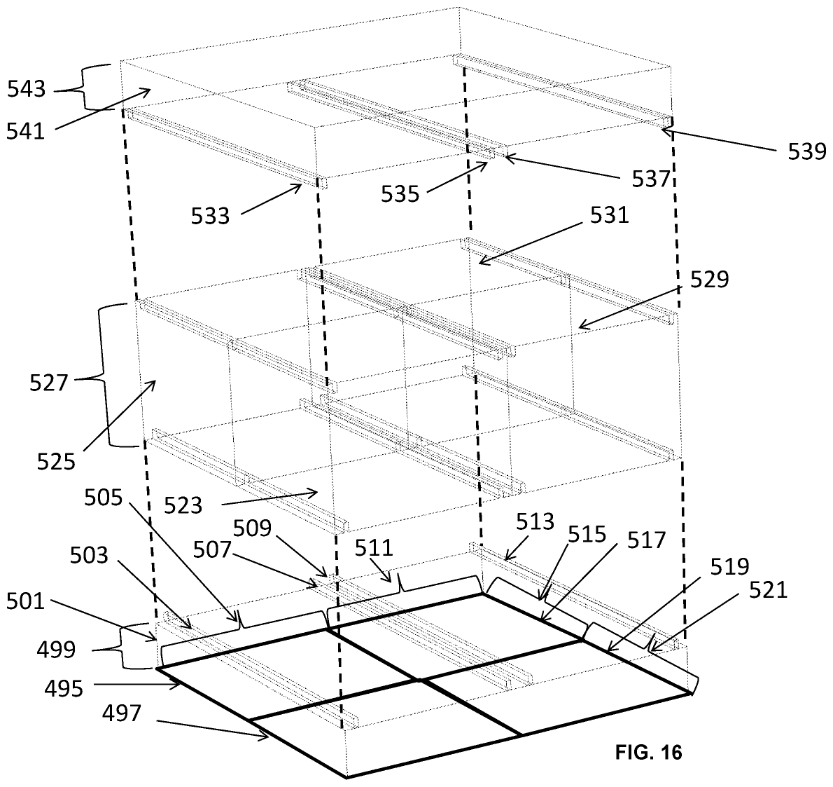

One embodiment of the dispersion compensator uses a four pixel sub-component design. FIG. 16 shows an embodiment of a four pixel sub-component dispersion compensator. The dispersion compensator embodiment may be made on a top 541 and bottom 501 piece of transparent material like glass with a length (515 plus 521) and width (505 plus 511). The thickness 543 of the top transparent material 541 and the thickness 499 of the bottom transparent material 501 do not have to be the same or substantially similar but it is preferred if the transparent materials are as thin as possible. The first pixel sub-component 495 has a width 505 and length 515, the second pixel sub-component 497 has a width 505 and length 521, the third pixel subcomponent 519 has a length 521 and width 511, and the fourth pixel sub-component 517 has a length 515 and a width 511. The widths 505 of pixel sub-components one 495 and two 497 may be the same or substantially similar and the width 511 of pixel sub-component three 519 and four 517 also may be the same or substantially similar but the width of pixel sub-component one 495 and two 497 and the width of pixel sub-component three 519 and four 517 do not need to be the same or substantially similar. The lengths 515 of pixel sub-component one 495 and four 517 may be the same or substantially similar and the length 521 of pixel sub-component two 497 and three 519 also may be the same or substantially similar but the length 515 of pixel sub-components one 495 and four 517 and pixel sub-components two 497 and three 519 do not need to be the same or substantially similar. It is preferred to make the lengths and width of all the pixel sub-components the same or substantially similar dimension. The four pixel sub-components, called the first 495, second 497, third 519, and fourth 517 pixel sub-components, may be aligned over the first, second, third, and fourth pixel sub-components located on layers of the superpixel that may be above or below the dispersion compensator. The length and width of a pixel sub-component in the dispersion compensator and length and width of the same pixel sub-component on a different layer of the superpixel in the same superpixel may be the same or substantially similar length and width dimensions. Each pixel sub-component on the four pixel sub-component dispersion compensator shown in FIG. 16 has a four electrode configuration. The electrodes seen in FIG. 16 of adjacent pixel sub-components may be also electrically connected lengthwise in order to reduce the number of required electrical connections. The four electrode configuration over each pixel sub-component is only one of the electrode configuration possibilities and the two and three electrode configurations over each pixel sub-component described herein could also be used but the four electrode set up is the preferred practice. Over the first 495 and second 497 pixel sub-component, the same or different voltage wave forms may be applied to electrodes one 503, two 507, three 533, and four 535 in order to create an electric field across the material 525 and 523. The material 525 and 523 can either be an electro-optical material like a liquid crystal or electro-optical crystal or a NCM. Over the third 519 and fourth 517 pixel sub-components, electrode five 509, six 513, seven 537, and eight 539 may be used in order to create an electric field across the material 529 and 531. The material 529 and 531 can also either be an electro-optical material like a liquid crystal or electro-optical crystal or a NCM. The height 527 of material 525, 523, 529, and 531 is important as if materials 525, 523, 529, or 531 are an electro-optical material as the height 527 will be directly related to the optical path length of light of a given wavelength or small range of wavelengths. The optical path length may be important because when an electric field is applied across the electro-optical material, the electric field can create a gradient in the electro-optical materials refractive index across the electro-optical material substantially perpendicular to the length of the electrodes. The longer the optical path length, the larger the change in angle in substantially one direction (79 or 81) that may be substantially perpendicular to the length of the electrodes will be. The magnitude of the gradient of refractive index and the optical path length of the light will change the angle of light in substantially one direction (79 or 81) that may be perpendicular to the length of the electrodes. The magnitude of the gradient in refractive index may be controlled by the magnitude of the electric field applied across the electro-optical material. The four pixel sub-component dispersion compensator may be used to make sure that the four beamlets of two, three, or four wavelengths or small range of wavelengths that exit the top or bottom of the superpixel as in case 1 and 2 both have the same or substantially similar angle in substantially one direction (79 or 81). To accomplish the beamlets exiting the top or bottom of the superpixel as in case 1 and 2 both having the same or substantially similar angle in substantially one direction (79 or 81), the materials that make up material 525, 523, 529, and 531 may be changed from either an electro-optical material or an NCM. The NCM material may have electrodes around the NCM material but the electrodes are not required to be around the NCM in the four pixel sub-component dispersion compensator even if the electrodes are seen in FIG. 16 though it is preferred if the electrodes are around the NCM in four pixel sub-component dispersion compensator. Different embodiments of the four pixel sub-component dispersion compensators are described herein called case 5.1, case 5.2, case 5.3, case 5.4, case 5.5, and case 5.6.

In one embodiment of a four pixel sub-component dispersion compensator called case 5.1, material 523 and 525 may be an electro-optical material, and material 529 and 531 may be an electro-optical material. The case 5.1 configuration is very similar to the 2 pixel sub-component dispersion compensator. The case 5.1 configuration is preferred when the first and second beamlets with same or substantially similar wavelength or small range of wavelengths enters material one 525 and two 523 at the same or different angles in substantially one direction (79 or 81) that may be perpendicular to the length of the electrodes and the third and fourth beamlets with same or substantially similar wavelength or small range of wavelengths that may be different than the first and second beamlets that enter material three 529 and four 531 at the same or substantially similar angles in substantially one direction (79 or 81) that may be perpendicular to the length of the electrodes. The first and second beamlet's angle may be adjust in substantially one direction by changing the voltages on electrodes one 503, two 507, three 533, and four 535 and the third and fourth beamlet's angle may be also adjust in substantially one direction by changing the voltages on electrodes five 509, six 513, seven 537, and eight 539 to create the appropriate gradient of refractive index across material 525 and 523 and material 529 and 531 so that all four beamlets can exit the top or bottom of the superpixel at the same or substantially similar angle in substantially one direction (79 or 81) that is perpendicular to the length of the electrodes as in case 1 or 2.

In one embodiment of a four pixel sub-component dispersion compensator called case 5.2, material 525 and 529 may be an electro-optical material, and material 523 and 531 may be a NCM. The case 5.2 configuration is preferred when the first and third beamlets with the same or substantially similar wavelength or small range of wavelengths enter material one 525 and three 529 at the same or different angles in substantially one direction (79 or 81) that is perpendicular to the length of the electrodes and the second and fourth beamlets with same or substantially similar wavelength or small range of wavelengths that may be different than the first and third beamlets that enter material two 523 and four 531 at the same or substantially similar angles in substantially one direction (79 or 81) that may be perpendicular to the length of the electrodes. Beamlets two and four that travel though material two 523 and four 531 may be made of an NCM so the beamlets travel through material two 523 and four 531 unaffected by the voltages on electrodes one through eight. The first beamlet's angle may be adjust in substantially one direction (79 or 81) by changing the voltages on electrodes one 503, two 507, three 533, and four 535 and the third beamlet's angle may be adjust in substantially one direction (79 or 81) by changing the voltages on electrodes five 509, six 513, seven 537, and eight 539 to create the appropriate gradient of refractive index across material 525 and 529 so that the first and third beamlets can be adjusted so that all four beamlets exit the top or bottom of the superpixel at the same or substantially similar angle in substantially one direction (79 or 81) that is perpendicular to the length of the electrodes as in case 1 or 2.

In one embodiment of a four pixel sub-component dispersion compensator called case 5.3, material 525 may be an electro-optical material and material 523, 529, and 531 may be a NCM. The case 5.3 configuration is preferred when the first beamlet has a particular wavelength or small range of wavelengths that enters material one 525 at a particular angles in substantially one direction (79 or 81) that may be perpendicular to the length of the electrodes. The second, third, and fourth beamlets with same or substantially similar wavelength or small range of wavelengths that may be different than the first beamlet's enter material two 523, three 529, and four 531 at the same or substantially similar angle in substantially one direction (79 or 81) that may be perpendicular to the length of the electrodes. Beamlets two, three, and four that travel though material two 523, three 529, and four 531 may be made of an NCM so the beamlets travel through material two 523, three 529, and four 531 unaffected by the voltages on electrodes one through eight. The first beamlet's angle may be adjust in substantially one direction (79 or 81) by changing the voltages on electrodes one 503, two 507, three 533, and four 535 to create the appropriate gradient of refractive index across material 525 so that the first beamlets angle can be adjusted so that all four beamlets exit the top or bottom of the superpixel at the same or substantially similar angle in substantially one direction (79 or 81) that may be perpendicular to the length of the electrodes as in case 1 or 2.

In one embodiment of a four pixel sub-component dispersion compensator called case 5.4, material 525 may be an NCM material and material 523, 529, and 531 may be an electro-optical material. The case 5.4 configuration is preferred when the first beamlet has a particular wavelength or small range of wavelengths that enters material one 525 at a particular angles in substantially one direction (79 or 81) that may be perpendicular to the length of the electrodes. The second beamlet with the same or substantially similar wavelength or small range of wavelengths that may be different than the first beamlet's and the same or substantially similar as material three 529 and four 531 enter material two 523 at an angle in substantially one direction (79 or 81) that may be perpendicular to the length of the electrodes. The third and fourth beamlets with the same or substantially similar wavelength or small range of wavelengths as beamlet two and may be different than the first beamlet's enters material three 529 and four 531 at the same or substantially similar angle in substantially one direction (79 or 81) that may be substantially perpendicular to the length of the electrodes. Beamlet one travels through material one 525, may be made of an NCM so beamlet one travels through material one 525 unaffected by the voltages on electrodes one through eight. The second beamlet's angle may be adjust in substantially one direction (79 or 81) by changing the voltages on electrodes one 503, two 507, three 533, and four 535 to create the appropriate gradient of refractive index across material 523 so that the second beamlets angle can be adjusted so that all four beamlets exit the top or bottom of the superpixel at the same or substantially similar angle in substantially one direction (79 or 81) that may be perpendicular to the length of the electrodes as in case 1 or 2. The third and fourth beamlet's angle may be adjust in substantially one direction (79 or 81) by changing the voltages on electrodes five 509, six 513, seven 537, and eight 539 to create the appropriate gradient of refractive index across material 529 and 531 so that the third and fourth beamlet's angle may be adjusted so that all four beamlets exit the top or bottom of the superpixel at the same or substantially similar angle in substantially one direction (79 or 81) that is perpendicular to the length of the electrodes as in case 1 or 2.

In one embodiment of a four pixel sub-component dispersion compensator called case 5.5, material 525 and 529 may be an electro-optical material and material 523, and 531 may be a NCM. The case 5.5 configuration is preferred when the first and third beamlet are different wavelengths or small range of wavelengths that enters material one 525 and three 529 at a particular angle in substantially one direction (79 or 81) that may be perpendicular to the length of the electrodes. The second and fourth beamlets with same or substantially similar wavelength or small range of wavelengths that may be different than the first or third beamlet's enter material two 523, three 529, and four 531 at the same or substantially similar angle in substantially one direction (79 or 81) that may be perpendicular to the length of the electrodes. Beamlets two and four that travel through material two 523 and four 531 may be made of an NCM so the beamlets travel through material two 523 and four 531 unaffected by the voltages on electrodes one through eight. The first beamlet's angle may be adjust in substantially one direction (79 or 81) by changing the voltages on electrodes one 503, two 507, three 533, and four 535 to create the appropriate gradient of refractive index across material 525 and the third beamlet's angle may be adjust in substantially one direction (79 or 81) by changing the voltages on electrodes five 509, six 513, seven 537, and eight 539 to create the appropriate gradient of refractive index across material 529 so that the first and third beamlet's angle can be adjusted so that all four beamlets exit the top or bottom of the superpixel at the same or substantially similar angle in substantially one direction (79 or 81) that may be perpendicular to the length of the electrodes as in case 1 or 2.

In one embodiment of a four pixel sub-component dispersion compensator called case 5.6, material 523, 525, 529, and 531 may be all a NCM. The case 5.6 configuration is preferred when the first, second, third, and fourth beamlet may be all different wavelengths or small range of wavelengths that enters material one 525, two 523, three 529 and four 531 all at a particular angle in substantially one direction (79 or 81) that may be perpendicular to the length of the electrodes. The case 5.6 configuration may be used when the four different wavelength or small range of wavelengths may be all very close in wavelength or all in the infrared spectrum where the dispersion in refractive index is small. Beamlets one, two, three, and four that travel through material one 525, two 523, three 529 and four 531 may be made of an NCM so the beamlets travel through material one 525, two 523, three 529, and four 531 substantially unaffected by the voltages on electrodes one through eight and exit the superpixel in the same or substantially similar direction as in case 1 or 2.

One of the layers that can make up one or two layers of an embodiment of a superpixel includes the main beam deflector. The main beam deflector may be needed in the superpixel designs to do the bulk of modifying the angle and trajectory of the beamlets in substantially one direction (79 or 81) substantially perpendicular to the length of the electrodes that travels through the main beam deflector. Modifying the angle and trajectory of the beamlets in substantially one direction (79 or 81) substantially perpendicular to the length of the electrodes may be accomplished by using one larger electro-optical deflector that may be over all of the two to four pixel sub-components of the two to four pixel sub-component main beam deflector. The electro-optical deflector over all of the pixel sub-components may all use a two, three, or four electrode scheme as described herein. The same or different voltage waveforms may be applied to the electrodes to create an electric field across the electro-optic material like a liquid crystal or electro-optic crystal in the electro-optic deflector that can cause a gradient in refractive index across the electro-optic material when an electric field is applied across the electro-optical material. The gradient of the refractive index of the electro-optic deflectors may be perpendicular or substantially perpendicular to the normal 77 of the plane of the superpixel 75 and substantially perpendicular to the length of the electrodes. The different embodiments of a main beam deflectors are described herein.

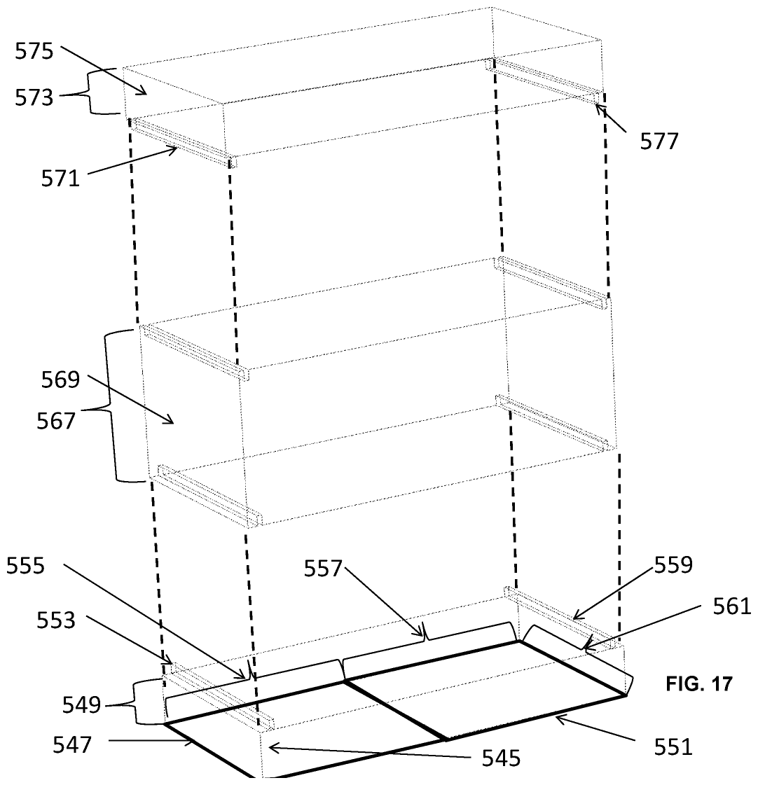

FIG. 17 shows an embodiment of a two pixel sub-component main beam deflector. The main beam deflector embodiment may be made on a top 575 and bottom 545 piece of transparent material like glass with a length 561 and width (555 plus 557). The thickness 573 of the top transparent material 575 and the thickness 549 of the bottom transparent material 545 do not have to be the same or substantially similar but it is preferred if the transparent materials are as thin as possible. The first pixel sub-component 547 has a width 555 and length 561 and the second pixel sub-component 551 has a width 557 and length 561. The width 555 of pixel sub-component one 547 and the width 557 of pixel sub-component two 551 do not need to be the same or substantially similar but the length 561 of pixel sub-component one 547 and two 551 may be the same or substantially similar. It is preferred to make the lengths and width of all the pixel sub-components the same or a substantially similar dimension. The two pixel sub-components, called the first 547 and second 554 pixel sub-component, may be aligned over the first, and second pixel sub-components located on layers of the superpixel that may be above or below the main beam deflector. The length and width of a pixel sub-component in the dispersion compensator and length and width of the same pixel sub-component on a different layer of the superpixel in the same superpixel may be the same or substantially similar length and width dimensions. The two pixel sub-component main beam deflector shown in FIG. 16 has a four electrode configuration. The four electrode configuration over all of the pixel sub-components is only one of the electrode configuration possibilities and the two and three electrode configurations over each pixel subcomponent described herein could also be used but the four electrode set up is preferred. Over the first 547 and second 551 pixel sub-component, the same or different voltage wave forms may be applied to electrodes one 553, two 559, three 571, and four 557 in order to create an electric field across the material 569. The material 569 may be an electro-optical material like a liquid crystal or electro-optical crystal. The height 567 of material 569 is important as the height 567 can be directly related to the optical path length of light of a given wavelength or small range of wavelengths. The optical path length is important because when an electric field is applied across the electro-optical material as the electric field can create a gradient in the electro-optical material's refractive index across the electro-optical material substantially perpendicular to the length of the electrodes. The longer the optical path length, the larger the change in angle in substantially one direction (79 or 81) that may be perpendicular to the length of the electrodes may be. The magnitude of the gradient of refractive index and the optical path length of the light will change the angle of light in substantially one direction (79 or 81) that may be perpendicular to the length of the electrodes. The magnitude of the gradient in refractive index may be controlled by the magnitude of the electric field applied across the electro-optical material. The two pixel sub-component main beam deflector may be used to make sure that the two beamlets of two different wavelengths or small range of wavelengths that exit the top or bottom of the superpixel as in case 1 and 2 may be bent to the desired direction.

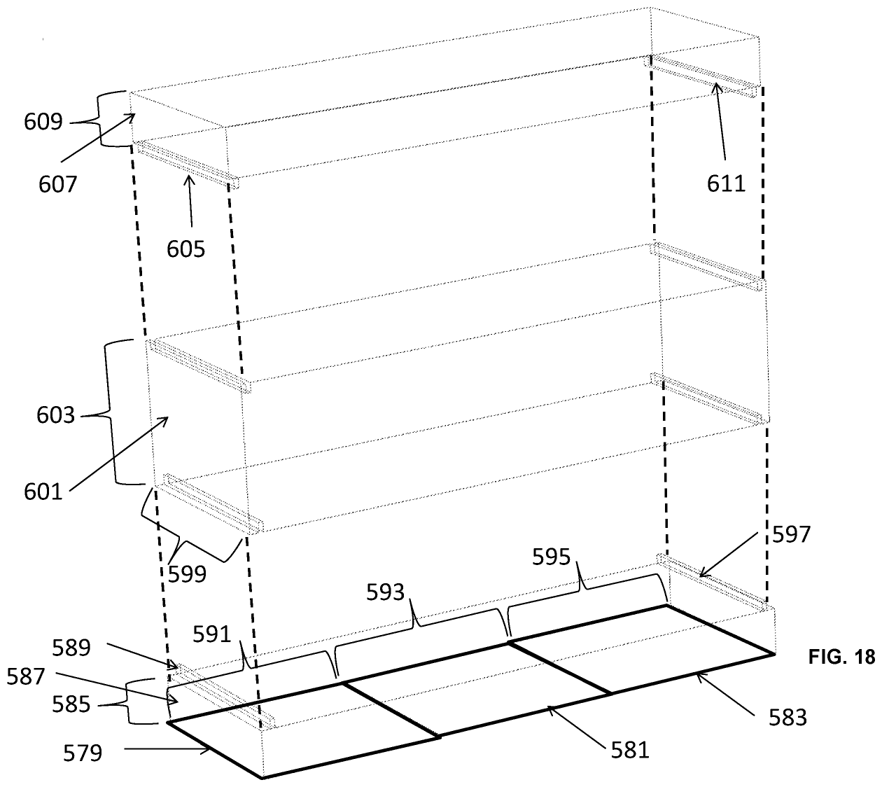

FIG. 18 shows an embodiment of a three pixel sub-component main beam deflector. The main beam deflector embodiment may be made on a top 607 and bottom 587 piece of transparent material like glass with a length 599 and width (591 plus 593 plus 595). The thickness 609 of the top transparent material 607 and the thickness 585 of the bottom transparent material 587 do not have to be the same or substantially similar but it is preferred if the transparent materials are as thin as possible. The first pixel sub-component 579 has a width 591 and length 599, the second pixel sub-component 581 has a width 593 and length 599, and the third pixel subcomponent 583 has a width 595 and length 599. The width 591 of pixel sub-component one 579, the width 593 of pixel sub-component two 581, and the width 595 of pixel sub-component three 583 do not need to be the same or substantially similar but the length 599 of pixel sub-component one 579, two 581, three 583 may be the same or substantially similar. It is preferred to make the lengths and width of all the pixel sub-components the same or substantially similar dimension. The three pixel sub-components, called the first 579, second 581, and third 583 pixel sub-component, may be aligned over their corresponding first, second, and third pixel sub-components located on layers of the superpixel that may be above or below the main beam deflector. The length and width of a pixel sub-component in the main beam deflector and length and width of the same pixel subcomponent on a different layer of the superpixel in the same superpixel are preferred to have the same or substantially similar length and width dimensions. The three pixel sub-component main beam deflector shown in FIG. 18 has a four electrode configuration. The four electrode configuration over all of the pixel sub-components is only one of the electrode configuration possibilities and the two and three electrode configurations over each pixel sub-component described herein could also be used but the four electrode set up is preferred. Over the first 579, second 581, and third 583 pixel sub-component, the same or different voltage wave forms may be applied to electrodes one 589, two 597, three 605, and four 611 in order to create an electric field across the material 601. The material 601 may be an electro-optical material like a liquid crystal or electro-optical crystal. The height 603 of material 601 is important as the height 603 may be directly related to the optical path length of light of a given wavelength or small range of wavelengths. The optical path length may be important because when an electric field is applied across the electro-optical material, the electric field can create a gradient in the electro-optical material's refractive index across the electro-optical material substantially perpendicular to the length of the electrodes. The longer the optical path length, the larger the change in angle in one direction (79 or 81) that is substantially perpendicular to the length of the electrodes will be. The magnitude of the gradient of refractive index and the optical path length of the light will change the angle of light in one direction (79 or 81) that may be substantially perpendicular to the length of the electrodes. The magnitude of the gradient in refractive index may be controlled by the magnitude of the electric field applied across the electro-optical material. The three pixel subcomponent main beam deflector may be used to make sure that the three beamlets of two to three different wavelengths or small range of wavelengths that exit the top or bottom of the superpixel as in case 1 and 2 may be bent to the desired direction.

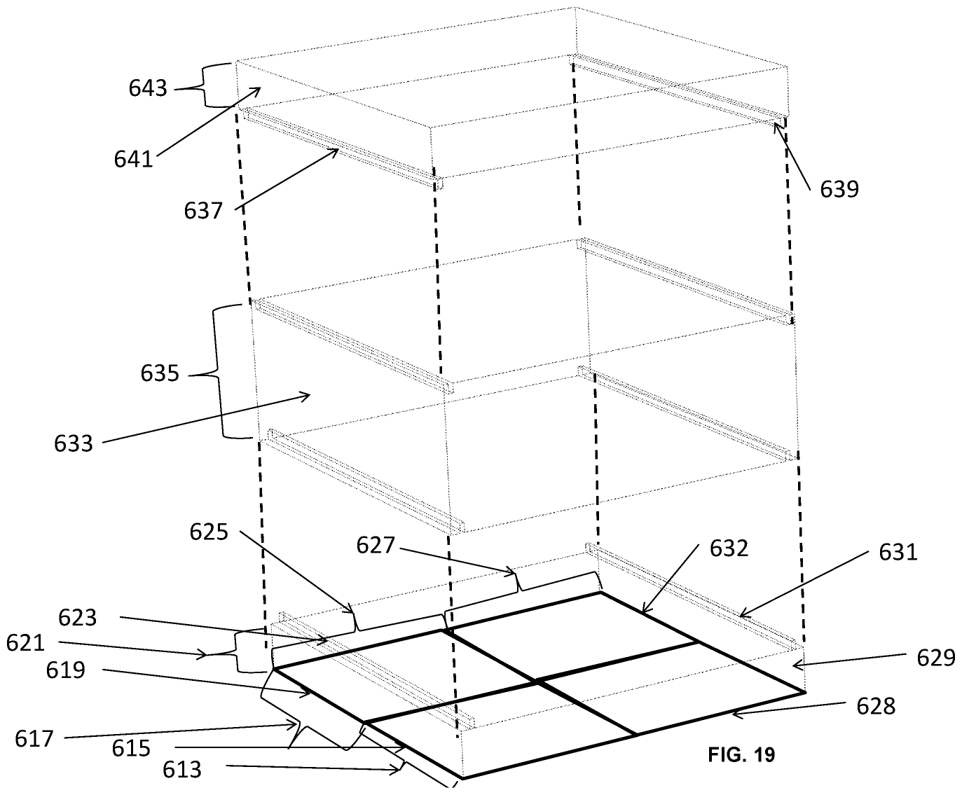

FIG. 19 shows an embodiment of a four pixel sub-component main beam deflector. The main beam deflector embodiment may be made on a top 641 and bottom 629 piece of transparent material like glass with a length (617 plus 613) and width (625 plus 627). The thickness 643 of the top transparent material 641 and the thickness 621 of the bottom transparent material 629 do not have to be the same or substantially similar but it is preferred if the transparent materials are as thin as possible. The first pixel sub-component 619 has a width 625 and length 617, the second pixel sub-component 615 has a width 625 and length 613, the third pixel sub-component 628 has a width 627 and length 613, and the fourth pixel sub-component 632 has a width 627 and length 617. The width 625 of pixel sub-component one 619 and two 615 may be the same or substantially similar. The width 627 of pixel sub-component four 632 and three 628 may be the same or substantially similar. Widths 625 and 627 do not need to be the same or substantially similar but it is preferred if the widths are. The length 617 of pixel sub-component one 619 and four 632 may be the same or substantially similar. The length 613 of pixel sub-component two 615 and three 628 may be the same or substantially similar. Lengths 617 and 613 do not need to be the same or substantially similar but it is preferred if the lengths are. The four pixel sub-components, called the first 619, second 615, third 628, and fourth 632 pixel sub-component, may be aligned over their corresponding first, second, third, and fourth pixel sub-components located on layers of the superpixel that may be above or below the main beam deflector. The length and width of a pixel sub-component in the main beam deflector and length and width of the same pixel sub-component on a different layer of the superpixel in the same superpixel may be the same or substantially similar length and width dimensions. The four pixel sub-component main beam deflector shown in FIG. 19 has a four electrode configuration. The four electrode configuration over all of the pixel sub-components is only one of the electrode configuration possibilities and the two and three electrode configurations over each pixel sub-component described herein could also be used but the four electrode set up is preferred. Over the first 619, second 615, third 628, and fourth 632 pixel sub-component, the same or different voltage wave forms may be applied to electrodes one 623, two 631, three 637, and four 639 in order to create an electric field across the material 633. The material 633 may be an electro-optical material like a liquid crystal or electro-optical crystal. The height 635 of material 633 is important as the height 635 may be directly related to the optical path length of light of a given wavelength or small range of wavelengths. The optical path length may be important because when an electric field is applied across the electro-optical material, the electric field can create a gradient in the electro-optical material's refractive index across the electro-optical material substantially perpendicular to the length of the electrodes. The longer the optical path length, the larger the change in angle in substantially one direction (79 or 81) that may be perpendicular to the length of the electrodes will be. The magnitude of the gradient of refractive index and the optical path length of the light will change the angle of light in substantially one direction (79 or 81) that may be perpendicular to the length of the electrodes. The magnitude of the gradient in refractive index may be controlled by the magnitude of the electric field applied across the electro-optical material. The four pixel sub-component main beam deflector may be used to make sure that the four beamlets of two to four different wavelengths or small range of wavelengths that exit the top or bottom of the superpixel as in case 1 and 2 may be bent to the desired direction.

Embodiments of a superpixel may include a light collimator as one of the superpixel embodiment's layers. The light collimators primary purpose may be to limit the angular range of light in substantially one (79 or 81) or two directions (79 and 81) that can travel through the superpixel embodiment. In order to limit the angular range of light in substantially one (79 or 81) or two directions (79 and 81), a grid of an optically opaque and absorptive material may be made between two transparent substrates over each pixel sub-component of the superpixel. Between the optically opaque and absorptive material may be a transparent material. The angular range may be primarily controlled by the height of light collimator with a higher height reducing the angular range. The angular range is the maximum angle in substantially one (79 or 81) or two (79 and 81) directions with respect to the normal of the plane of the superpixel.

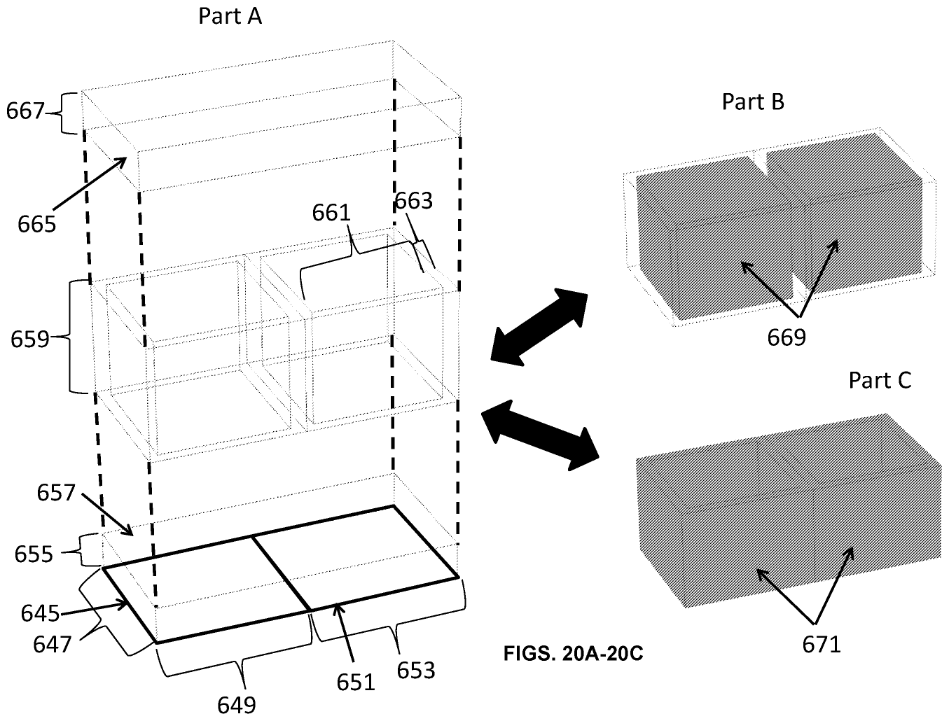

FIG. 20 shows an embodiment of a two pixel sub-component light collimator. The light collimator embodiment may be made on a top 665 and bottom 657 piece of transparent material like glass with a length 647 and width (649 plus 653). The thickness 667 of the top transparent material 665 and the thickness 655 of the bottom transparent material 657 do not have to be the same or substantially similar but it is preferred if the transparent materials are as thin as possible. The first pixel sub-component 645 has a width 649 and length 647 and the second pixel subcomponent 651 has a width 653 and length 647. The width 649 of pixel sub-component one 645 and the width 653 of pixel sub-component two 651 do not need to be the same or substantially similar but it is preferred if the widths are. The length 647 of pixel sub-component one 645 and two 651 may be the same or substantially similar. The two pixel sub-components, called the first 645 and second 651 pixel sub-component, may be aligned over their corresponding first and second pixel sub-components located on layers of the superpixel that may be above or below the light collimator. The length and width of a pixel sub-component in the light collimator and length and width of the same pixel sub-component on a different layer of the superpixel in the same superpixel may be the same or substantially similar length and width dimensions. A square or rectangular shaped grid 671 that may be made of an optically opaque and absorptive material that absorbs the light that intersects with the grid may be placed over each pixel sub-component. The optically opaque and absorptive grid 671 has a thickness 663. The thickness 663 of the grid 671 does not have to be the same or substantially similar over each pixel sub-component but it is preferred if thickness 663 is. Inside the optically opaque and absorptive grid 671, may be a transparent material 669 with a width 661 that the light travels through. The width 661 of the transparent material 669 does not have to be the same or substantially similar in both directions (79 or 81) for each pixel sub-component but it is preferred if width 661 is. The height 659 of the optically opaque and absorptive grid 671 and transparent material 669 controls the angular range of light that can pass through the light collimator.

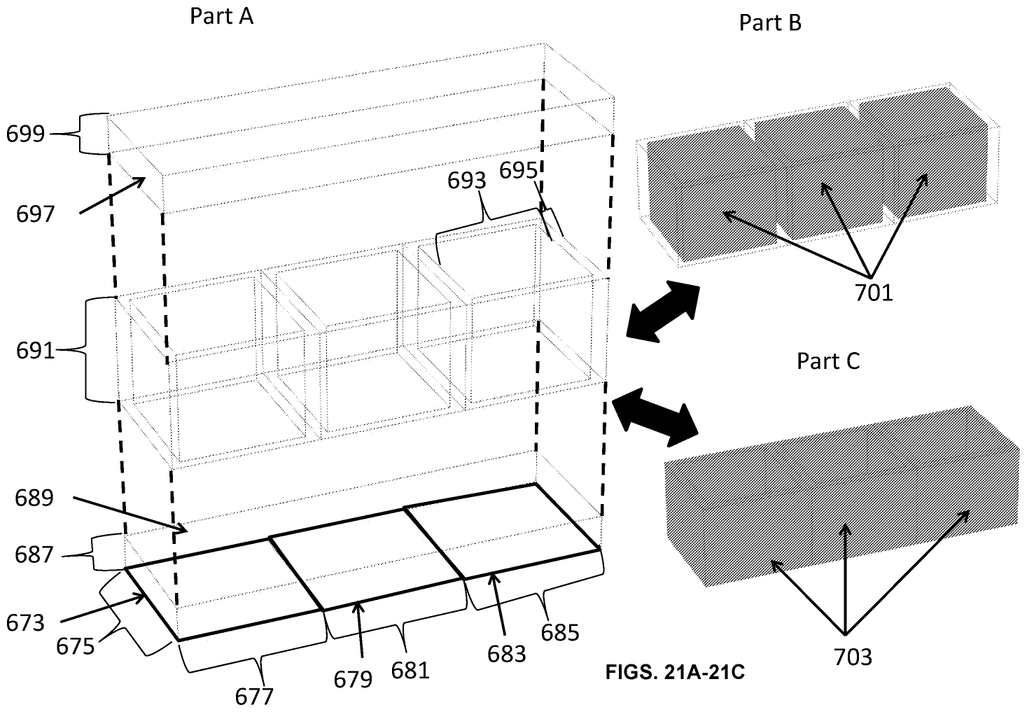

FIG. 21 shows an embodiment of a three pixel sub-component light collimator. The light collimator embodiment may be made on a top 697 and bottom 689 piece of transparent material like glass with a length 675 and width (677 plus 681 plus 685). The thickness 699 of the top transparent material 697 and the thickness 687 of the bottom transparent material 673 do not have to be the same or substantially similar but it is preferred if transparent materials are as thin as possible. The first pixel sub-component 673 has a width 677 and length 675, the second pixel subcomponent 679 has a width 681 and length 675, and the third pixel sub-component 683 has a width 685 and length 675. The width 677 of pixel sub-component one 673, the width 681 of pixel sub-component two 679, and the width 685 of pixel sub-component three 683 do not need to be the same or substantially similar but it is preferred if the widths are. The length 675 of pixel sub-component one 673, two 679, and three 683 may be the same or substantially similar. The three pixel sub-components, called the first 645, second 651, and third 683 pixel sub-component, may be aligned over their corresponding first, second, and third pixel sub-components located on layers of the superpixel that may be above or below the light collimator. The length and width of a pixel sub-component in the light collimator and length and width of the same pixel sub-component on a different layer of the superpixel in the same superpixel may be the same or substantially similar length and width dimensions. A square or rectangular shaped grid 703 may be made of an optically opaque and absorptive material that absorbs the light that intersects with the grid may be placed over each pixel sub-component. The optically opaque and absorptive grid 703 has a thickness 695. The thickness 695 of the grid 703 does not have to be the same or substantially similar over each pixel sub-component but it is preferred if thickness 695 is. Inside the optically opaque and absorptive grid 703, may be a transparent material 701 with a width 693 that the light travels through. The width 693 of the transparent material 701 does not have to be the same or substantially similar in both directions (79 or 81) for each pixel sub-component but it is preferred if width 693 is. The height 691 of the optically opaque and absorptive grid 703 and transparent material 701 controls the angular range of light that can pass through the light collimator.

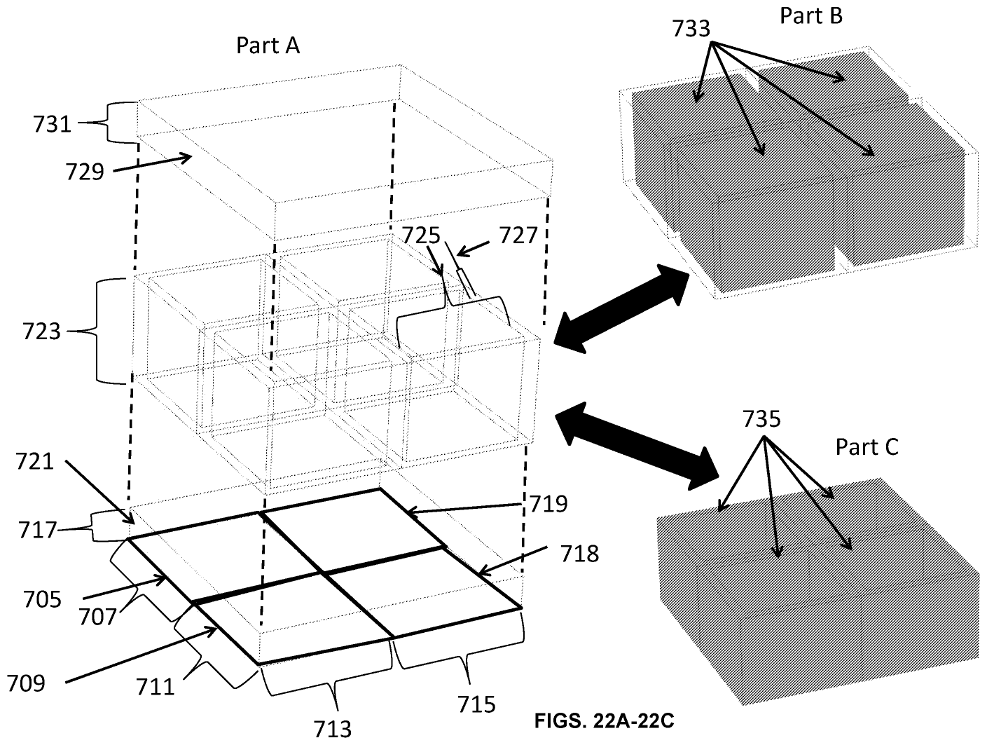

FIG. 22 shows an embodiment of a four pixel sub-component light collimator. The light collimator embodiment may be made on a top 729 and bottom 721 piece of transparent material like glass with a length (707 plus 711) and width (713 plus 715). The thickness 731 of the top transparent material 729 and the thickness 717 of the bottom transparent material 721 do not have to be the same or substantially similar but it is preferred if the transparent materials are as thin as possible. The first pixel sub-component 705 has a width 713 and length 707, the second pixel subcomponent 709 has a width 713 and length 711, the third pixel sub-component 718 has a width 715 and length 711, and the fourth pixel sub-component 719 has a width 715 and length 707. The width 713 of pixel sub-component one 705 and two 709 may be the same or substantially similar. The width 715 of pixel sub-component three 718 and four 719 may be the same or substantially similar. The widths 713 of pixel sub-component one 705 and two 709 and the widths 715 of pixel sub-component three 718 and four 719 do not need to be the same or substantially similar though it is preferred if widths are. The length 707 of pixel sub-component one 705 and four 719 may be the same or substantially similar. The length 711 of pixel sub-component two 709 and three 718 may be the same or substantially similar. The lengths 707 of pixel sub-component one 705 and four 719 and the lengths 711 of pixel sub-component two 709 and three 718 do not need to be the same or substantially similar though it is preferred if lengths are. The four pixel sub-components, called the first 705, second 709, third 718, and fourth 719 pixel sub-component, may be aligned over their corresponding first, second, third, and fourth pixel sub-components located on layers of the superpixel that may be above or below the light collimator. The length and width of a pixel sub-component in the light collimator and length and width of the same pixel sub-component on a different layer of the superpixel in the same superpixel may be the same or substantially similar length and width dimensions. A square or rectangular shaped grid 735 may be made of an optically opaque and absorptive material that absorbs the light that intersects with the grid may be placed over each pixel sub-component. The optically opaque and absorptive grid 735 has a thickness 727. The thickness 727 of the grid 735 does not have to be the same over each pixel subcomponent but it is preferred if thickness 727 is. Inside the optically opaque and absorptive grid 735, may be a transparent material 733 with a width 725 that the light travels through. The width 725 of the transparent material 733 does not have to be the same or substantially similar in both directions (79 or 81) for each pixel sub-component but it is preferred if width 725 is. The height 723 of the optically opaque and absorptive grid 735 and transparent material 733 controls the angular range of light that can pass through the light collimator.

Embodiments of a superpixel may include one or more prism arrays and light planarization layers. The prism array's primary purpose is to change the angular range of light in one (79 or 81) direction that can travel through the prism array as in case 1 or 2. The reason for the need for prism array layer includes that the main beam deflector layer in most designs can only bend the light up to plus or minus (+/−) a maximum number degrees in substantially one direction (79 or 81). This maximum number of degrees of main beam deflector embodiments in substantially one direction (79 or 81) is usually between +/−5 and 12 degrees. The prism array changes the angular range of a superpixel of plus or minus (+/−) a maximum number degrees in substantially one direction (79 or 81) that occurs. For example, if a prism array is not used, the angular range would be zero degrees+/−a maximum number degrees in one direction (79 or 81). If a prism array is used, the angular range would be an angle alpha with respect to the normal 77 of the plane 75 of the superpixel in substantially one direction (79 or 81)+/−a maximum number degrees in substantially one direction (79 or 81). The value of alpha can be between +/−0 to 80 degrees. The planarization layer works in conjunction with the prism array to control the angular range as the planarization layer usually has a lower refractive index than the prism array layer. The planarization layer also planarizes or flattens the prism array layer so additional layers of the superpixel can be built on top of the prism array layer.

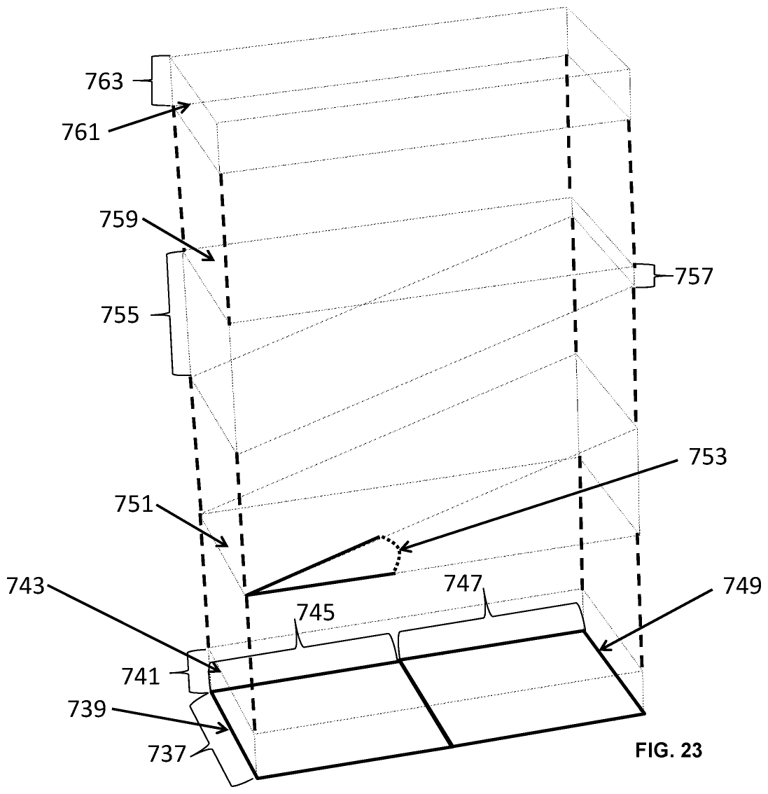

FIG. 23 shows an embodiment of a two pixel sub-component prism array and planarization layer. The prism array and planarization layer embodiment may be made on a top 761 and bottom 743 piece of transparent material like glass with a length 737 and width (745 plus 747). The thickness 763 of the top transparent material 761 and the thickness 741 of the bottom transparent material 743 do not have to be the same or substantially similar but it is preferred if the transparent materials are as thin as possible. The first pixel sub-component 739 has a width 745 and length 737 and the second pixel sub-component 749 has a width 747 and length 737. The width 745 of pixel sub-component one 739 and the width 747 of pixel sub-component two 749 do not need to be the same or substantially similar but it is preferred if the widths are. The length 737 of pixel sub-component one 739 and two 749 may be the same or substantially similar. The two pixel sub-components, called the first 739 and second 749 pixel sub-component, may be aligned over their corresponding first and second pixel sub-components located on layers of the superpixel that may be above or below the prism array and planarization layer. The length and width of a pixel sub-component in prism array and planarization layer and length and width of the same pixel sub-component on a different layer of the superpixel in the same superpixel may be the same or substantially similar length and width dimensions. The prism array 751 in the two pixel subcomponent prism array and planarization layer may be triangularly shaped and over both pixel sub-components. The angle theta 753 of the prism array 751 controls the angular range of the superpixel in substantially one direction (79 or 81). The prism array 751 generally has a higher refractive index than the planarization layer 759. The planarization layer 759 has a height 755 from the bottom of the prism array to the top glass and also an additional height 757 from the top of the prism array to the top glass.

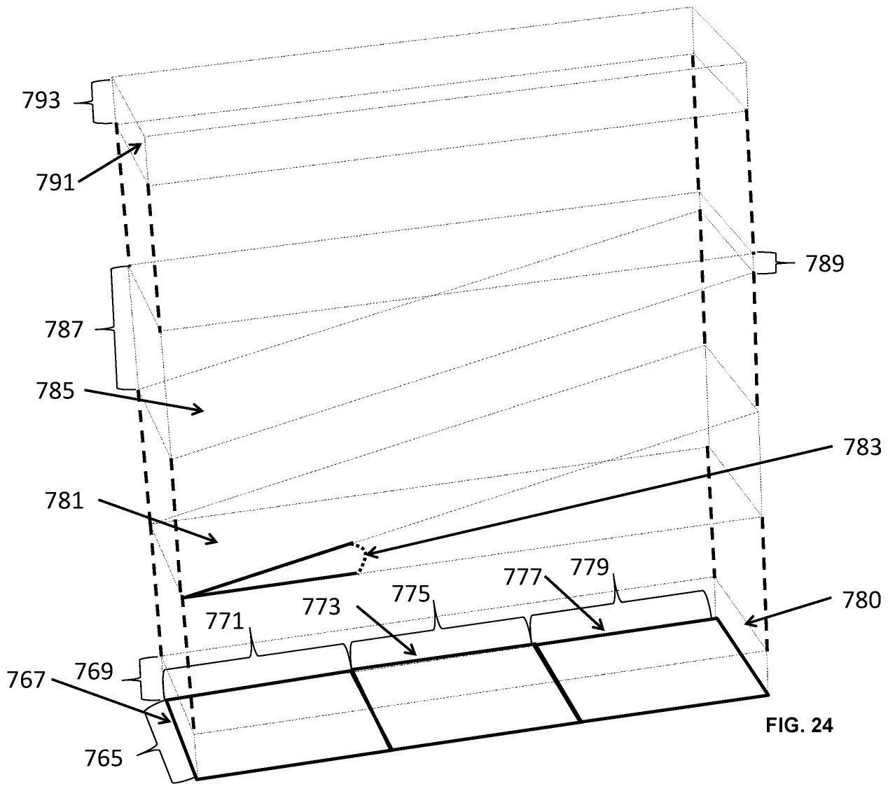

FIG. 24 shows an embodiment of a three pixel sub-component prism array and planarization layer. The prism array and planarization layer embodiment may be made on a top 791 and bottom 780 piece of transparent material like glass with a length 765 and width (767 plus 773 plus 777). The thickness 793 of the top transparent material 791 and the thickness 769 of the bottom transparent material 780 do not have to be the same or substantially similar but it is preferred if the transparent materials are as thin as possible. The first pixel sub-component 767 has a width 771 and length 765, the second pixel sub-component 773 has a width 775 and length 765, and the third pixel sub-component 777 has a width 779 and length 765. The width 771 of pixel sub-component one 767, the width 775 of pixel sub-component two 773, and the width 779 of pixel sub-component three 777 do not need to be the same or substantially similar but it is preferred if widths are. The length 765 of pixel sub-component one 767, two 773, and three 777 may be the same or substantially similar. The three pixel sub-components, called the first 767, second 773, and third 777 pixel sub-component, may be aligned over their corresponding first, second, and third pixel sub-components located on layers of the superpixel that may be above or below the prism array and planarization layer. The length and width of a pixel sub-component in prism array and planarization layer and length and width of the same pixel sub-component on a different layer of the superpixel in the same superpixel may be the same or substantially similar length and width dimensions. The prism array 781 in the three pixel sub-component prism array and planarization layer may be triangularly shaped and over all three pixel sub-components. The angle theta 783 of the prism array 781 controls the angular range of the superpixel in substantially one direction (79 or 81). The prism array 781 generally has a higher refractive index than the planarization layer 785. The planarization layer 785 has a height 787 from the bottom of the prism array to the top glass and also an additional height 789 from the top of the prism array to the top glass.

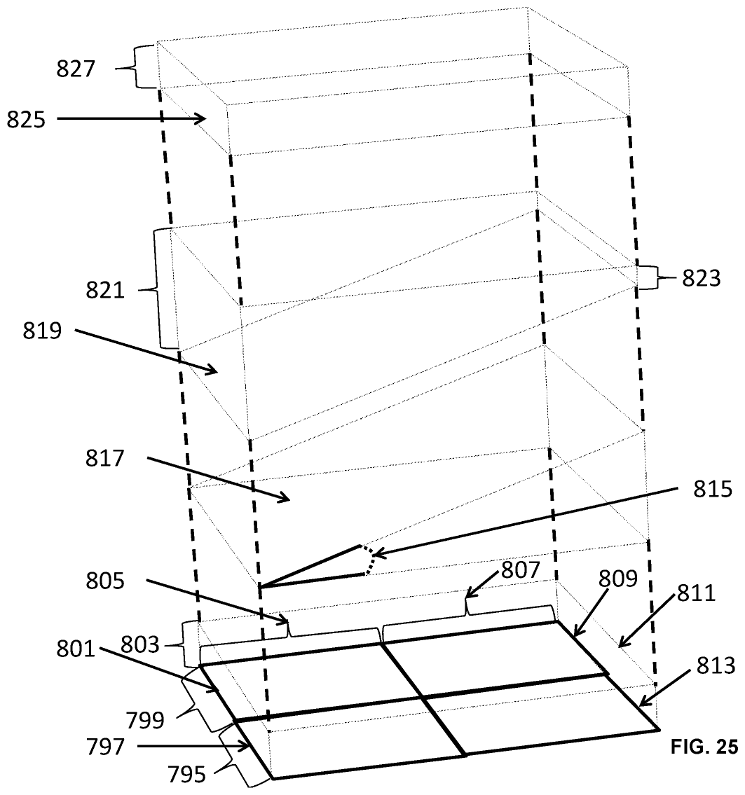

FIG. 25 shows an embodiment of a four pixel sub-component prism array and planarization layer. The prism array and planarization layer embodiment may be made on a top 825 and bottom 811 piece of transparent material like glass with a length (799 plus 795) and width (805 plus 807). The thickness 827 of the top transparent material 825 and the thickness 803 of the bottom transparent material 811 do not have to be the same or substantially similar but it is preferred if the transparent materials are as thin as possible. The first pixel sub-component 801 has a width 805 and length 799, the second pixel sub-component 797 has a width 805 and length 795, the third pixel sub-component 813 has a width 807 and length 795, and the fourth pixel subcomponent 809 has a width 807 and length 799. The width 805 of pixel sub-component one 801 and two 797 may be the same or substantially similar. The width 807 of pixel sub-component three 813 and four 809 may be the same or substantially similar. The widths 805 of pixel subcomponent one 801 and two 797 and the widths 807 of pixel sub-component three 813 and four 809 do not may be the same or substantially similar though it is preferred if the widths are. The length 799 of pixel sub-component one 801 and four 809 may be the same or substantially similar. The length 795 of pixel sub-component two 797 and three 813 may be the same or substantially similar. The lengths 799 of pixel sub-component one 801 and four 809 and the lengths 795 of pixel sub-component two 797 and three 813 do not need to be the same or substantially similar though it is preferred if the lengths are. The four pixel sub-components, called the first 801, second 797, third 813, and fourth 809 pixel sub-component, may be aligned over their corresponding first, second, third, and fourth pixel sub-components located on layers of the superpixel that are above or below the prism array and planarization layer. The length and width of a pixel sub-component in the prism array and planarization layer and length and width of the same pixel sub-component on a different layer of the superpixel in the same superpixel may be the same or substantially similar length and width dimensions. The prism array 817 in the four pixel sub-component prism array and planarization layer may be triangularly shaped and over all four pixel sub-components. The angle theta 815 of the prism array 817 controls the angular range of the superpixel in substantially one direction (79 or 81). The prism array 817 generally has a higher refractive index than the planarization layer 819. The planarization layer 819 has a height 821 from the bottom of the prism array to the top glass and also an additional height 823 from the top of the prism array to the top glass.

Embodiments of a superpixel may include a 90 degree optical rotator as one of the layers. The 90 degree rotation layer's purpose may be to change the polarization of light by 90 degrees using a birefringent material which could be a liquid crystal and may be needed in superpixel designs that change the angle of light in substantially two directions (79 and 81) with respect to the normal of the plane of the superpixel. The reason for the 90 degree rotation layer may be to make sure that the polarization of the light is perpendicular or substantially perpendicular to the length of the electrodes in the dispersion compensators and main beam deflectors.

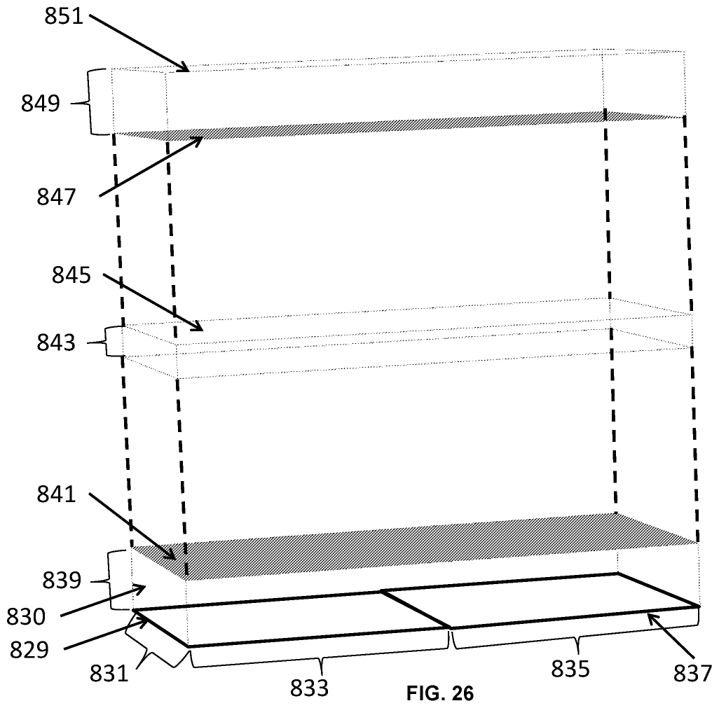

FIG. 26 shows an embodiment of a two pixel sub-component 90 degree optical rotator. The 90 degree rotation layer embodiment may be made on a top 851 and bottom 830 piece of transparent material like glass with a length 831 and width (833 plus 835). The thickness 849 of the top transparent material 851 and the thickness 839 of the bottom transparent material 830 do not have to be the same or substantially similar but it is preferred if the transparent materials are as thin as possible. The first pixel sub-component 829 has a width 833 and length 831 and the second pixel sub-component 837 has a width 835 and length 831. The width 833 of pixel sub-component one 829 and the width 835 of pixel sub-component two 837 do not need to be the same or substantially similar but it is preferred if widths are. The length 831 of pixel sub-component one 829 and two 837 may be the same or substantially similar. The two pixel sub-components, called the first 829 and second 837 pixel sub-component, may be aligned over their corresponding first and second pixel sub-components located on layers of the superpixel that may be above or below the prism array and planarization layer. The length and width of a pixel sub-component in prism array and planarization layer and length and width of the same pixel sub-component on a different layer of the superpixel in the same superpixel may be the same or substantially similar length and width dimensions. The birefringent material 845 in the two pixel sub-component 90 degree rotation layer may be over both of the pixel sub-components and rotates the light traveling through the birefringent layer with a thickness 843 by substantially 90 degrees so that the lights polarization may be substantially perpendicular to the length of the electrodes. If the birefringent material 845 is a liquid crystal then surface 841 on the bottom transparent material 830 and the surface 847 on the top transparent material 851 can be textured to align the liquid crystal material. The preferred practice is to make material 845 a liquid crystal but other birefringent materials can be used.

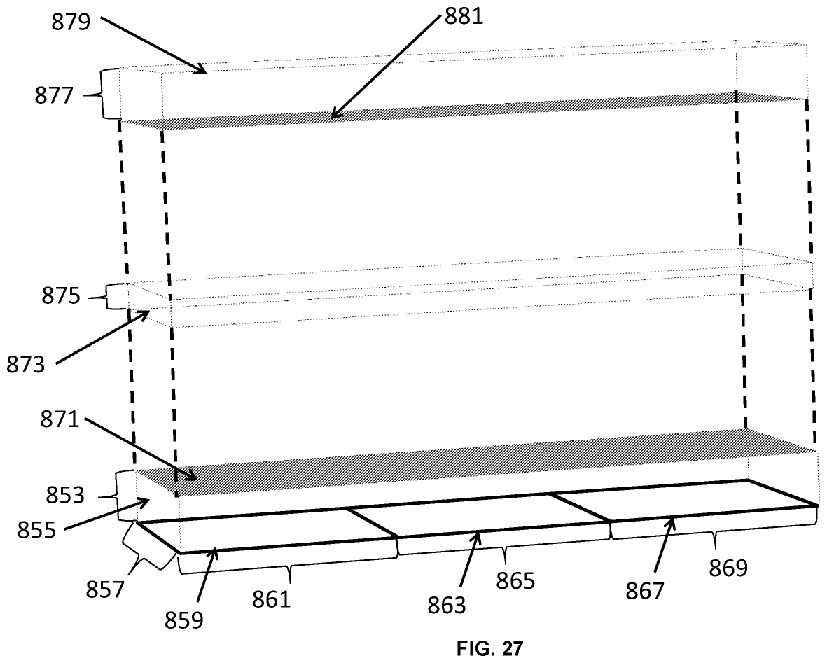

FIG. 27 shows an embodiment of a three pixel sub-component 90 degree optical rotator. The 90 degree rotation layer embodiment may be made on a top 879 and bottom 855 piece of transparent material like glass with a length 857 and width (861 plus 865 plus 869). The thickness 877 of the top transparent material 879 and the thickness 853 of the bottom transparent material 855 do not have to be the same or substantially similar but it is preferred if the transparent materials are as thin as possible. The first pixel sub-component 859 has a width 861 and length 857, the second pixel sub-component 863 has a width 865 and length 857, and the third pixel subcomponent 867 has a width 869 and length 857. The width 861 of pixel sub-component one 859, the width 865 of pixel sub-component two 863, and the width 869 of pixel sub-component three 867 do not need to be the same or substantially similar but it is preferred if the widths are. The length 857 of pixel sub-component one 859, two 863, and three 867 may be the same or substantially similar. The three pixel sub-components, called the first 859, second 863, and third 867 pixel sub-component, may be aligned over their corresponding first, second, and third pixel sub-components located on layers of the superpixel that may be above or below the prism array and planarization layer. The length and width of a pixel sub-component in three pixel subcomponent 90 degree optical rotation layer and length and width of the same pixel sub-component on a different layer of the superpixel in the same superpixel may be the same or substantially similar length and width dimensions. The birefringent material 875 in the three pixel subcomponent 90 degree rotation layer may be over all three of the pixel sub-components and rotates the light traveling through the birefringent layer with a thickness 875 by substantially 90 degrees so that the lights polarization may be substantially perpendicular to the length of the electrodes of a dispersion compensator or main beam deflector on a layer of the superpixel that may be above or below the 90 degree rotation layer. If the birefringent material 873 is a liquid crystal then surface 871 on the bottom transparent material 855 and the surface 881 on the top transparent material 879 can be textured to align the liquid crystal material. The preferred practice is to make material 873 a liquid crystal but other birefringent materials can be used.

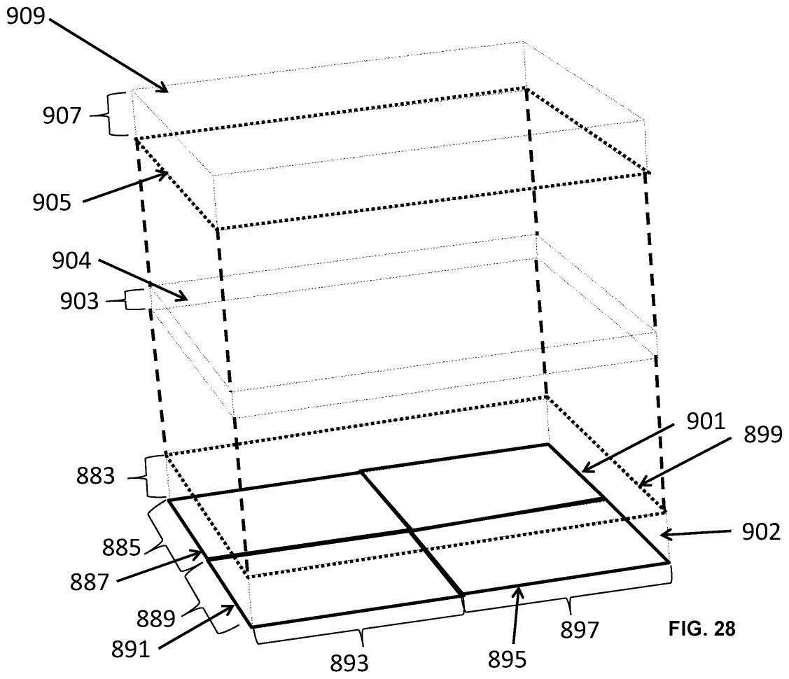

FIG. 28 shows an embodiment of a four pixel sub-component 90 degree optical rotator. The 90 degree optical rotator embodiment may be made on a top 909 and bottom 902 piece of transparent material like glass with a length (885 plus 889) and width (893 plus 897). The thickness 907 of the top transparent material 909 and the thickness 883 of the bottom transparent material 902 do not have to be the same or substantially similar but it is preferred if the transparent materials are as thin as possible. The first pixel sub-component 887 has a width 893 and length 885, the second pixel sub-component 891 has a width 893 and length 889, the third pixel subcomponent 895 has a width 897 and length 889, and the fourth pixel sub-component 901 has a width 897 and length 885. The width 893 of pixel sub-component one 887 and two 891 may be the same or substantially similar. The width 897 of pixel sub-component three 895 and four 901 may be the same or substantially similar. The widths 893 of pixel sub-component one 887 and two 891 and the widths 897 of pixel sub-component three 895 and four 901 do not need to be the same or substantially similar but it is preferred if the widths are. The length 885 of pixel sub-component one 887 and four 901 may be the same or substantially similar. The length 889 of pixel sub-component two 891 and three 895 may be the same or substantially similar. The lengths 885 of pixel sub-component one 887 and four 901 and the lengths 889 of pixel sub-component two 891 and three 895 do not need to be the same or substantially similar though it is preferred if the lengths are. The four pixel sub-components, called the first 887, second 891, third 895, and fourth 901 pixel sub-component, may be aligned over their corresponding first, second, third, and fourth pixel sub-components located on layers of the superpixel that may be above or below the 90 degree rotation layer. The length and width of a pixel sub-component in the 90 degree optical rotation layer and length and width of the same pixel sub-component on a different layer of the superpixel in the same superpixel may be the same or substantially similar length and width dimensions. The birefringent material 904 in the four pixel sub-component 90 degree rotation layer may be over all four of the pixel sub-components and rotates the light traveling through the birefringent layer with a thickness 903 by substantially 90 degrees so that the lights polarization may be substantially perpendicular to the length of the electrodes of a dispersion compensator or main beam deflector on a layer of the superpixel that above or below the 90 degree rotation layer. If the birefringent material 904 is a liquid crystal then surface 899 on the bottom transparent material 902 and the surface 905 on the top transparent material 909 can be textured to align the liquid crystal material. The preferred practice is to make material 904 a liquid crystal but other birefringent materials can be used.

Embodiments of a superpixel with two, three, four, or more electrode configurations may be used to bend light in substantially one (79 or 81) or two (79 and 81) directions. The embodiments of a superpixel can be divided into two major types. The first type of superpixel embodiments may bend the light in substantially one direction (79 or 81) as in case 1 and 2 and the second type of superpixel embodiments may bend the light in substantially two directions (79 and 81). Several variations of the superpixel embodiments that may include two, three, and four pixel sub-component superpixels and may include the corresponding two, three, or four pixel subcomponent layers are described herein.

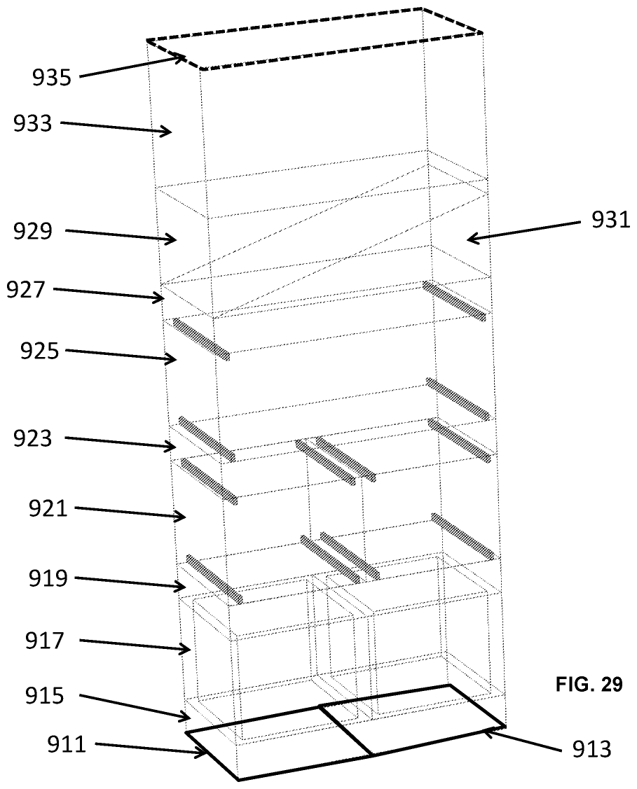

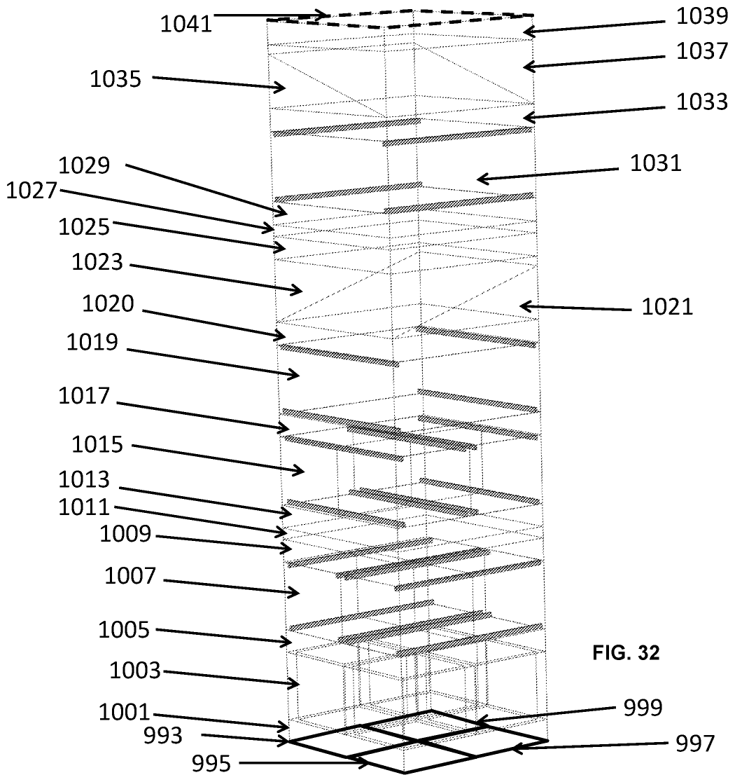

FIG. 29 shows all of the layers of an embodiment of a one directional (79 or 81) two pixel sub-component superpixel. The relative alignment of pixel sub-component one 911 and two 913 may be located at the bottom of the superpixel. The preferred length and width of all the pixel sub-components is between 10 and 25 microns. From the bottom up, the first layer includes a two pixel sub-component light collimator 917 which may be built on two pieces of transparent material 915 and 919. The preferred height of the light collimator is between 100 and 400 microns. The transparent material 915 and 919 and the other transparent materials in FIG. 29 are preferred to be ultrathin glass that is less than 100 microns thick. The second layer may be a two pixel sub-component four electrode dispersion compensator 921 which may be built on two pieces of transparent material 923 and 919. The two pixel sub-component dispersion compensator 921 shares the transparent material 919 with the light collimator 917. The preferred height of the dispersion compensator is 5 to 20 microns The two and three electrode configurations could also be used in over each pixel sub-component in the two pixel sub-component dispersion compensator 921. The third layer may be a two pixel sub-component four electrode main beam deflector 925 which may be built on two pieces of transparent material 927 and 923. The height of the main beam deflector is preferred to be 20 microns. The two pixel sub-component main beam deflector 925 shares the transparent material 923 with the two pixel sub-component dispersion compensator 921. The two and three electrode configurations could also be used in over all of the pixel subcomponents in the two pixel sub-component main beam deflector 925. The width and height of the electrodes in the two pixel sub-component superpixel embodiment are preferred to be 2 microns and 1 to 2 microns. The electrodes in FIG. 29 can either be embedded in the transparent materials in FIG. 32 or build on top of the transparent materials. The fourth layer may be the two pixel subcomponent prism array 931 and planarization layer 929 which may be built on two pieces of transparent material 927 and 933. The two pixel subcomponent prism array 931 and planarization layer 929 may be made of a transparent polymer or photoresist and it is preferred if the prism array and planarization layer in FIG. 29 have different refractive indexes. The preferred combined height of the two pixel subcomponent prism array and planarization layer is 50 microns. If the angle theta of the prism array 931 is made to be substantially close to zero then the prism array 931 and planarization layer 929 can be removed from the superpixel. The orientation of the prism array 931 and planarization layer 929 can also be rotated substantially one hundred eighty degree if desired. The two pixel sub-component prism array and planarization layer share the transparent material 927 with the two pixel sub-component main beam deflector 925. Transparent material 933 is also the top glass layer and can be thicker than the other transparent layers to provide additional structural support.

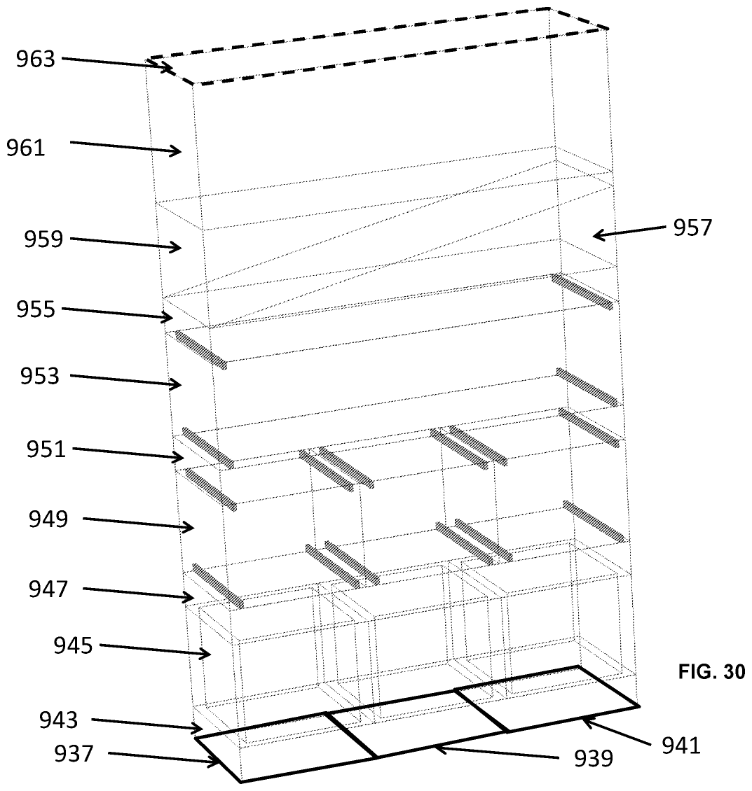

FIG. 30 shows all of the layers in an embodiment of a one directional (79 or 81) three pixel sub-component superpixel. The relative alignment of pixel sub-component one 937, two 939, and three 941 may be located at the bottom of the superpixel. The preferred length and width of all the pixel sub-components is between 10 and 25 microns. From the bottom up, the first layer may be the three pixel sub-component light collimator 945 which is built on two pieces of transparent material 943 and 947. The preferred height of the light collimator is between 100 and 400 microns. The transparent material 943 and 947 and the other transparent materials in FIG. 30 are preferred to be ultrathin glass that is less than 100 microns thick. The second layer may be a three pixel sub-component four electrode dispersion compensator 949 which may be built on two pieces of transparent material 947 and 951. The three pixel sub-component dispersion compensator 949 shares the transparent material 947 with the three pixel sub-component light collimator 945. The two and three electrode configurations could also be used in over each pixel sub-component in the three pixel sub-component dispersion compensator. The preferred height of the dispersion compensator is 5 to 20 microns. The third layer may be a three pixel sub-component four electrode main beam deflector 953 which may be built on two pieces of transparent material 951 and 955 with a liquid crystal electro-optical material as the preferred practice. The three pixel subcomponent main beam deflector shares the transparent material 951 with the three pixel subcomponent dispersion compensator 949. The preferred height of the main beam deflector is 20 microns. The two and three electrode configurations could also be used in over all of the pixel subcomponents in the three pixel sub-component main beam deflector. The width and height of the electrodes in the superpixel embodiment in FIG. 30 are preferred to be 2 microns and 1 to 2 microns. The electrodes in FIG. 30 can also either be embedded in the transparent materials in FIG. 30 or build on top of the transparent materials. The fourth layer may be the three pixel sub-component prism array 957 and planarization layer 959 which may be built on two pieces of transparent material 955 and 961. If its angle theta of the prism array 957 is made to be substantially close to zero then the prism array 957 and planarization layer 959 can be removed from the superpixel. The orientation of the prism array 957 and planarization layer 959 can also be rotated one hundred eighty degree if desired. The prism array and planarization layer in FIG. 30 may be made of a transparent polymer or photoresist and it is preferred if the prism array and planarization layer in FIG. 30 have different refractive indexes. The combined height of the prism array and planarization layer are preferred to be 50 microns. The three pixel sub-component prism array 957 and planarization layer 959 share the transparent material 955 with the three pixel subcomponent main beam deflector 953. Transparent material 961 is also the top glass layer and can be thicker than the other transparent layers to provide additional structural support.

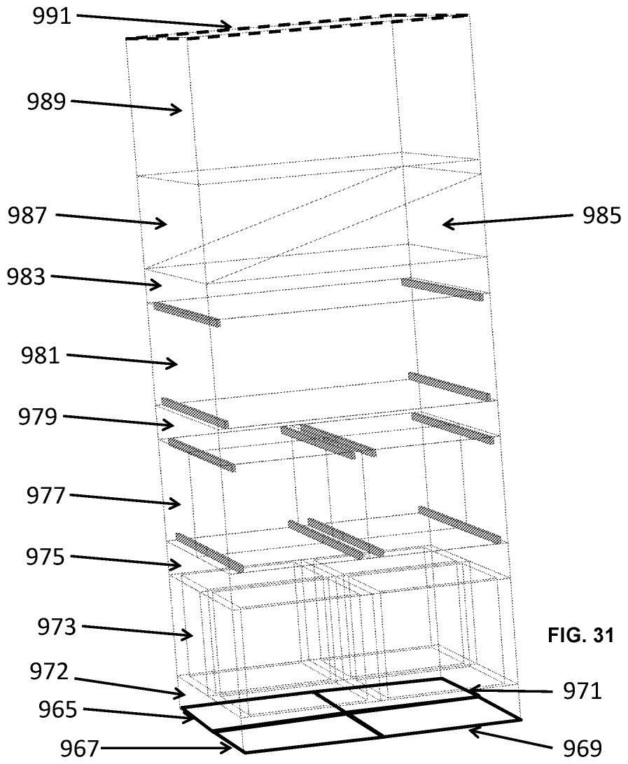

FIG. 31 shows all of the layers in an embodiment of a one directional (79 or 81) four pixel sub-component superpixel. Pixel sub-component one 965, two 967, three 969, and four 971 may be located at the bottom of the superpixel. The preferred length and width of all the pixel subcomponents is between 10 and 25 microns. From the bottom up, the first layer may be the four pixel sub-component light collimator 973 which may be built on two pieces of transparent material 972 and 975. The transparent material 972 and 975 and the other transparent materials in FIG. 31 are preferred to be ultrathin glass less than 100 microns thick. The preferred height of the light collimator in FIG. 31 is between 100 and 400 microns. The second layer may be a four pixel sub-component four electrode dispersion compensator 977 which is built on two pieces of transparent material 975 and 979. The four pixel sub-component dispersion compensator 977 shares the transparent material 975 with the four pixel sub-component light collimator 973. The preferred height of the dispersion compensator in FIG. 31 is between 5 and 20 microns. The two and three electrode configurations could also be used in over each pixel sub-component in the four pixel sub-component dispersion compensator. The width and height of the electrodes in the superpixel embodiment in FIG. 31 are preferred to 2 microns and 1 to 2 microns. The electrodes in FIG. 31 can also either be embedded in the transparent materials in FIG. 31 or build on top of the transparent materials. The third layer may be a four pixel sub-component four electrode main beam deflector 981 which may be built on two pieces of transparent material 979 and 983. The four pixel sub-component main beam deflector shares the transparent material 979 with the four pixel sub-component dispersion compensator 977 with a liquid crystal electro-optical material as the preferred practice. The height of the main beam deflector in FIG. 31 is preferred to be 20 microns. The two and three electrode configurations could also be used over all of the pixel subcomponents in the four pixel sub-component main beam deflector. The fourth layer may be the four pixel sub-component prism array 985 and planarization layer 987 which may be built on two pieces of transparent material 927 and 933. If the angle theta of the prism array 985 is made to be substantially close to zero then the prism array 985 and planarization layer 987 can be removed from the superpixel. The prism array and planarization layer in FIG. 31 may be made of a transparent polymer or photoresist and it is preferred if the prism array and planarization layer in FIG. 31 have different refractive indexes. The combined height of the prism array and planarization layer in FIG. 31 are preferred to be 50 microns. The orientation of the prism array 985 and planarization layer 987 can also be rotated one hundred eighty degree if desired. The four pixel sub-component prism array 985 and planarization layer 987 share the transparent material 983 with the four pixel sub-component main beam deflector 981. Transparent material 989 is also the top glass layer and can be thicker than the other transparent layers to provide additional structural support.

FIG. 32 shows all of the layers in an embodiment of a two directional (79 and 81) four pixel sub-component superpixel. The relative alignment of pixel sub-component one 993, two 995, three 997, and four 999 may be located at the bottom of the superpixel. The preferred length and width of all the pixel sub-components is between 10 and 25 microns. From the bottom up, the first layer may be the four pixel sub-component light collimator 1003 which may be built on two pieces of transparent material 1001 and 1005. The transparent material 1001 and 1005 and the other transparent materials in FIG. 32 are preferred to be ultrathin glass that is less than 100 microns thick. The preferred height of the light collimator in FIG. 32 is between 100 and 400 microns. The second layer may be a four pixel sub-component four electrode dispersion compensator 1007 which may be built on two pieces of transparent material 1005 and 1009 with case 5.5 being the preferred practice with liquid crystal electro-optical deflectors. The four pixel sub-component dispersion compensator 1007 shares the transparent material 1005 with the four pixel subcomponent light collimator 1003. The preferred height of the dispersion compensators in FIG. 32 is 5 to 20 microns. The two and three electrode configurations could also be used in over each of the pixel sub-components in the four pixel sub-component dispersion compensator 1007. The width and height of electrodes in the superpixel embodiment in FIG. 32 is preferred to be 2 microns and 1 to 2 microns. The electrodes in FIG. 32 can also either be embedded in the transparent materials in FIG. 32 or build on top of the transparent materials. The third layer may be a four pixel sub-component 90 degree rotation layer 1011 which may be built on two pieces of transparent material 1009 and 1013 and has a preferred height of 1 micron. The four pixel subcomponent 90 degree rotation layer 1011 shares the transparent material 1009 with the four pixel sub-component dispersion compensator 1007. The fourth layer may be a four pixel sub-component dispersion compensator 1015 which is built on two pieces of transparent material 1013 and 1017 with case 5.5 being the preferred practice with liquid crystal electro-optical deflectors. It is also important to note that if a pixel sub-component on a dispersion compensator has an NCM over one of the pixel sub-components then that same pixel sub-component on the a different dispersion compensator is preferred to also have an NCM over the same pixel sub-component. The two and three electrode configurations could also be used in over each of the pixel sub-components in the four pixel sub-component dispersion compensator 1015. The four pixel sub-component dispersion compensator 1015 shares the transparent material 1013 with the four pixel sub-component 90 degree rotation layer 1011. The fifth layer may be a four pixel sub-component main beam deflector 1019 which may be built on two pieces of transparent material 1017 and 1020 with a liquid crystal electro-optical material as the preferred practice. The two and three electrode configurations could also be used in over all of the pixel sub-components in the four pixel subcomponent main beam deflector 1019. It is important to note that the four pixel sub-component main beam deflector 1019 has the four pixel sub-component main beam deflector's electrodes substantially parallel to the four pixel sub-component dispersion compensator 1015. The four pixel sub-component main beam deflector 1019 shares the transparent material 1017 with the four pixel sub-component dispersion compensator 1015. The preferred height of main beam deflectors in FIG. 32 is 20 microns. The sixth layer may be a four pixel sub-component prism array 1021 and planarization layer 1023. If the angle theta of the prism array 1021 is made to be substantially close to zero then the prism array 1021 and planarization layer 1023 can be removed from the superpixel. The orientation of the prism array 1021 and planarization layer 1023 can also be rotated substantially one hundred eighty degree if desired. The prism arrays and planarization layers in FIG. 32 may be made of a transparent polymer or photoresist and it is preferred if the prism arrays and planarization layers have different refractive indexes. The combined height of the prism arrays and planarization layers are preferred to be 50 microns. The four pixel subcomponent prism array 1021 and planarization layer 1023 share the transparent material 1020 with the four pixel sub-component main beam deflector 1019. The seventh layer may be a four pixel sub-component 90 degree rotation layer which may be built on two pieces of transparent material 1025 and 1029 with a preferred height of 1 micron. The four pixel sub-component 90 degree rotation layer 1027 shares the transparent material 1025 with the four pixel sub-component prism array and planarization layer 1025. The eighth layer may be a four pixel sub-component main beam deflector 1031 that may be built on two pieces of transparent material 1029 and 1033 with a liquid crystal electro-optical material as the preferred practice. The two and three electrode configurations could also be used in over all of the pixel sub-components in the four pixel subcomponent main beam deflector 1031. It is important to note that the four pixel sub-component main beam deflector 1031 may have the four pixel sub-component main beam deflector's 1031 electrodes substantially perpendicular to the other four pixel sub-component main beam deflector 1019. The four pixel sub-component main beam deflector 1031 shares the transparent material 1029 with the four pixel sub-component 90 degree rotation layer 1027. The ninth layer may be a four pixel sub-component prism array 1035 and planarization layer 1037 which may be built on two transparent material 1033 and 1039. If the angle theta of the prism array 1035 is made to be substantially close to zero then the prism array 1035 and planarization layer 1037 can be removed from the superpixel. The orientation of the prism array 1035 and planarization layer 1037 can also be rotated one hundred eighty degree if desired. The four pixel sub-component prism array 1035 and planarization layer 1037 share the transparent material 1033 with the four pixel subcomponent main beam deflector 1031. Transparent material 1039 is also known as the top glass layer and can be made thicker for additional structural support.

An embodiment of a superpixel in the AMOS may include only one pixel sub-component superpixel with multiple layers of optical elements and devices that may be aligned and stacked on top of each other. As light travels through each layer of embodiments of a one pixel sub-component superpixel, each layer of the one pixel sub-component superpixel accomplishes a specific task in bending light of a range of wavelengths in substantially one (x axis 79 or y axis 81) or 2 directions (both x axis 79 and y axis 81) that are perpendicular to the normal 77 of the plane of the superpixel 75 to the desired direction.

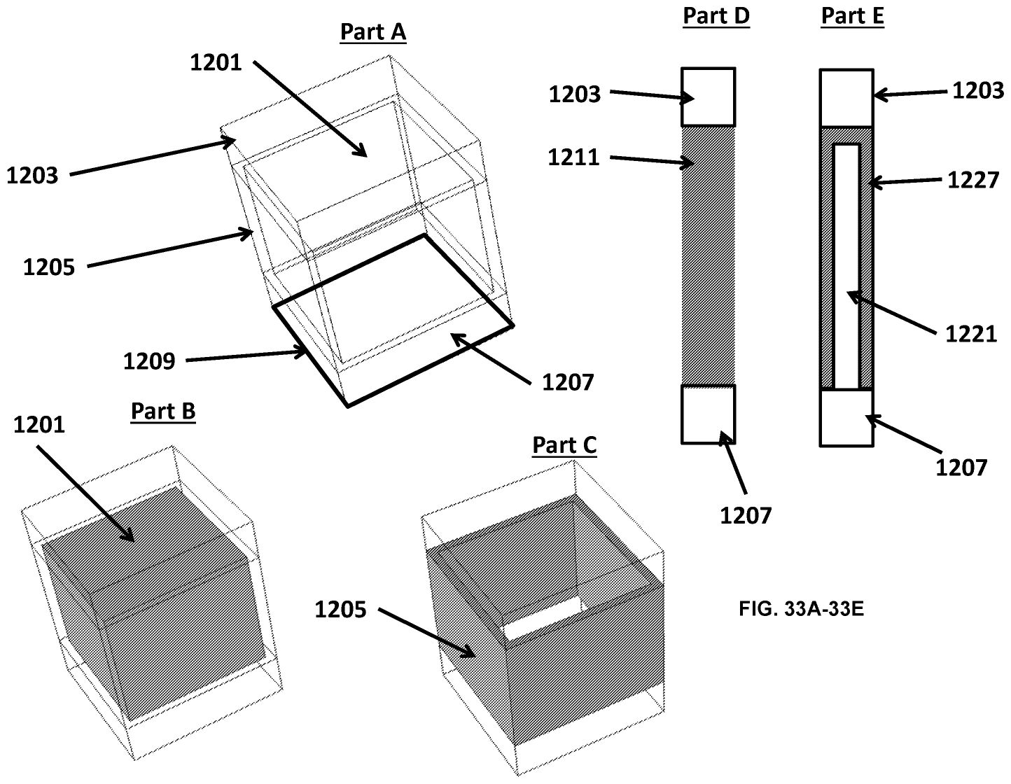

An embodiment of a one pixel sub-component 1209 light collimator is shown in FIG. 33. The one pixel sub-component 1209 light collimator may be made of a bottom optically transparent material 1207, an optically opaque and absorptive material or structure 1205, a transparent material 1201, and a top optically transparent material 1201. A cross section of the two embodiments of the optically opaque and absorptive material are seen in part D, the first version, and part E, the second version, of FIG. 33. The cross section first version of the optically opaque and absorptive material or structure may be made of an optically absorptive material 1211. The cross section of the second version of the optically opaque and absorptive material or structure may be made of an optically opaque or absorptive material 1227 around an optically transparent material 1221 in the form of a U shape. The first or second version or both of the optically transparent and absorptive material or structure seen in FIG. 33 can be used in each of the pixel sub-components of the one 1205, two 671, three 703, and four 735 pixel sub-component light collimator's opaque sections. The optically opaque and absorptive material can be shared between adjacent pixel sub-component(s) sections of optically opaque and absorptive material or structure if desired.

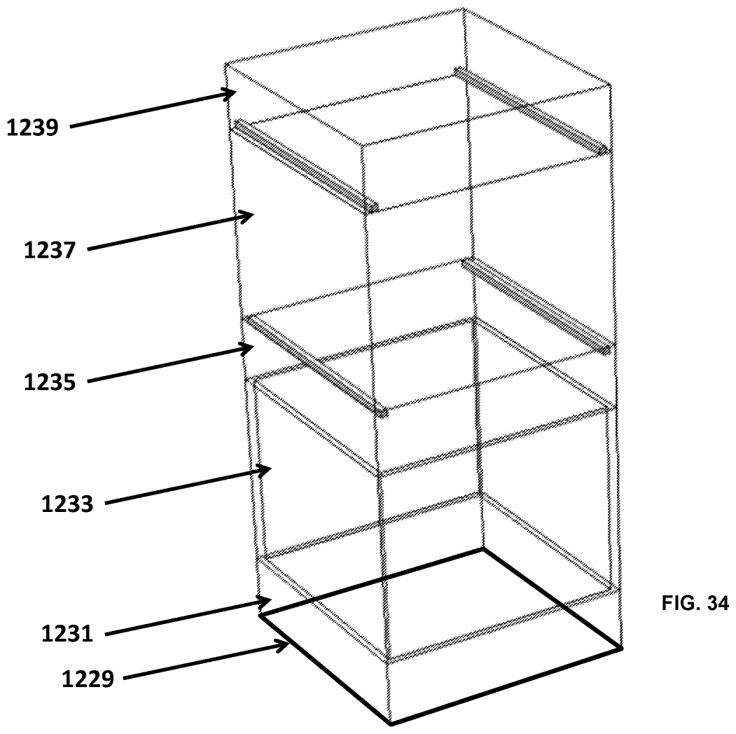

FIG. 34 shows an embodiment of a one pixel sub-component 1229 superpixel comprising of a optically transparent material 1231, a one pixel sub-component light collimator 1233, an optically transparent material 1235, a four electrode main beam deflector 1237, and a top optically transparent material. The preferred length and width of the pixel sub-component is between 10 and 25 microns. The transparent materials in FIG. 34 are preferred to be ultrathin glass that is less than 100 microns thick. The preferred height of the light collimator in FIG. 34 is between 100 and 400 microns. The preferred height of the main beam deflector in FIG. 34 is 20 microns. The four electrode main beam deflector 1237 is only one of the electrode configuration possibilities and the two and three electrode configurations over the pixel sub-component described herein could also be used but the four electrode set up is the preferred practice. The width and height of the electrodes in FIG. 34 are preferred to be 2 microns and 1 to 2 microns. The electrodes also can either be embedded in the transparent materials or build on top of the transparent material.

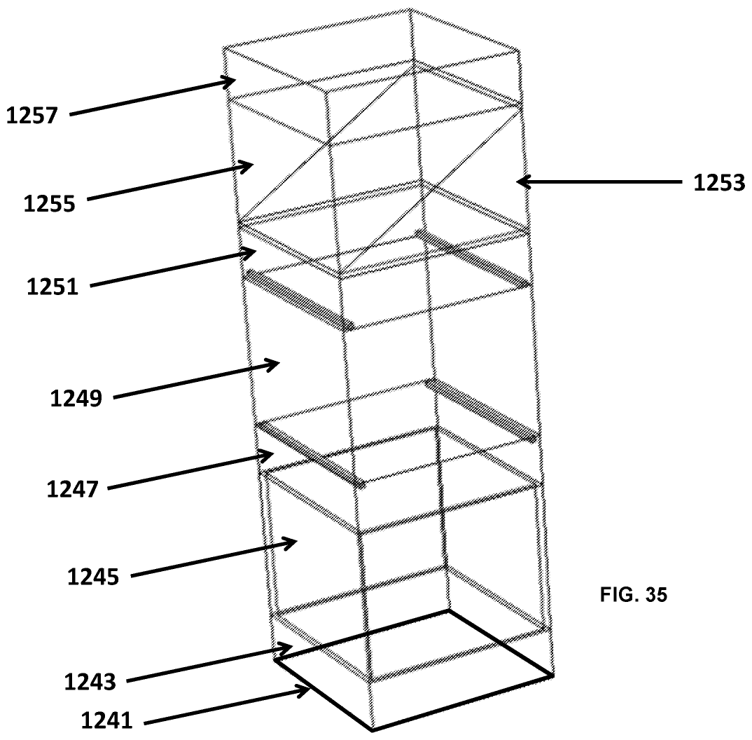

FIG. 35 shows an embodiment of a one pixel sub-component 1241 superpixel comprising of a optically transparent material 1243, one pixel sub-component light collimator 1245, a optically transparent material 1247, a four electrode main beam deflector 1249, a optically transparent material 1251, a prism array 1253, a planarization layer 1255, and a top optically transparent material 1257. The preferred length and width of the pixel sub-component in FIG. 35 is between 10 and 25 microns. The transparent materials in FIG. 35 are preferred to be ultrathin glass that is less than 100 microns thick. The preferred height of the light collimator in FIG. 35 is between 100 and 400 microns. The preferred height of the main beam deflector in FIG. 35 is 20 microns. The four electrode main beam deflector 1249 is only one of the electrode configuration possibilities and the two and three electrode configurations over the pixel sub-component described herein could also be used but the four electrode set up is the preferred practice. The electrodes also can either be embedded in the transparent materials or build on top of the transparent material.

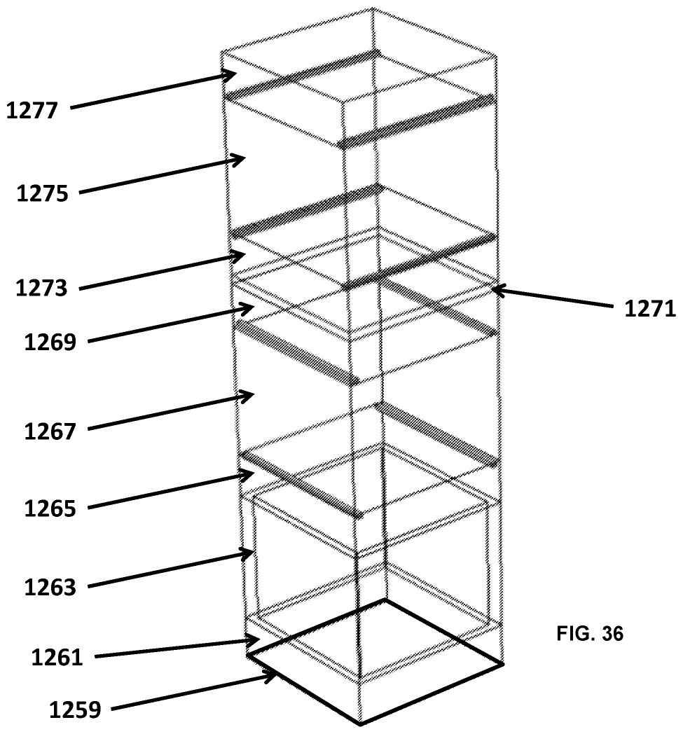

FIG. 36 shows an embodiment of a one pixel sub-component 1259 superpixel comprising of a optically transparent material 1261, a one pixel sub-component light collimator 1263, a optically transparent material 1265, a four electrode main beam deflector 1267, a optically transparent material 1269, a 90 degree rotation layer 1271, a optically transparent material 1273, a second 4 electrode main beam deflector 1275, and a top optically transparent material 1277. The preferred length and width of the pixel subcomponent is between 10 and 25 microns. The transparent materials in FIG. 36 are preferred to be ultrathin glass that is less than 100 microns thick. The preferred height of the light collimator in FIG. 36 is between 100 and 400 microns. The preferred height of the main beam deflector is 20 microns. The preferred height of the 90 degree rotation layer in FIG. 36 is 1 micron. The prism array and planarization layer in FIG. 36 may be made of a transparent polymer or photoresist and it is preferred if the prism array and planarization layer in FIG. 36 have different refractive indexes. The combined height of the prism array and planarization in FIG. 36 is preferred to be 50 microns. The four electrode main beam deflector 1267, 1275 is only one of the electrode configuration possibilities for either main beam deflector 1267, 1275 and the two and three electrode configurations over the pixel sub-component described herein could also be used but the four electrode set up is the preferred practice. The width and height of the electrodes in FIG. 36 are preferred to be 2 microns and 1 to 2 microns. The electrodes also can either be embedded in the transparent materials or build on top of the transparent material.

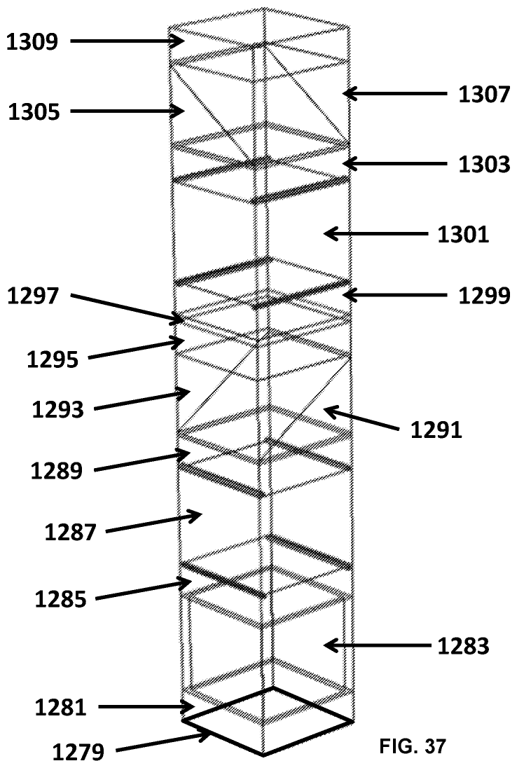

FIG. 37 shows an embodiment of a one pixel sub-component 1279 superpixel comprising a bottom optically transparent material 1281, a one pixel sub-component light collimator 1283, an optically transparent material 1285, a four electrode main beam deflector 1287, an optically transparent material 1289, a prism array 1291, a planarization layer 1293, an optically transparent material 1295, a 90 degree rotation layer 1297, an optically transparent material 1299, a second four electrode main beam deflector 1301, an optically transparent material 1303, a second prism array 1305, a second planarization layer 1307, and a top optically transparent material 1309. The preferred length and width of the pixel sub-component in FIG. 37 is between 10 and 25 microns. The transparent materials in FIG. 37 are preferred to be ultrathin glass that is less than 100 micron thick. The preferred height of the main beam deflectors in FIG. 37 is 20 microns. The preferred height of the 90 degree rotation layer is 1 micron. The prism arrays and planarization layers in FIG. 37 may be made of a transparent polymer or photoresist and it is preferred if the prism arrays and planarization layers in FIG. 37 have different refractive indexes. The combined height of a prism array and planarization layer is preferred to be 50 microns. The four electrode main beam deflector 1287 and 1301 is only one of the electrode configuration possibilities for either main beam deflector 1287, 1301 and the two and three electrode configurations over the pixel sub-component described herein could also be used but the four electrode set up is the preferred practice. The width and height of the electrodes in FIG. 37 are preferred to be 2 microns and 1 to 2 microns. The electrodes also can either be embedded in the transparent materials or build on top of the transparent material. If the angle of either prism array 1291 or 1305 is made to be substantially close to zero then either prism array 1291 and planarization layer 1293 or prism array 1305 and planarization layer 1307 can be removed.

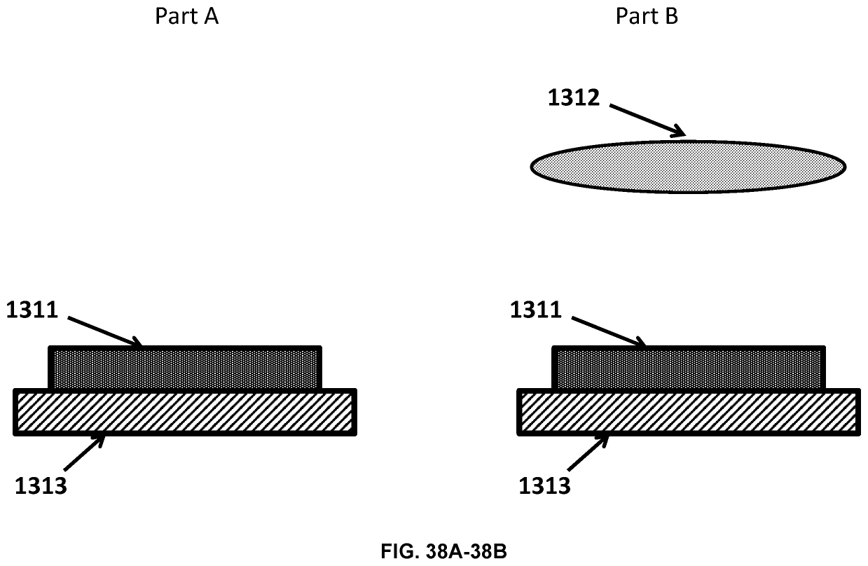

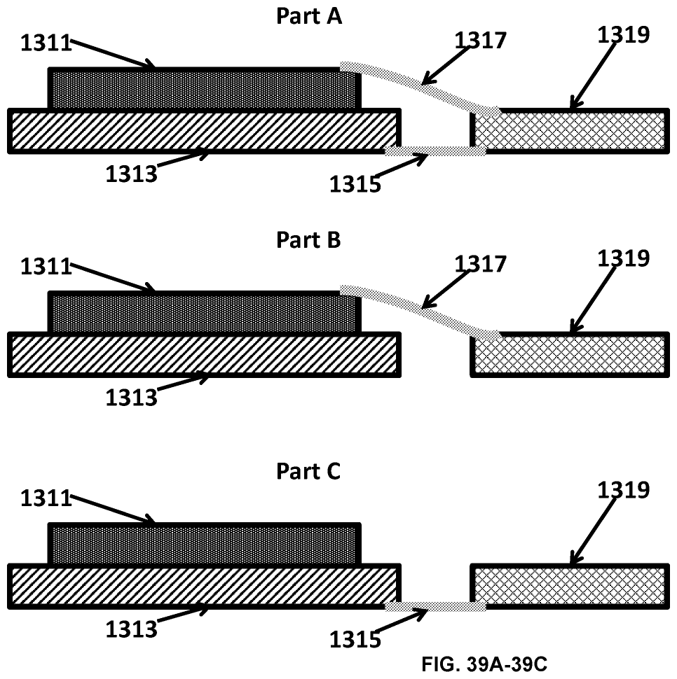

In some embodiments, there is an assembly for use with an optical component. Examples of assemblies include an AMOS made of a plurality of optical devices like the one, two, three, or four pixel sub-component superpixels that may be shown in FIGS. 29, 30, 31, 32, 34, 35, 36, and/or 37 positioned along a light axis. It is preferred if all of the plurality of optical devices like the various pixel sub-component superpixels in the AMOS have the same number of layers. For ease of reference, the assembly will be used herein to represent any of the assembly embodiments described herein. Examples of the optical components include a lens, lens assembly, mirror, or optoelectronic component. The assembly may comprise an AMOS 1311 made of a one or two dimensional array of superpixels made of a plurality of optical devices positioned along a light axis and aligned with one or more pixels of an optoelectronic component 1313 shown in FIG. 38 part A. The assembly may also comprise an AMOS 1311 made of a one or two dimensional array of superpixels made of a plurality of optical devices like a superpixel positioned along a light axis and aligned with one or more pixels of an optoelectronic component 1313 and a lens or lens assembly 1312 shown in FIG. 38 part B. In some embodiments, the optoelectronic component may be a light emitter like a display, laser source, a projector or light source or a light receiver like an imaging sensor or optical sensor. In some embodiments, aligned with the one or more pixels means that a respective plurality of optical devices and the one or more pixels are configured to transfer light there between. The plurality of optical devices may controllably or dynamically alter the angle of light exiting the plurality of optical devices at an angle divergent to the light axis at a second end of the plurality of optical devices. As used herein, the term “controllably” may refer to control an aspect of the assembly directly and optionally using a controller. As used herein, the term “dynamically” may refer to changing a characteristic of the assembly over time. In some embodiments, the optical device of the plurality of optical devices varies the divergent angle as a function of characteristics of a control signal received from a controller 1319 seen in FIG. 39. Examples of characteristics of the control signal include voltage, time period, or any characteristic that describes the control signal. Exemplary functions to vary the divergent angle include changing the voltage(s) on the electrodes in the assembly.

In some embodiments, the assembly further comprising: a controller 1319 like a micro-controller, digital circuit, or electronic circuit that may be configured to cause each respective assembly to independently alter an angle of a respective wavelength of light entering the respective assembly.

In some embodiments, the controller 1319 is connected directly to the assembly 1311 by a connector 1317 and connect directly to the optoelectronic component 1313 by a connector 1315 which is shown in FIG. 39 part A. The controller 1319 in some embodiments may only be connected directly to the assembly 1311 by a connector 1317 and indirectly to the optoelectronic component 1313 which is seen in FIG. 39 B. The controller 1319 in some embodiments may also only be connected directly to the optoelectronic component 1313 by a connector 1315 and indirectly connected to the assembly 1311 which is seen in FIG. 39 C.

In some embodiments, the assembly further comprising: a controller 1319 like a micro-controller, digital circuit, or electronic circuit may be configured to: set an angle of the wavelength range of light for a respective assembly at a first angle like 5 degrees, +/−5 degrees, 15 degrees, and/or 30 degrees during a first time period like 1 to 100 milliseconds and/or set an angle of the wavelength range of light for the respective assembly at a second angle like 10 degrees and/or +/−10 degrees during a subsequent time periods.

In some embodiments, the controller 1319 is configured to set a respective angle for example 5 or +/−5 degrees of a respective wavelength range of light by applying a one or more voltages to one or more electrodes of the one or more dispersion compensators and/or the one or more main beam deflectors to alter the electric field applied to the one or more electrodes.

In some embodiments, the controller is configured to set the angle of the first wavelength range of light along different angular positions along an angular range of greater than 3 degrees during a scanning time period of less than 10 seconds by adjusting a respective voltage applied to the one or more electrodes during the scanning time period. In some embodiments, the angular range may be greater than 3, 12, or 24 degrees.

In some embodiments, the optoelectronic component is a light receiver like an imaging sensor. The assembly 1311 which may be aligned over the pixels of the optoelectronic component can be used with a controller 1319 to control the angles of light of a respective wavelength or wavelength range that reaches the pixels on the light receiver. An image can be taken at a first set of angles during a first time period, the controller may change the angles that exit the assemble during the transition between subsequent time periods, and addition images may be taken by the light receiver at the same or different angles in subsequent time periods to capture a light field.

In some embodiments, the optoelectronic component is a light emitter like a display. The assembly 1311 which may be aligned over the pixels of the optoelectronic component can be used with a controller 1319 to control the angles of light of a respective wavelength or wavelength range that exit the assembly from the light emitter. An image may be emitted at a first set of angles during a first time period, the controller may change the angles that exit the assemble 1311 during the transition between subsequent time periods, and addition images may be emitted by the light emitter at the same or different angles in subsequent time periods to emit a light field.

It will be appreciated by those skilled in the art that changes could be made to the exemplary embodiments shown and described above without departing from the broad inventive concept thereof. It is understood, therefore, that this invention is not limited to the exemplary embodiments shown and described, but it is intended to cover modifications within the spirit and scope of the present invention as defined by the claims. For example, specific features of the exemplary embodiments may or may not be part of the claimed invention, different components as opposed to those specifically mentioned may perform at least some of the features described herein, and features of the disclosed embodiments may be combined. The words “right”, “left”, “lower” and “upper” designate directions in the drawings to which reference is made. The words “inwardly” and “outwardly” refer to directions toward and away from, respectively, the geometric center of any referenced device. As used herein, the terms “about” and “approximately” may refer to + or −10% of the value referenced. For example, “about 9” is understood to encompass 8.2 and 9.9.

It is to be understood that at least some of the figures and descriptions of the invention have been simplified to focus on elements that are relevant for a clear understanding of the invention, while eliminating, for purposes of clarity, other elements that those of ordinary skill in the art will appreciate may also comprise a portion of the invention. However, because such elements are well known in the art, and because they do not necessarily facilitate a better understanding of the invention, a description of such elements is not provided herein.

It will be understood that, although the terms “first,” “second,” etc. are sometimes used herein to describe various elements, these elements should not be limited by these terms. These terms are only used to distinguish one element from another. For example, a first element could be termed a second element, and, similarly, a second element could be termed a first element, without changing the meaning of the description, so long as all occurrences of the “first element” are renamed consistently and all occurrences of the second element are renamed consistently. The first element and the second element are both elements, but they are not the same element.

The terminology used herein is for the purpose of describing particular implementations only and is not intended to be limiting of the claims. As used in the description of the implementations and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, operations, elements, and/or components, but do not preclude the presence or addition of one or more other features, integers, operations, elements, components, and/or groups thereof

As used herein, the term “if” may be construed to mean “when” or “upon” or “in response to determining” or “in accordance with a determination” or “in response to detecting,” that a stated condition precedent is true, depending on the context. Similarly, the phrase “if it is determined (that a stated condition precedent is true)” or “if (a stated condition precedent is true)” or “when (a stated condition precedent is true)” may be construed to mean “upon determining” or “in response to determining” or “in accordance with a determination” or “upon detecting” or “in response to detecting” that the stated condition precedent is true, depending on the context.

Further, to the extent that the method does not rely on the particular order of steps set forth herein, the particular order of the steps should not be construed as limitation on the claims. The claims directed to the method of the present invention should not be limited to the performance of their steps in the order written, and one skilled in the art can readily appreciate that the steps may be varied and still remain within the spirit and scope of the present invention.

1-66. (canceled)

67. An apparatus, comprising:
(a) a plurality of optical devices positioned along a light axis and aligned with one or more pixels of an optoelectronic component,
(i) wherein the plurality of optical devices is configured to receive light at a light receiving angle along the light axis at a first end of the plurality of optical devices and controllably alter the angle of light exiting the plurality of optical devices at an angle divergent or the same to the light receiving angle at a second end of the plurality of optical devices, and
(ii) wherein the one or more pixels includes a pixel subcomponent configured to emit and receive pixel subcomponent light having a wavelength range and wherein the plurality of optical devices is aligned with the pixel subcomponent;
(b) a light collimator included with the plurality of optical devices, wherein the light collimator is aligned over the pixel subcomponent and comprises:
(i) an optically transparent material that extends along the light axis; and
(ii) an optically absorptive material that surrounds the optically transparent material along the light axis; and
(c) at least one main beam deflector included with the plurality of optical devices,
(i) wherein the main beam deflector is configured to alter an angle of a respective wavelength range of light relative to the light axis by an angular amount based on a magnitude of a gradient in refractive index across the main beam deflector that varies as a function of a characteristic of a received electrical signal from a controller and a height of the main beam deflector.

68. The apparatus of claim 67, wherein the plurality of optical devices includes:
(a) at least one prism array configured to alter the angle of the respective wavelength range of light relative to the light axis by an angular amount based on an angle of the prism array; and
(b) at least one planarization layer configured to planarize the prism array such that a side of the planarization layer where a respective wavelength range of light enters or exits is substantially normal to the light axis.

69. The apparatus of claim 67, further comprising:
(a) a second pixel subcomponent configured to emit and receive second pixel subcomponent light having a second wavelength range; and
(b) a second plurality of optical devices positioned along a light axis and aligned with the second pixel subcomponent, wherein the second plurality of optical devices includes a light collimator and at least one main beam deflector.

70. The apparatus of claim 69, wherein the first and second pluralities of optical devices each include:
(a) at least one dispersion compensator configured to alter an angle of the first and second pixel subcomponent light to exit the first and second pluralities of optical devices at a substantially similar angle to the first pixel subcomponent light by generating an electric field across the dispersion compensator, wherein
(b) the at least one dispersion compensator includes an electro-optical deflector having two or more electrodes configured to generate an electric field that varies as a function of a received voltage signal from a controller.

71. The apparatus of claim 69, wherein each plurality of optical devices includes:
(a) at least one prism array configured to alter the angle of the respective wavelength range of light relative to the light axis by an angular amount based on an angle of the prism array; and
(b) at least one planarization layer configured to planarize the prism array such that a side of the planarization layer where a respective wavelength range of light enters or exits is substantially normal to the light axis.

72. The apparatus of claim 69, further comprising:
(a) a third pixel subcomponent configured to emit and receive third pixel subcomponent light having a third wavelength range; and
(b) a third plurality of optical devices positioned along a light axis and aligned with the third pixel subcomponent, wherein the third plurality of optical devices includes a light collimator and at least one main beam deflector.

73. The apparatus of claim 72, wherein the first, second, and third pluralities of optical devices each include:
(a) at least one dispersion compensator configured to alter an angle of the first, second, and third pixel subcomponent light to exit the first, second, and third pluralities of optical devices at a substantially similar angle to the first pixel subcomponent light by generating an electric field across the dispersion compensator, and
(b) wherein the at least one dispersion compensator includes an electro-optical deflector having two or more electrodes configured to generate an electric field that varies as a function of a received voltage signal from a controller.

74. The apparatus of claim 72, wherein each plurality of optical devices includes:
(a) at least one prism array configured to alter the angle of the respective wavelength range of light relative to the light axis by an angular amount based on an angle of the prism array; and
(b) at least one planarization layer configured to planarize the prism array such that a side of the planarization layer where a respective wavelength range of light enters or exits is substantially normal to the light axis.

75. The apparatus of claim 72, further comprising:
(a) a fourth pixel subcomponent configured to emit and receive fourth pixel subcomponent light having a fourth wavelength range; and
(b) a fourth plurality of optical devices positioned along a light axis and aligned with the fourth pixel subcomponent, wherein the fourth plurality of optical devices includes a light collimator and at least one main beam deflector.

76. The apparatus of claim 75, wherein the first, second, third, and fourth pluralities of optical devices each include:
(a) at least one dispersion compensator configured to alter an angle of the first, second, third, and fourth pixel subcomponent light to exit the first, second, third, and fourth pluralities of optical devices at a substantially similar angle to the first pixel subcomponent light by generating an electric field across the dispersion compensator, and
(b) wherein the at least one dispersion compensator includes an electro-optical deflector having two or more electrodes configured to generate an electric field that varies as a function of a received voltage signal from a controller.

77. The apparatus of claim 75, wherein each plurality of optical devices includes:
(a) at least one prism array configured to alter the angle of the respective wavelength range of light relative to the light axis by an angular amount based on an angle of the prism array; and
(b) at least one planarization layer configured to planarize the prism array such that a side of the planarization layer where a respective wavelength range of light enters or exits is substantially normal to the light axis.

78. The apparatus of claim 67, further comprising:
(a) a sensor configured to detect light exiting the optical electronic component and generate a sensor signal representative of a light field of its environment; and
(b) a controller configured to receive the sensor signal and alter the angle of the first wavelength range of light exiting the plurality of optical devices based on at least one of sensor signal characteristics, operating characteristics, and optical device characteristics.

79. The apparatus of claim 67, wherein the optoelectronic component is a light emitter or light receiver.

80. The apparatus of claim 75, further comprising one or more assemblies arranged in either a one-dimensional or two-dimensional array extending along a plane orthogonal to the light axes of any or all of the pluralities of optical devices, wherein each assembly independently alters an angle of a respective wavelength of light entering a respective assembly.
